(19) United States
(12) Patent Application Publication
(10) Pub. No.: US 2026/0068631 A1
(43) Pub. Date: Mar. 5, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/818,130

(22) Filed: Aug. 28, 2024

(51) Int. Cl. H01L 23/528; H01L 21/768; H01L 21/8238; H01L 27/092; H01L 29/06; H01L 29/161; H01L 29/417; H01L 29/423; H01L 29/49; H01L 29/66; H01L 29/775; H01L 29/786

(52) U.S. Cl. CPC H01L 23/5286; H10D 64/254; H10D 84/0186; H10D 84/038; H10D 84/85; H10D 30/014; H10D 30/43; H10D 30/6735; H10D 30/6757; H10D 62/121; H10D 62/832; H10D 64/668

(57) ABSTRACT

A method includes forming a semiconductive sheet over a front-side of a semiconductive region that is on a front-side of a substrate; forming semiconductive layers on the front-side of the semiconductive region and at either side of the semiconductive sheet; forming source/drain structures over the semiconductive layers and on the either side of the semiconductive sheet; forming a gate structure wrapping around the semiconductive sheet; performing a planarization process on a back-side of the substrate to expose the semiconductive region; etching the semiconductive region from a back-side of the semiconductive region to form a first opening exposing a first one of the semiconductive layers, while remains covering a second one of the semiconductive layers; selectively removing the first one of the semiconductive layers through the first opening to form a second opening; forming a contact in the first and second openings.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is schematic view of a wafer including a front-side interconnect structure and a back-side interconnect structure on a device region thereof in accordance with some embodiments of the present disclosure.

FIGS. 2A and 2B illustrate a layout diagram of a circuit on a front side and a back side of a semiconductor structure, respectively, according to some embodiments of the present disclosure.

FIGS. 3A-3E, 3G, 3I, and 3J illustrate cross-sectional views obtained from reference cross-sections C1-C1′, C2-C2′, C3-C3′, C4-C4′, C5-C5′, C6-C6′, C7-C7′, and C8-C8′ in FIGS. 2A and 2B.

FIGS. 3F and 3H illustrate cross-sectional views of a semiconductor structure corresponding to FIGS. 3E and 3G, respectively, according to some embodiments of the present disclosure.

FIGS. 4A-4F illustrate cross-sectional views of a semiconductor structure corresponding to FIGS. 3A-3E and 3G, respectively, according to some embodiments of the present disclosure.

FIGS. 5A and 5B illustrate a layout diagram of a circuit on a front side and a back side of a semiconductor structure, respectively, according to some embodiments of the present disclosure.

FIGS. 6A and 6B illustrate cross-sectional views obtained from reference cross-sections C11-C11′ and C12-C12′, respectively, in FIGS. 5A and 5B.

FIGS. 7A-28C illustrate cross-sectional views of intermediate stages in the formation of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. For example, in a cell routing of the IC structure, Vdd and Vss power routing may occupy too many routing resources and therefore impact the cell scaling as well as the performance of the IC structure (e.g., RC delay or IR drop). Hence, a part of power lines and power conductive contacts are moved to wafer back-side, so as to reduce the routing loading and improve the circuit density in a same chip area. Nevertheless, the power conductive contact on the wafer back-side may not be aligned with the source/drain region when forming thereof, which in turn non-overlaps with the source/drain region and/or overlaps with the gate, such that an unwanted connection may occur and therefore impacts the performance of IC structure.

Therefore, the present disclosure in various embodiments provides a metal line routing method to improve the functional density and operation performance on the IC structure. Because the power conductive contact can be formed to inherit the location of the dielectric layer and/or semiconductive layer (e.g., sacrificial layer) directly underlying the source/drain region, the back-side contact can self-align with the source/drain region to connect the source/drain region to the back-side power metal layers. Therefore, an isolation margin issue of the back-side power conductive contact to gate electrode can be solved, which in turn allows for scaling the contacted poly pitch (CPP). In addition, because the back-side power conductive contact can have a back-side portion having wider width than the front-side portion thereof (e.g., stepped sidewall structure) to connect the back-side power metal layers, an improved contact resistance between the source/drain region and the back-side power metal layers can be achieved.

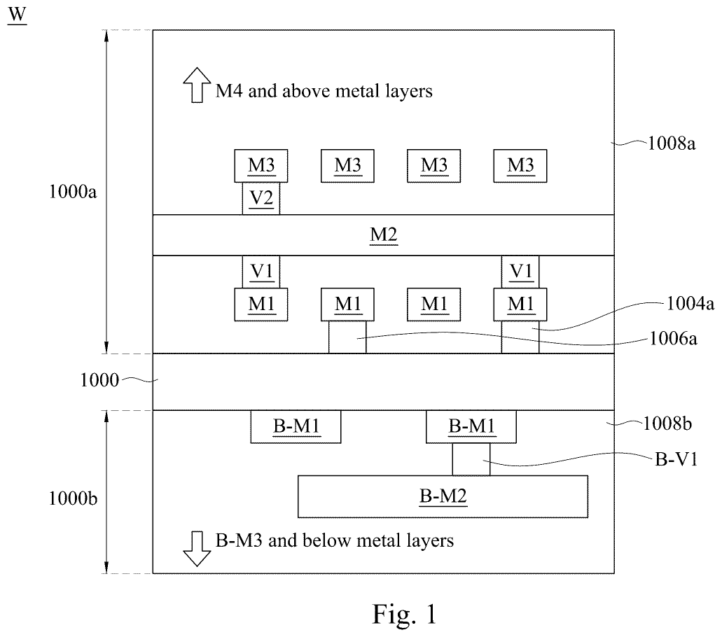

Reference is made to FIG. 1. FIG. 1 is schematic view of a wafer W including a front-side interconnect structure 1000a and a back-side interconnect structure 1000b on a device region 1000 thereof in accordance with some embodiments of the present disclosure. As shown in FIG. 1, the device region 1000 can be provide in the wafer W and includes, such as gate, channel, and source/drain regions. A front-side interconnect structure 1000a can be formed after the device region formation. Specifically, the front-side interconnect structure 1000a can be formed to have a front-side gate via 1006a, and a front-side source/drain via 1004a. The front-side interconnect structure 1000a may further include, for example, two metallization layers, labeled as M1, M2, and M3, with two layer of metallization via or interconnect, labeled as V1 and V2. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure 1000a includes a full metallization stack, including a portion of each of metallization layers M1, M2, and M3 connected by the interconnect V1 and V2, with the front-side gate via 1006a, and the front-side source/drain via 1004a connecting the stack to the source/drain region and the gate of the transistor in the device region 1000. Also included in the front-side interconnect structure 1000a shown in FIG. 1 is a front-side IMD (inter-metal dielectric) layer 1008a. The front-side IMD layer 1008a may provide electrical insulation as well as structural support for the various features in the front-side interconnect structure 1000a.

As shown in FIG. 1, the back-side interconnect structure 1000b can be formed after device region formation. The back-side interconnect structure 1000b can be formed to include, for example, two metallization layers, labeled as B-M1 and B-M2, with one layer of metallization via B-V1 connected between the metallization layers B-M1 and B-M2. Other embodiments may contain more or fewer metallization layers and corresponding more or fewer number of vias. The metal line illustrated here just for an example, and the metal line may be otherwise oriented (rotated 90 degrees or at other orientations). The back-side interconnect structure 1000b may include a full metallization stack including the metallization layer and the metallization layer B-M1 connecting the stack to the source/drain region of the transistor in the device region 1000. Also included in the back-side interconnect structure 1000b shown in FIG. 1 can be a back-side IMD layer 1008b. The back-side IMD layer 1008b may provide electrical insulation as well as structural support for the various features in the back-side interconnect structure 1000b.

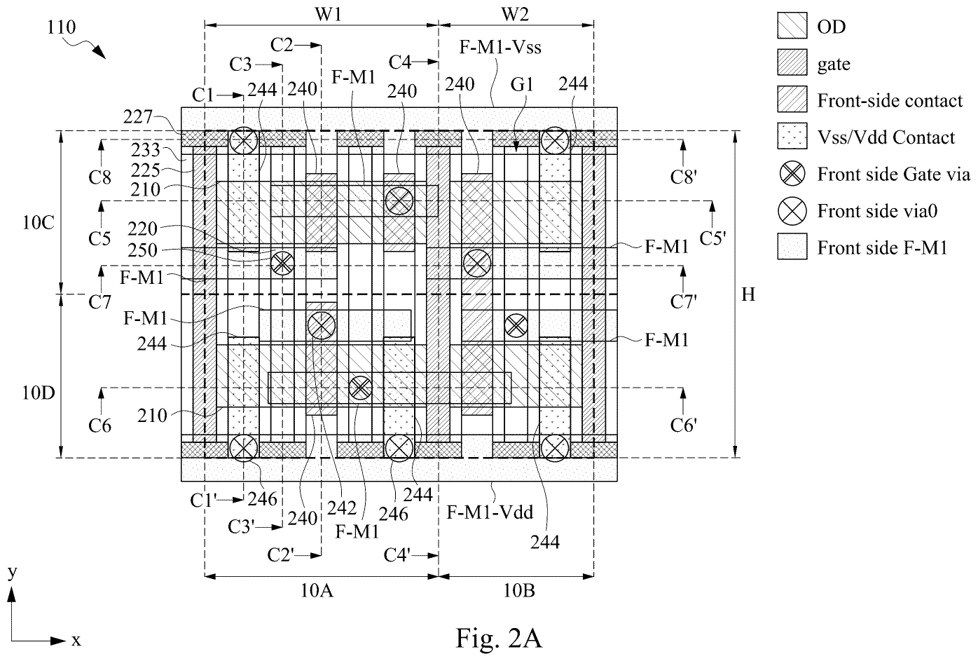

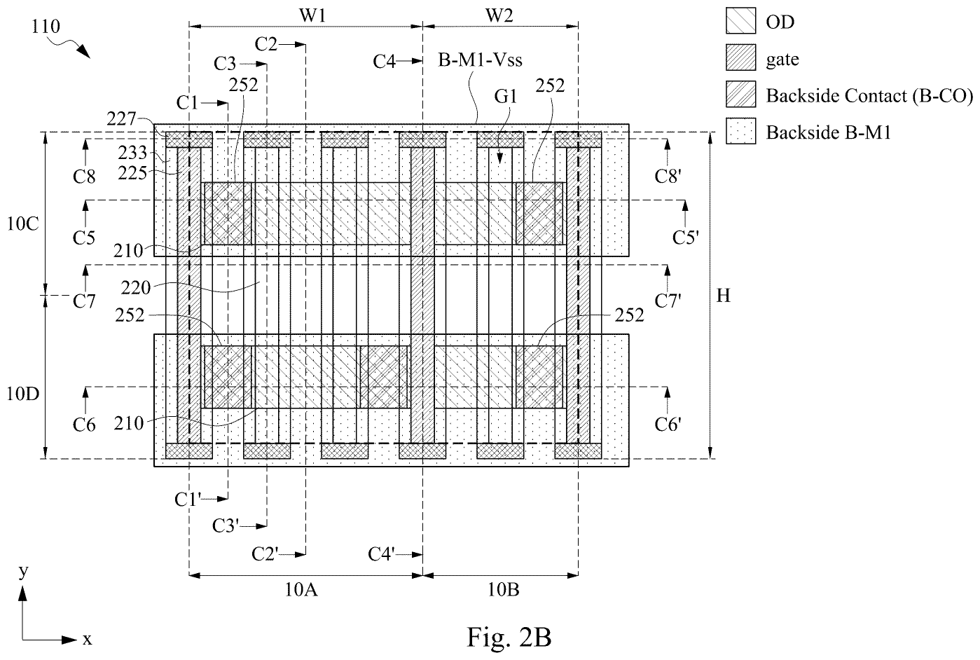

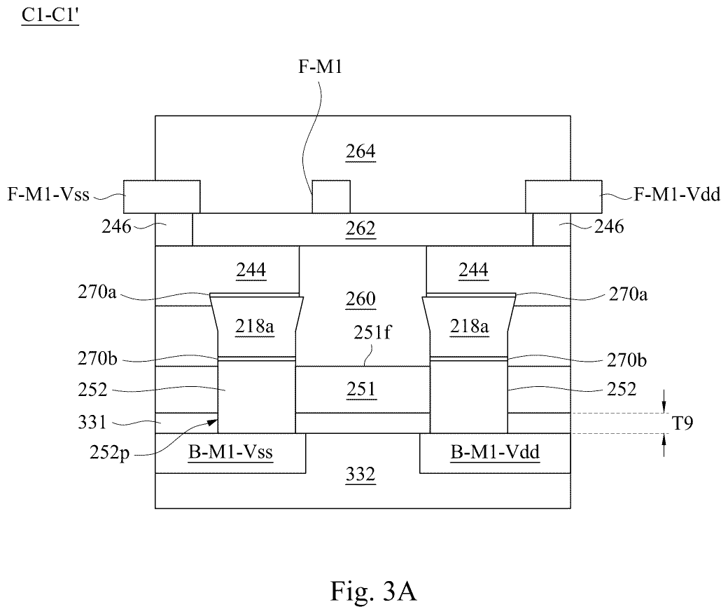

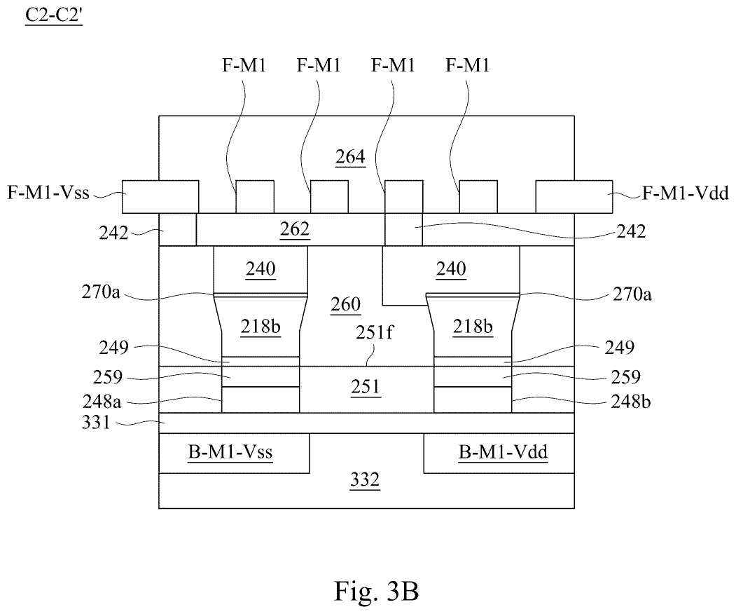

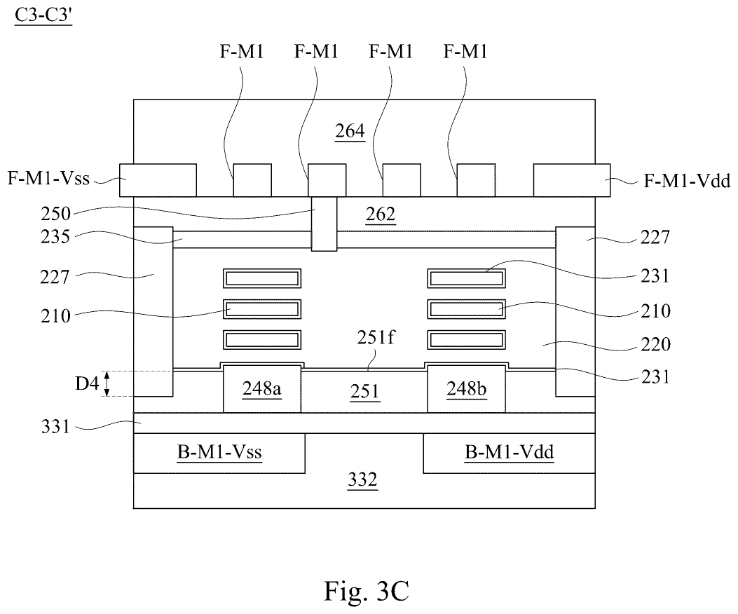

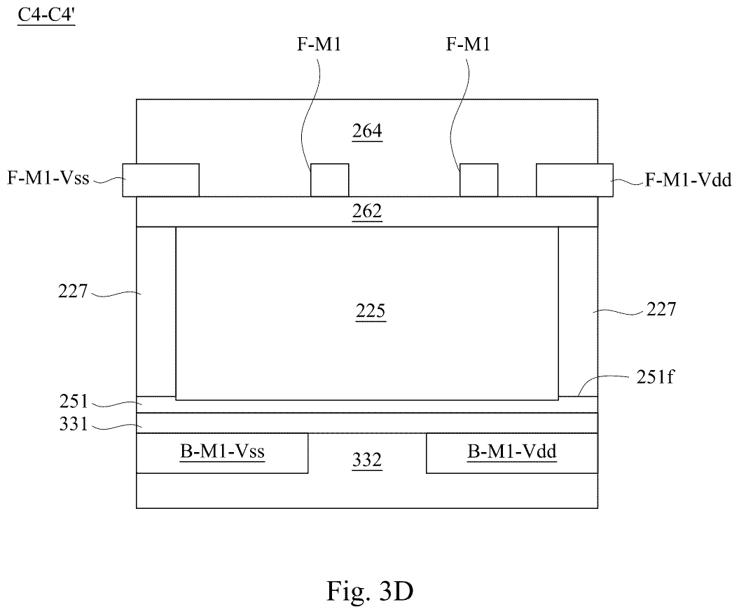

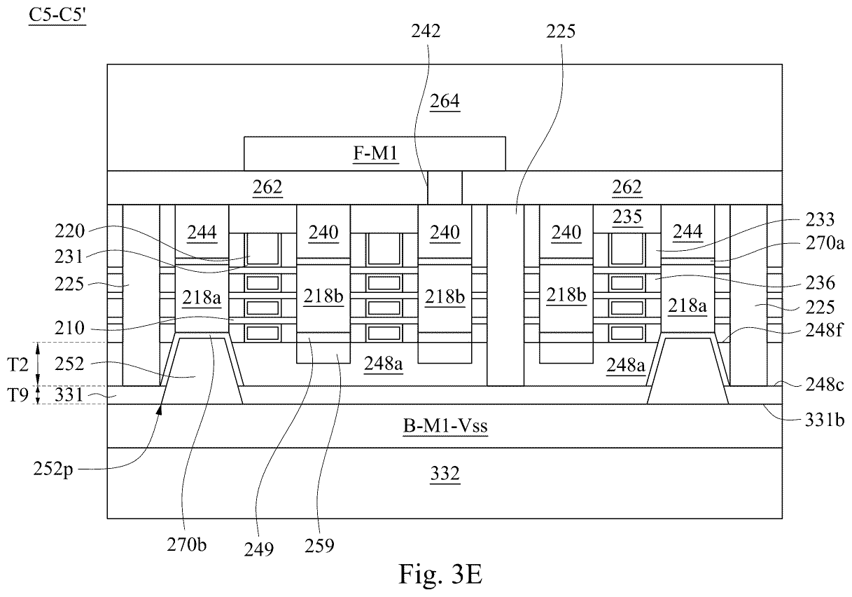

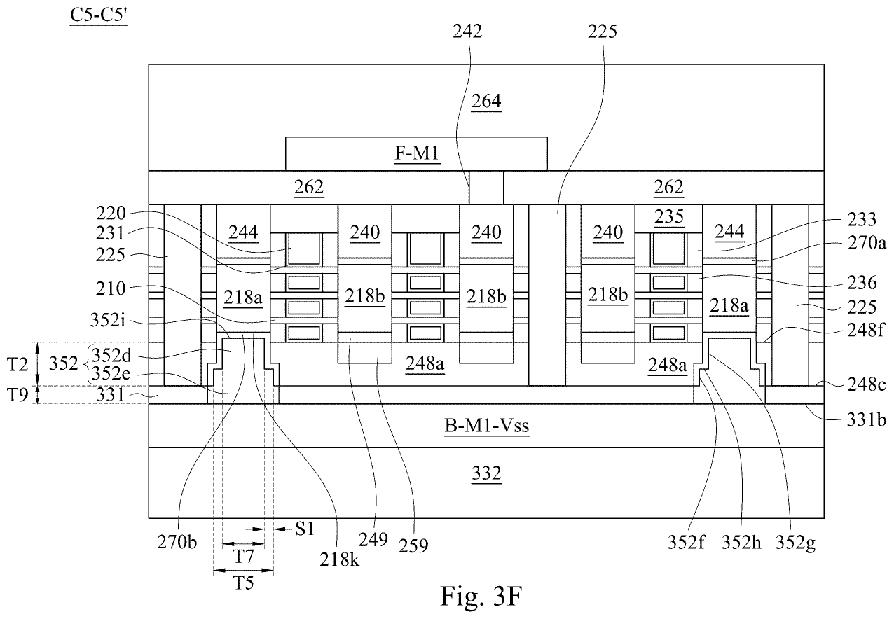

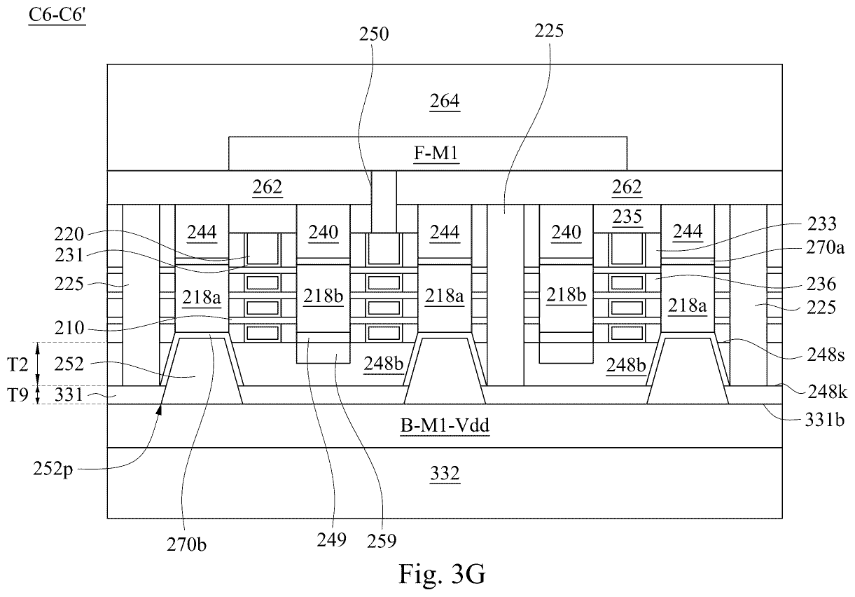

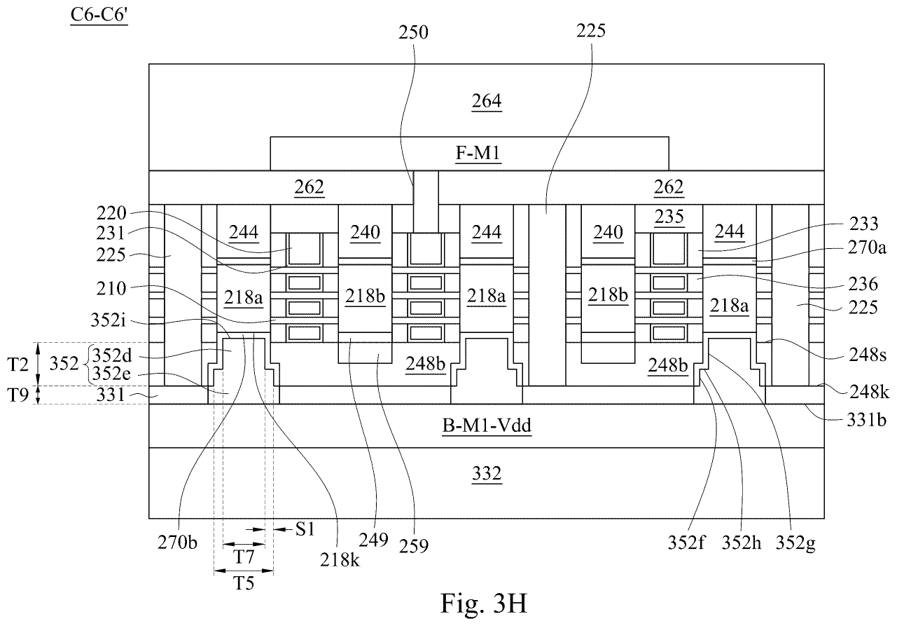

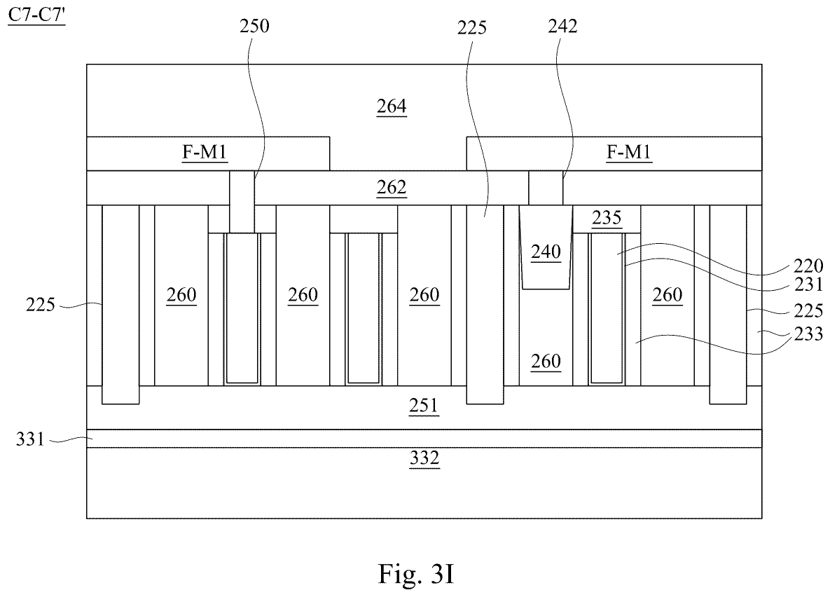

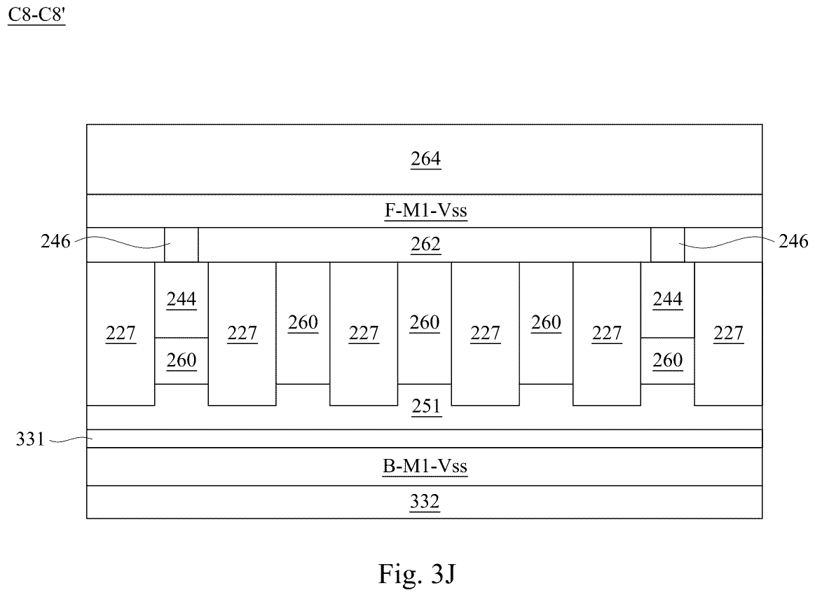

Reference is made to FIGS. 2A, 2B, 3A-3E, 3G, 3I, and 3J. FIGS. 2A and 2B illustrate a layout diagram of a logic circuit on a front side and a back side of a semiconductor structure, respectively, according to some embodiments of the present disclosure. FIGS. 3A-3E, 3G, 3I, and 3J illustrate cross-sectional views obtained from reference cross-sections C1-C1′, C2-C2′, C3-C3′, C4-C4′, C5-C5′, C6-C6′, C7-C7′, and C8-C8′ in FIGS. 2A and 2B.

As shown in FIGS. 2A and 2B, a first logic circuit region 10A and a second circuit region 10B are arranged in the same row in the cell. The outer boundary of each of the first logic circuit region 10A and the second circuit region 10B is illustrated using dashed lines. In some embodiments, the first logic circuit region 10A and the second circuit region 10B may have the same cell height H. In some embodiments, the cell width W1 of the first logic circuit region 10A may be wider than the cell width W2 of the second circuit region 10B. In FIGS. 2A and 2B, it should be noted that the configuration of the first logic circuit region 10A and the second circuit region 10B in the logic circuit 110 is used as an illustration, and not to limit the disclosure. In some embodiments, the row in the cell of the logic circuit 110 may include more logic cells or fewer logic cells than the layout shown in FIGS. 2A and 2B. In some embodiments, the cell of the logic circuit 110 may include more rows or fewer rows and more columns or fewer columns than the layout shown in FIGS. 2A and 2B. Each logic cell provides a circuit or portion thereof, exemplary functionality provided by the cells includes, but are not limited to NAND, NOR, AND, XOR, XNOR, SACN, inverter, Flip-Flop, latch, and/or other suitable logic or storage functions. For example, the first logic circuit region 10A may have a first one of the logic circuits including inverter, NAND, and NOR circuit schematics and Flip-Flop circuit schematics for NOR and NAND, and the second logic circuit region 10B may have a second one of the logic circuits including inverter, NAND, and NOR circuit schematics and Flip-Flop circuit schematics for NOR and NAND. By way of example but not limiting the present disclosure, the first logic circuit region 10A may have a NAND circuit, and the second circuit region 10B may have an inverter.

In some embodiments, the logic circuit 110 may include a plurality of transistors in a first conductivity type device region 10C and a second conductivity type device region 10D. In some embodiments, the transistors in the first conductivity type device region 10C may be NMOSFET transistors with silicon channel regions, and the transistors in the second conductivity type device region 10D may be PMOSFET transistors with silicon channel regions. In some embodiments, the transistors may be GAA FETs. The silicon channel regions of the NMOSFET and PMOSFET transistors are formed by semiconductive sheets 210. The semiconductive sheets 210 are stacked along the Z-direction (not shown) and are wrapped by the gate electrode, and the Z-direction is perpendicular to the plane formed by the X-direction and Y-direction. In some embodiments, the semiconductive sheets 210 has a length extending in the X-direction in a range from about 4 nm to about 12 nm, such as about 4, 5, 6, 7, 8, 9, 10, 11, or 12 nm. The semiconductive sheets 210 are over the front-side surface 248f/248s of the semiconductive layer 248a/248b (see FIGS. 3E and 3G).

As shown in FIGS. 2A and 2B, the logic circuit 110 includes dielectric-base gates 225 extending in the Y-direction. The logic circuit 110 further includes gate electrodes 220 extending in the Y-direction and being arranged between adjacent two of the dielectric-base gates 225. In other words, the gate electrodes 220 extend in parallel with each other, and the dielectric-base gates 225 extend in parallel with a lengthwise direction of the gate electrodes 220. The transistors are surrounded by the dielectric-base gates 225. In other words, the dielectric-base gates 225 are formed in the boundary of the first logic circuit region 10A and in the boundary of the second circuit region 10B. Moreover, one of the dielectric-base gates 225 between the first and second logic circuit regions 10A and 10B is shared by the first and second logic circuit regions 10A and 10B, i.e., the first logic circuit region 10A and the second circuit region 10B in the same row are isolated (or separated) from each other by said dielectric-base gate 225. The material of the dielectric-base gates 225 is different from that of the gate electrodes 220. In some embodiments, the dielectric-base gates 225 can be interchangeably referred to dummy gates, dummy gate pattern, dummy gate strip, isolation structures/dielectric gates serving as circuit boundaries. Also included in FIGS. 2A and 2B, spacers 233 are formed on sidewalls of the dielectric-base gates 225 and the gate electrodes 220. In some embodiments, the gate electrode 220 has a length extending in the Y-direction in a range from about 4 nm to about 70 nm, such as about 4, 5, 10, 15, 20, 25, 30, 35, 40, 45, 50, 55, 60, 65, or 70 nm.

As shown in FIG. 2A illustrating the logic circuit 110 on the front side of the semiconductor structure/wafer, the gate electrodes 220 are connected to an overlying level (e.g., metal line F-M1) through gate vias 250. Source/drain regions 218a/218b (see FIGS. 3A, 3B, 3E, and 3H) are formed on opposite sides of the semiconductive sheets 210 wrapping around by the gate electrodes 220. The source/drain regions 218a (or source nodes) (see FIGS. 3A, 3E, and 3G) which are of Vdd node and Vss node can be electrically coupled to overlying power supply voltage line F-M1-Vdd/F-M1-Vss through a power supply voltage contact 244 and a conductive via 246. In some embodiments, the source/drain region 218a can be interchangeably referred to as a power conductor connection, and the power supply voltage contact 244 can be interchangeably referred to as a Vss/Vdd contact. The source/drain regions 218b (or drain nodes) (see FIGS. 3B, 3E, and 3G) which are not of Vdd node and Vss node can be electrically coupled to overlying metal lines F-M1 through source/drain contacts 240 and source/drain vias 242.

In some embodiments, the power supply voltage line F-M1-Vdd can be interchangeably referred to as a Vdd line that is provided with positive a power supply voltage Vdd, and the power supply voltage line F-M1-Vss can be interchangeably referred to as a Vss line that is provided with power supply voltage Vss. In some embodiments, the cell can be powered through the positive power supply node Vdd that has a positive power supply voltage (also denoted as VDD). The cell can be also connected to power supply voltage Vss (also denoted as VSS), which may be an electrical ground. Throughout the description, the notations of metal lines may be followed by the metal line levels they are in, wherein the respective metal line level is placed in parenthesis. As shown in FIG. 2A, metal lines disposed at the M1 level on the front-side of the semiconductor structure may include the power supply voltage lines F-M1-Vdd and F-M1-Vss and the metal lines F-M1 laterally between the power supply voltage lines F-M1-Vdd and F-M1-Vss. The metal lines disposed at the M1 level on the front-side of the semiconductor structure may have lengthwise directions parallel to the X-direction (e.g., column direction). In some embodiments, the power supply voltage line F-M1-Vdd/F-M1-Vss disposed at the M1 level can be interchangeably referred to a power supply voltage landing pad or a power supply voltage landing line. In some embodiments, the lines can be interchangeably referred to metal layers, conductive lines, conductive layers, or conductors.

In some embodiments, a dopant in the source/drain regions 218a and 218b (see FIGS. 3A, 3B, and 3E) of the first conductivity type device region 10C (see FIGS. 2A and 2B) has an opposite conductivity type to another dopant in the source/drain regions 218a and 218b (see FIGS. 3A, 3B, and 3G) of the second conductivity type device region 10D. For example, the source/drain regions 218a and 218b of the first conductivity type device region 10C may have an n-type dopant, and the source/drain regions 218a and 218b of the second conductivity type device region 10D may have a p-type dopant. In some embodiments, the source/drain regions 218a and 218b of the first conductivity type device region 10C may include SiP, SiC, SiPC, SiAs, Si, or a combination thereof. In some embodiments, the source/drain regions 218a and 218b of the first conductivity type device region 10C may have a phosphorus concentration within a range from about 2E19/cm³ to about 3E21/cm³. In some embodiments, the source/drain regions 218a and 218b of the second conductivity type device region 10D may include boron, BF₂, SiGe, or a combination thereof. In some embodiments, the source/drain regions 218a and 218b (see FIGS. 3A, 3B, and 3G) of the second conductivity type device region 10D (see FIGS. 2A and 2B) may have a boron concentration within a range from about 1E19/cm³ to about 6E20/cm³. In some embodiments, the source/drain regions 218a and 218b of the second conductivity type device region 10D may have a Ge atomic percentage within a range of about 36% to about 85%. In some embodiments, the source/drain regions 218a and 218b of the second conductivity type device region 10D may include a carbon-containing material.

As shown in FIG. 2B illustrating the logic circuit 110 on the back side of the semiconductor structure with a contact 252, the source/drain regions 218a (see FIGS. 3A, 3E, and 3H) which are of Vdd node and Vss node can be electrically coupled to the underlying power supply voltage line B-M1-Vdd/B-M1-Vss through the contact 252. On the other hand, dielectric layers 249 and/or semiconductive layers 259 (see FIGS. 3B, 3E, and 3G) can be formed between the source/drain regions 218b and the semiconductive layer 248a/248b, such that the source/drain regions 218b (see FIGS. 3B, 3E, and 3G) which are not of Vdd node and Vss node can be isolated from the underlying semiconductive layers 248a and 248b and the underlying power supply voltage line B-M1-Vdd/B-M1-Vss. In some embodiments, the dielectric layer 249 and/or the semiconductive layer 259 can be interchangeably referred to a dielectric barrier layer or a leakage barrier.

As shown in FIGS. 3E and 3G, the semiconductive layers 248a and 248b are formed to underlie the semiconductive sheet 210 and extending along a lengthwise direction of the semiconductive sheet 210. Specifically, the semiconductive layer 248a/248b is formed as a fin-like structure underlying the semiconductive sheet 210. In some embodiments, the semiconductive layer 248a/248b may be a pure semiconductor layer without dopant. In some embodiments, the semiconductive layer 248a/248b may be doped with a dopant having a same conductivity type as the source/drain region 218a/218b formed subsequently overlying thereof, and the dopant can be either n-type or p-type doping species. In some embodiments, the semiconductive layer 248a/248b may be doped with a dopant having a different conductivity type than the source/drain region 218a/218b formed subsequently overlying thereof, and the dopant can be either n-type or p-type doping species. In some embodiments, the semiconductive layer 248a/248b overlaps the semiconductive sheet 210 and extends beyond opposite two edge of the semiconductive sheet 210. In some embodiments, the semiconductive layer 248a/248b may have a thickness T2 in a range from about 10 nm to about 100 nm, such as about 10, 20, 30, 40, 50, 60, 70, 80, 90, or 100 nm. In some embodiments, the semiconductive layer 248a/248b extends from one of the dielectric-base gates 225 across the gate electrodes 220 to another one of the dielectric-base gates 225. In some embodiments, the semiconductive layer 248a/248b can be interchangeably referred to as a bottom silicon region, a doped silicon layer, a semiconductor strip, a fin, fin structure, or a fin pattern.

In FIGS. 3B and 3C, the STI structure 251 can be formed to laterally surround the semiconductive layer 248a/248b. In some embodiments, the STI structure 251 is located between NMOSFET and PMOSFET. In some embodiments, the top surface of the STI structure 251 is coplanar (within process variations) with a front-side surface 248f/248s of the semiconductive layer 248a/248b. In some embodiments, the top surface of the STI structure 251 is above or below the front-side surface 248f/248s of the semiconductive layer 248a/248b. In some embodiments, the STI structure 251 may separate the features of adjacent devices.

In some embodiments, a back-side dielectric layer 331 is formed over a back-side surface of the STI structure 251 and back-side surfaces 248c and 248k of the semiconductive layers 248a and 248b. In some embodiments, the back-side dielectric layer 331 can have a thickness T9 (see FIG. 3A) in a range from about 3 nm to about 30 nm, such as about 3, 4, 6, 7, 8, 10, 12, 14, 16, 18, 20, 22, 24, 26, 28, or 30 nm. In some embodiments, the back-side dielectric layer 331 may be made of dielectric material. In some embodiments, the semiconductive layer 248a/248b can be partially broken by the dielectric-base gates 225, not fully broken by the dielectric-base gates 225. In some embodiments, the dielectric-base gate 225 can penetrate the semiconductive layer 248a/248b and is in contact with the back-side dielectric layer 331. In some embodiments, the dielectric-base gate 225 can have an extension depth in the semiconductive layer 248a/248b. That is, the dielectric-base gate 225 can have a vertical dimension as the thickness T2 of the semiconductive layer 248a/248b. In some embodiments, the back-side power supply voltage line B-M1-Vdd/B-M1-Vss can be formed over a back-side surface 331b of the back-side dielectric layer 331.

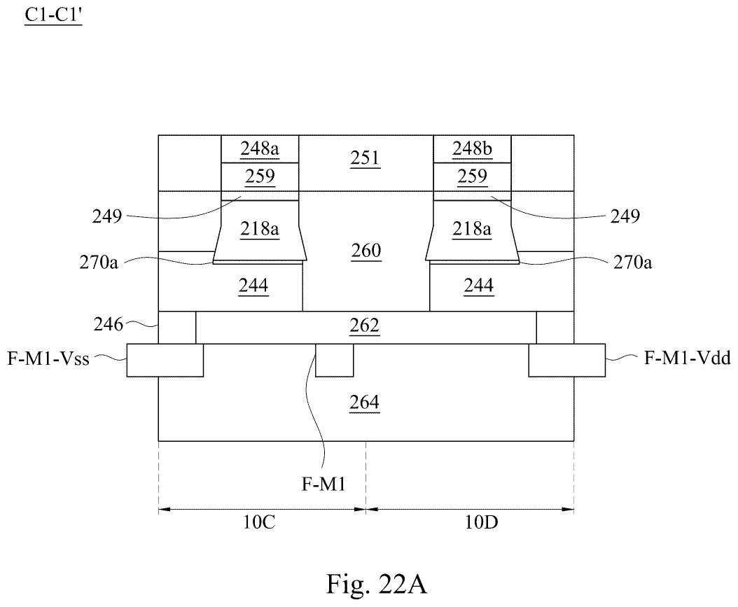

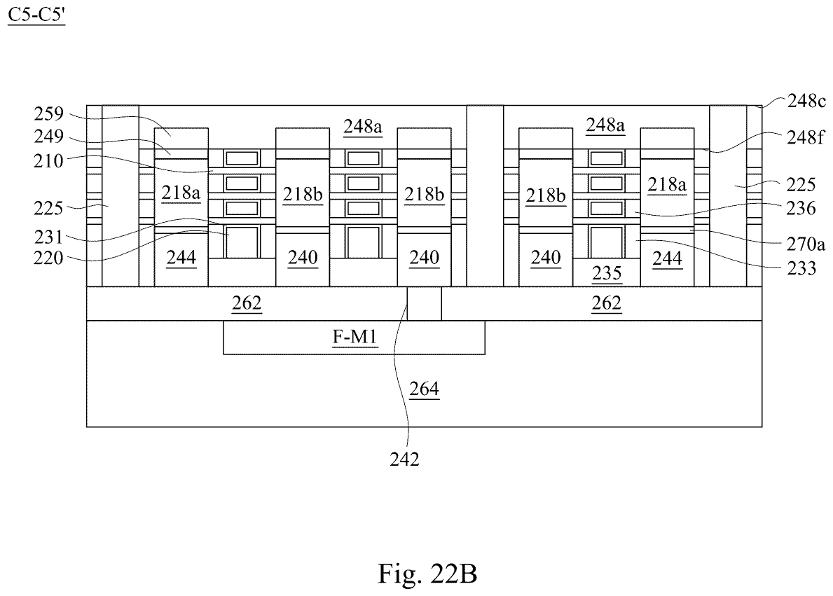

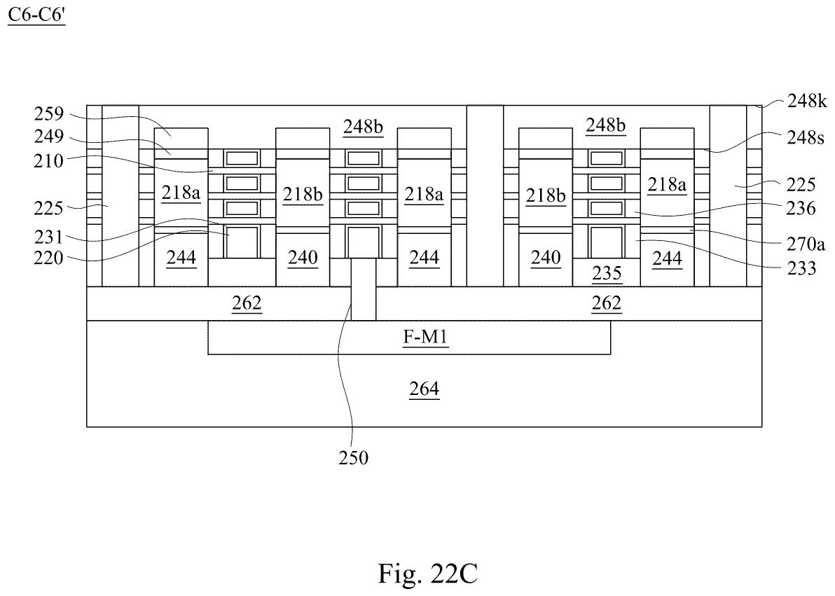

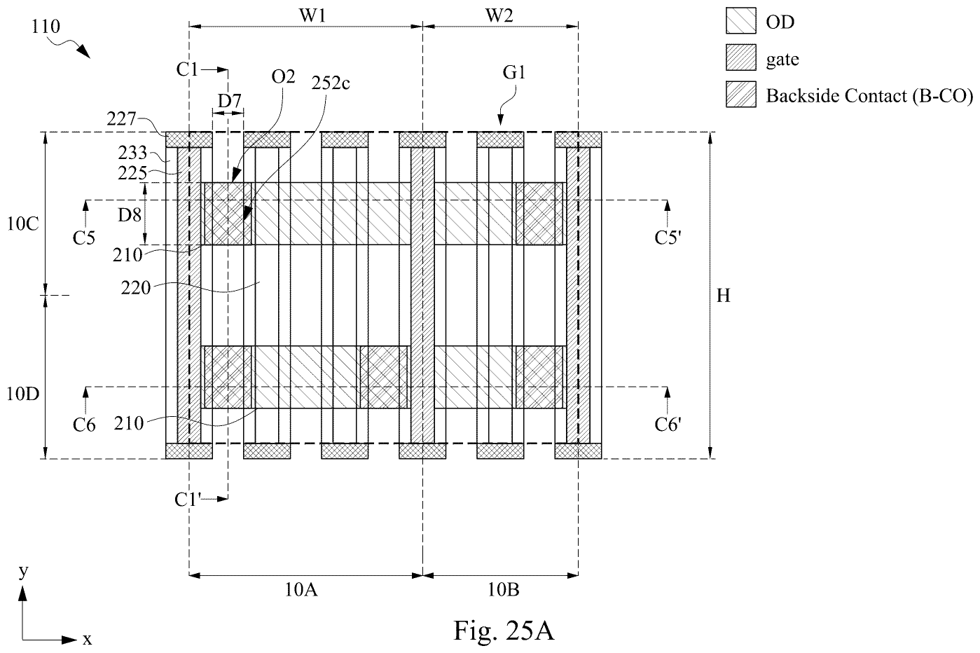

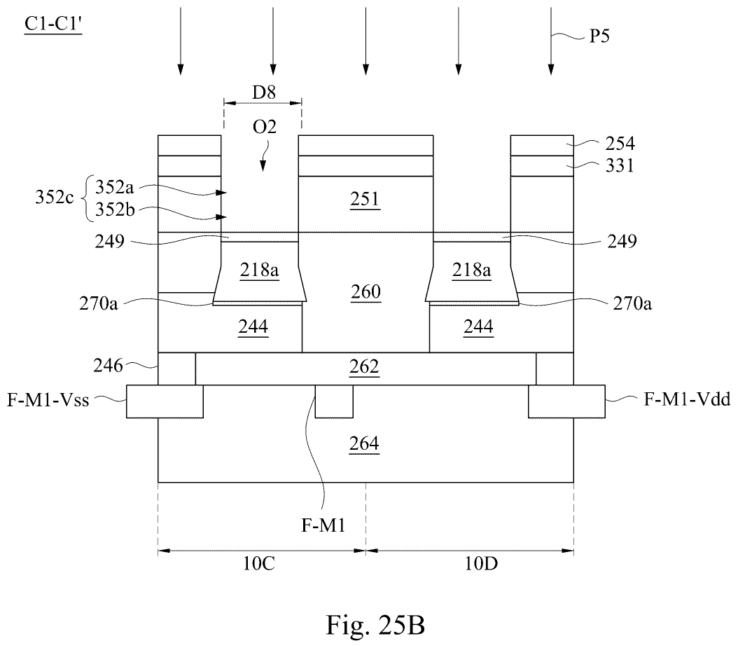

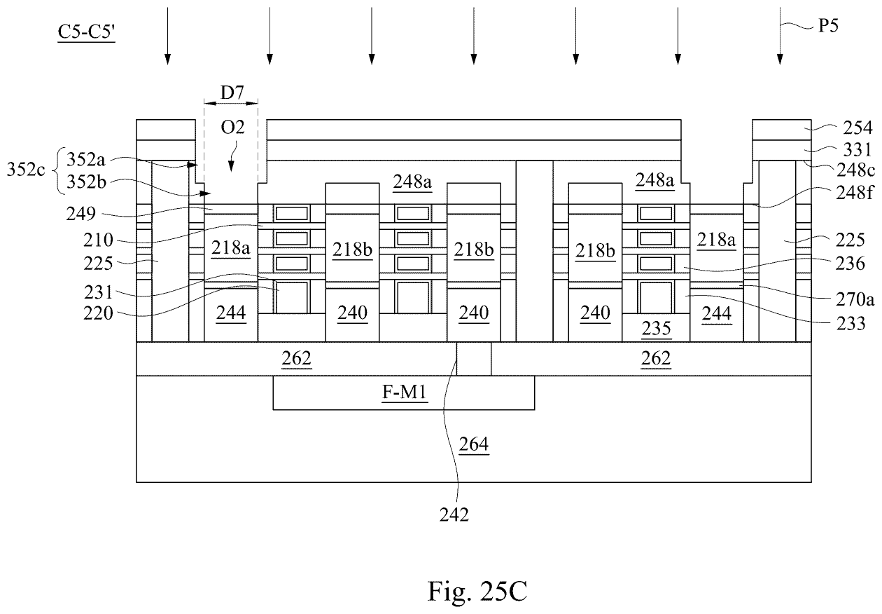

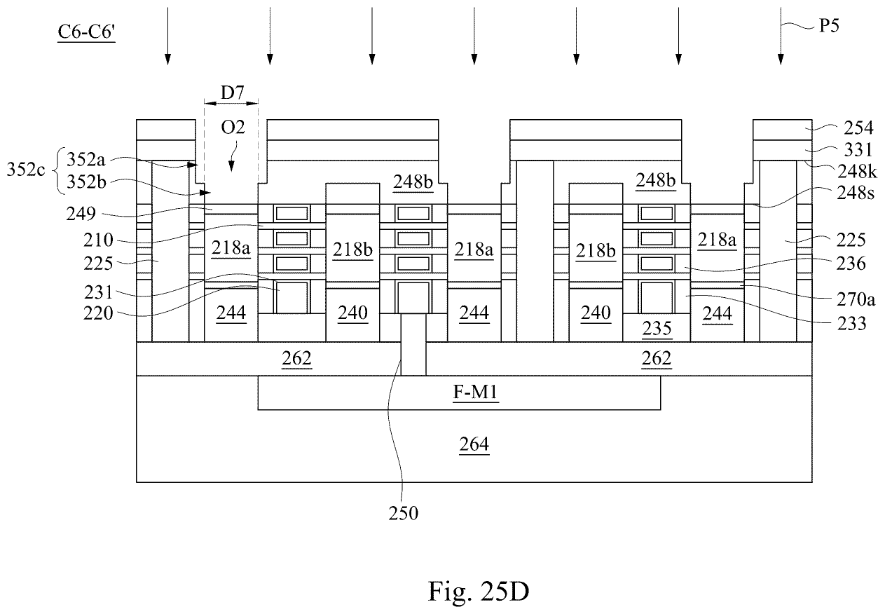

As shown in FIGS. 3E and 3G, the dielectric layers 249 are formed to electrically isolate the Vdd node and Vss node from the underlying semiconductive layers 248a and 248b. A semiconductive layer 259 can be formed to sandwich between the dielectric layer 249 and the semiconductive layer 248a/248b. When the contact 252 is formed from the back side of the semiconductor structure (see FIGS. 22A-27C), the semiconductive layer 259 can be selectively removed (see FIGS. 25A-25D) so that the source/drain region 218a originally located above the semiconductive layer 259 can be self-aligned with the contact 252 when the conductive material is later filled to form the contact 252. In some embodiments, the semiconductive layer 259 can be interchangeable referred to as a sacrificial layer. By way of example but not limiting the present disclosure, the semiconductive layer 259 can be made of silicon germanium.

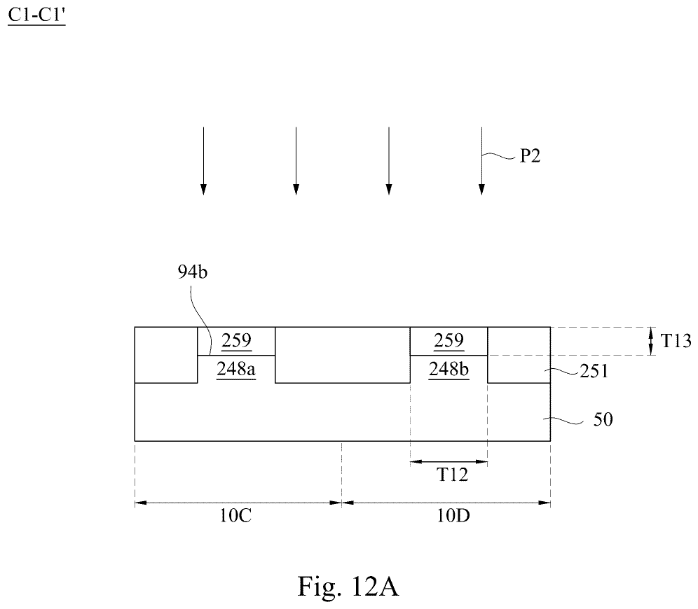

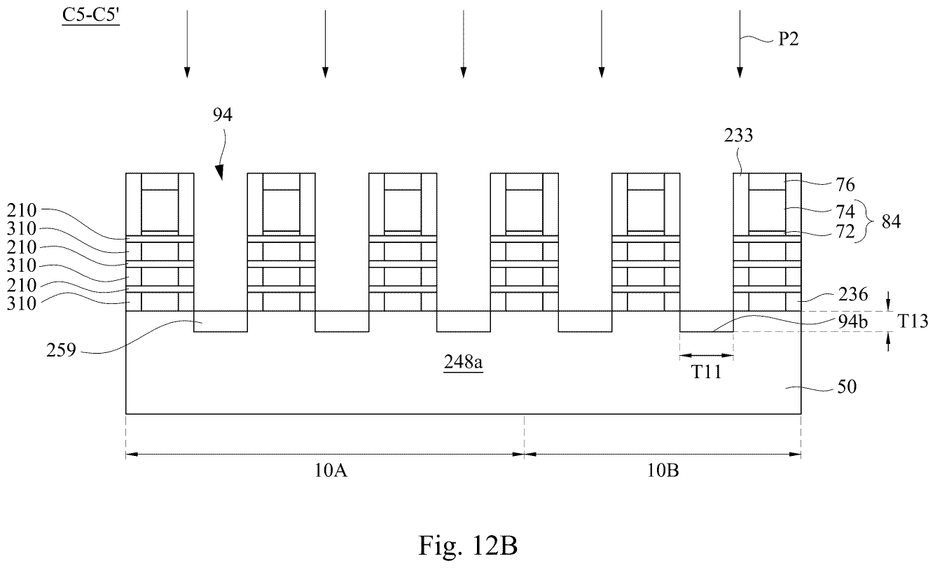

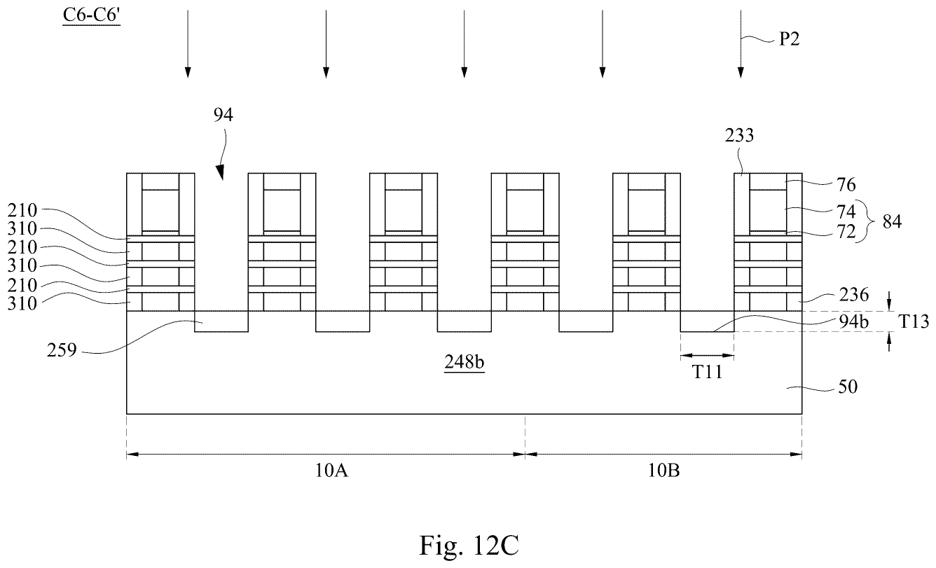

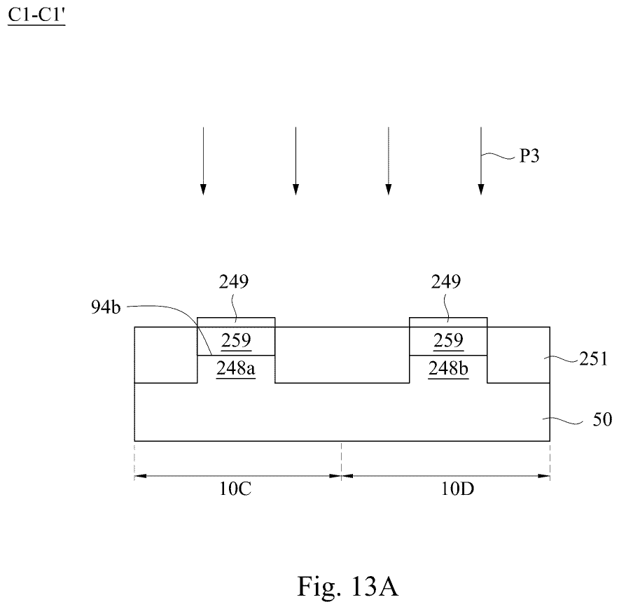

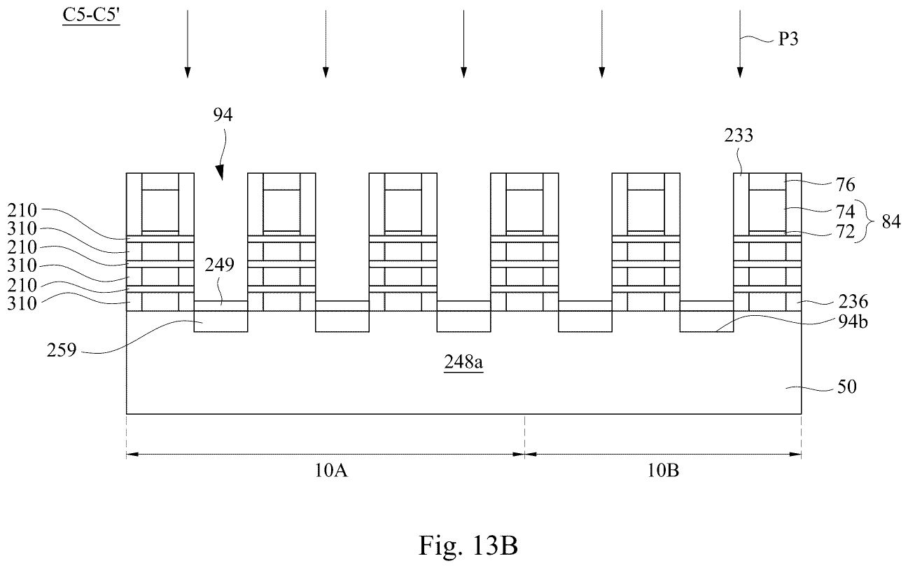

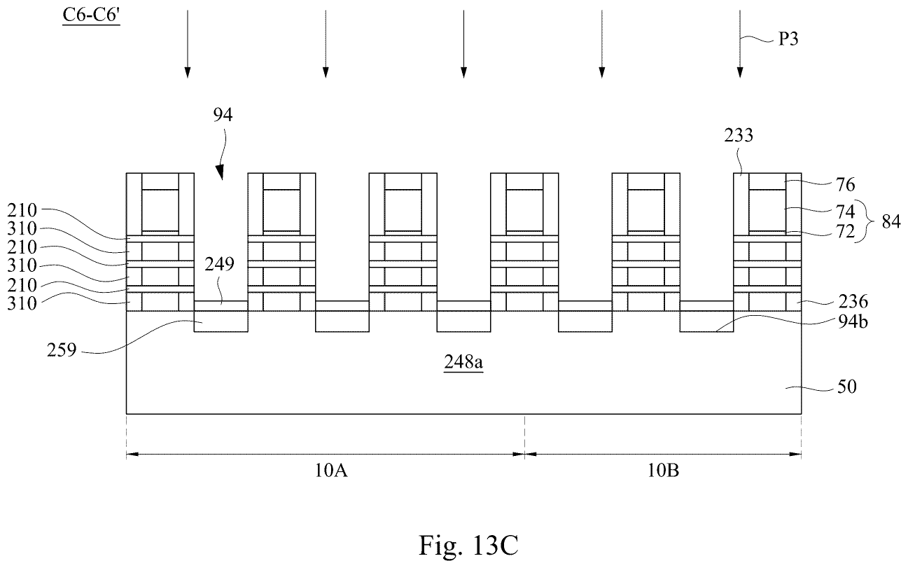

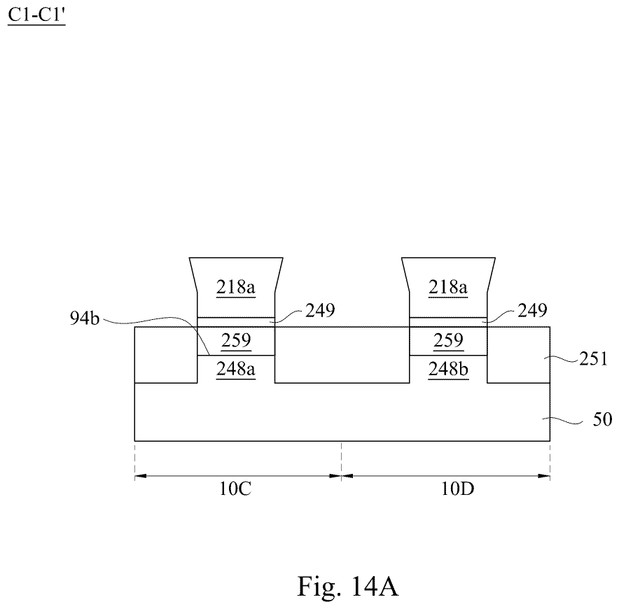

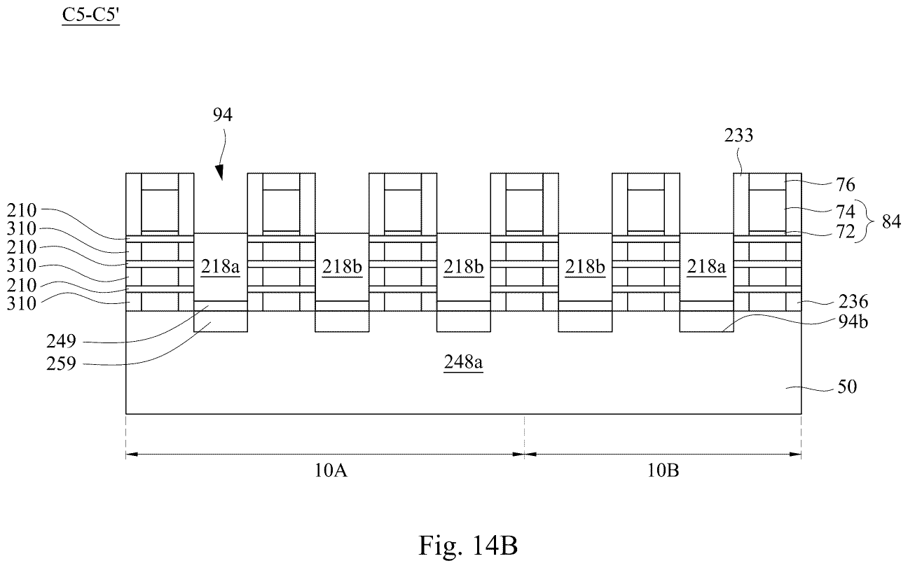

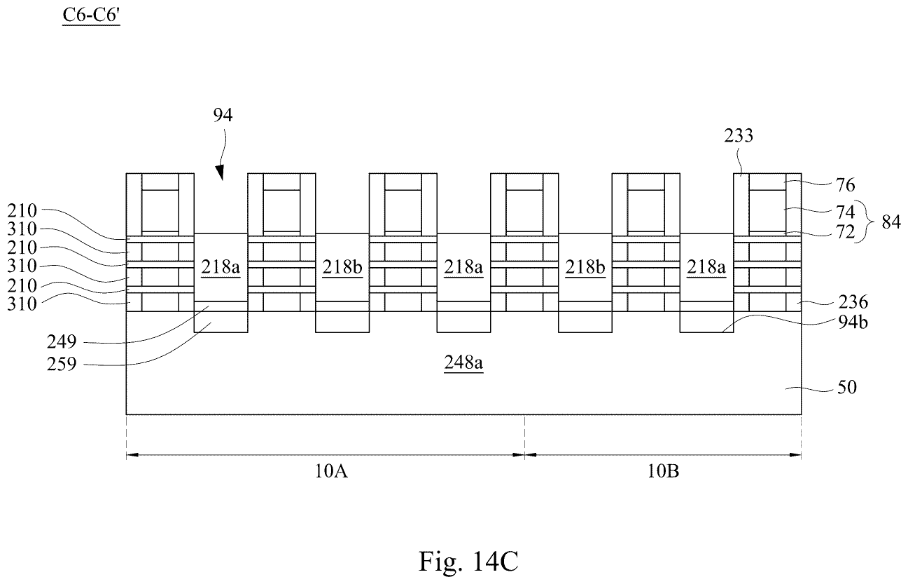

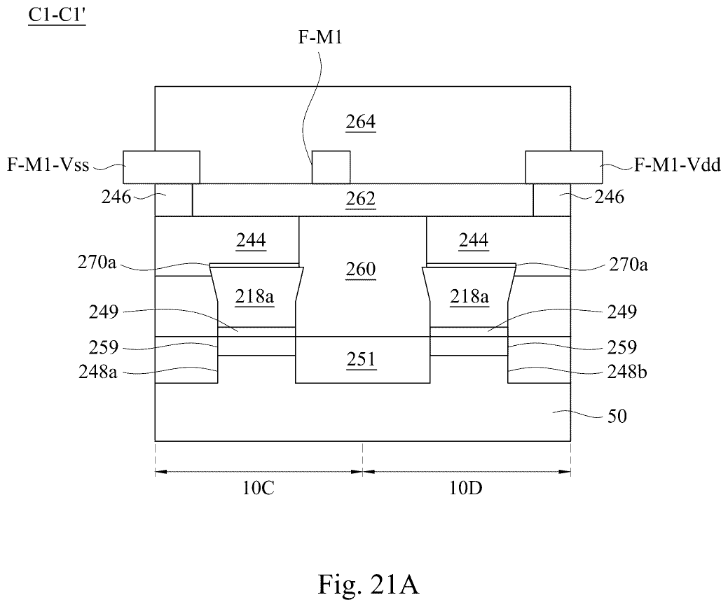

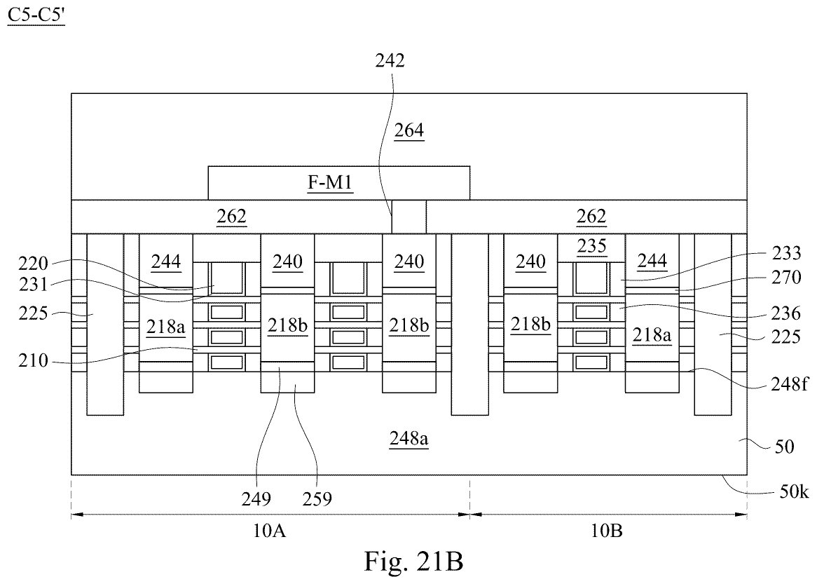

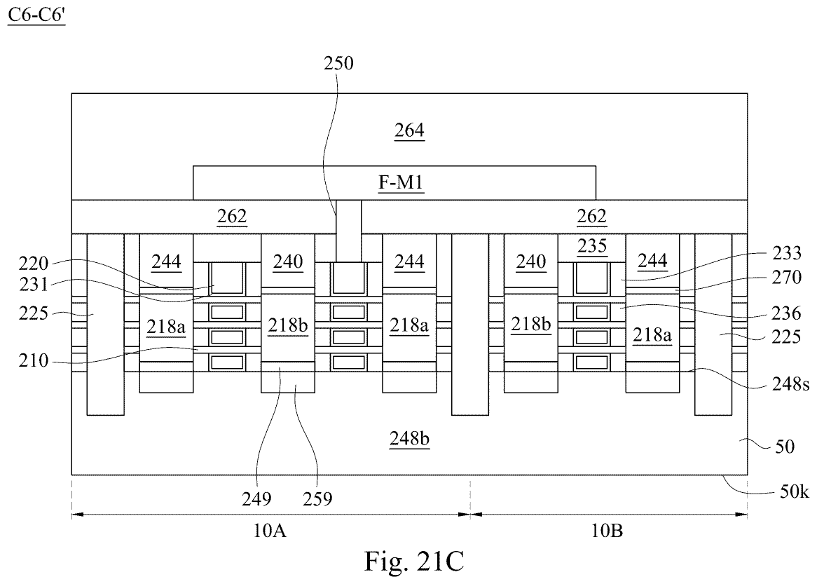

Specifically, the semiconductive layer 259 (see FIGS. 12A-12C) can be selective formed on all of the bottoms 94b of the source/drain recess 94 where source/drain regions 218a and 218b will be subsequently formed thereon. The dielectric layers 249 (see FIGS. 13A-13C) can be selective formed on the semiconductive layer 259. The source/drain region 218a/218b (see FIGS. 14A-14C) can be formed on the semiconductive sheet 210 and vertically self-aligns with the dielectric layers 249 in the source/drain recess 94. Subsequently, a substrate 50 (see FIGS. 21A-21C) underlying the semiconductive layers 248a and 248b of the semiconductor structure may be removed (see FIGS. 22A-22C) in one or more removing processes from the back-side of the semiconductor structure to expose the STI structure 251 (see FIG. 22A) and the semiconductive layers 248a, 248b (see FIGS. 22A-22C), in which the STI structure 251 and/or the semiconductive layer 248a/248b can act as an etch stop layer.

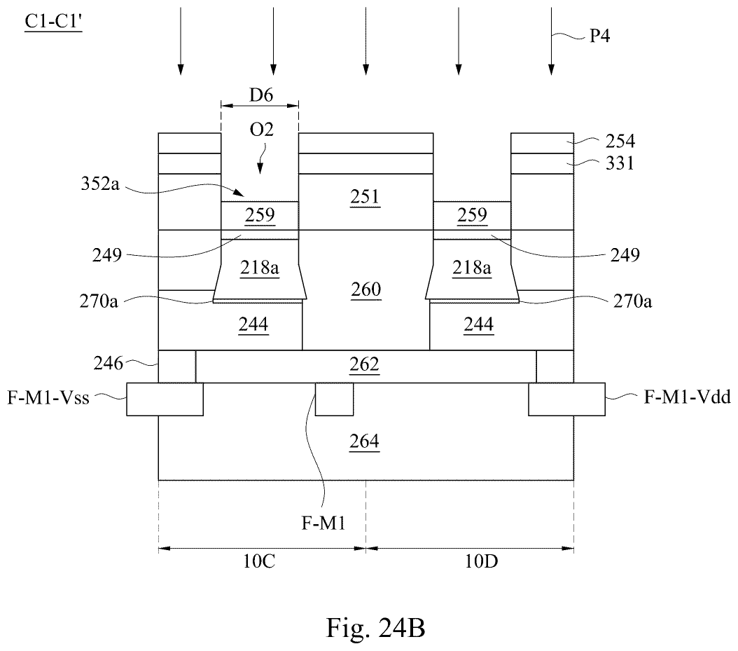

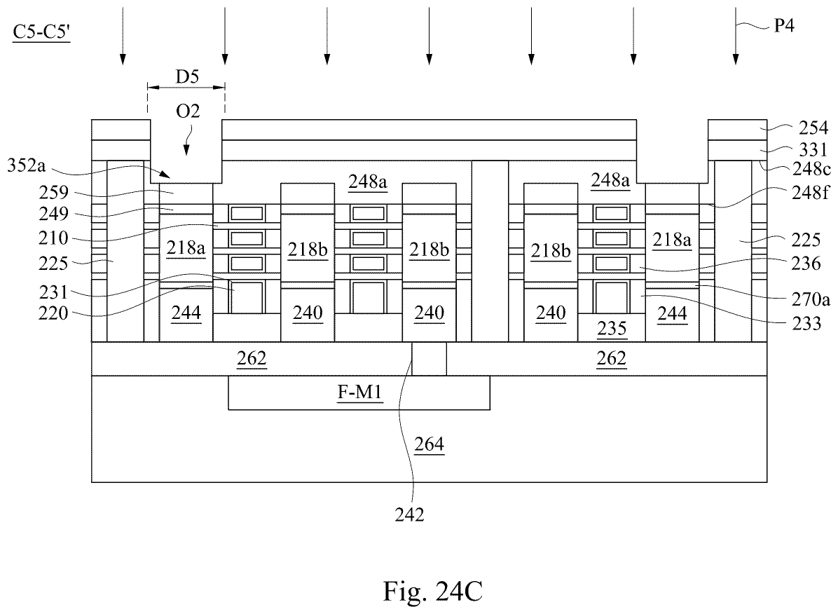

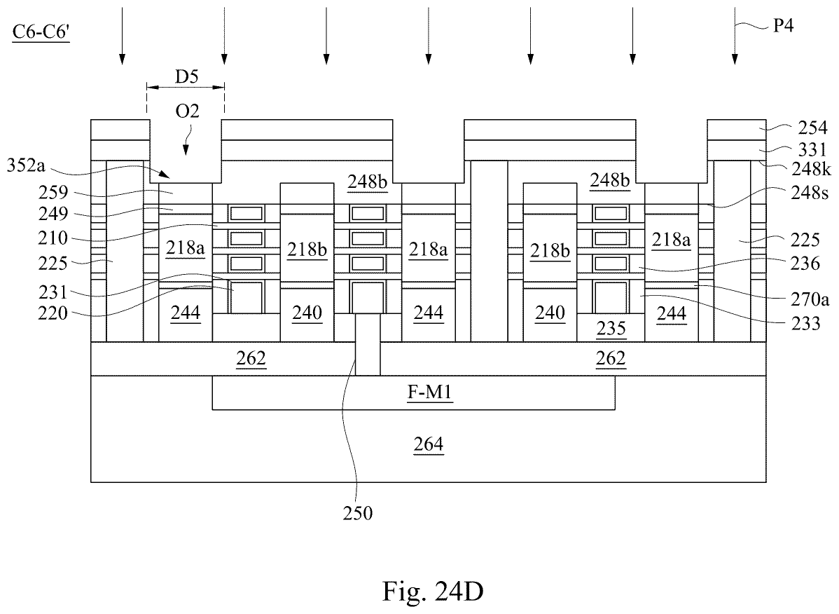

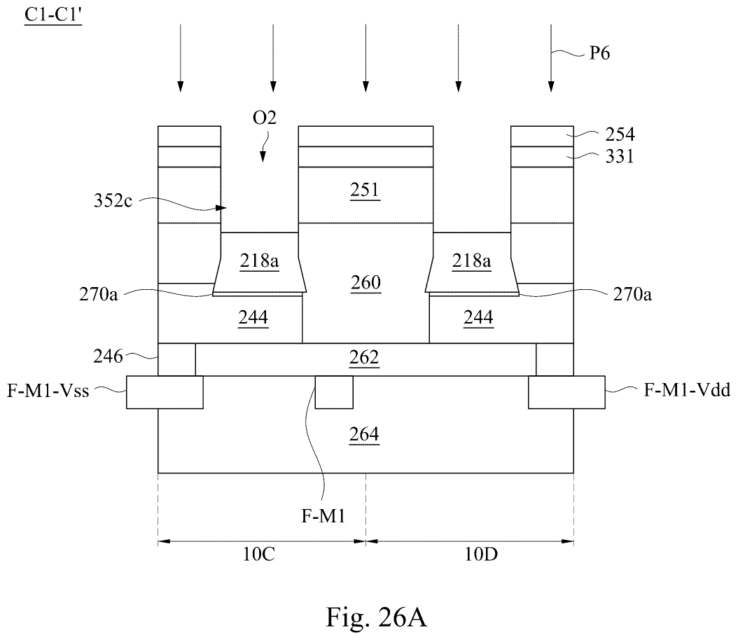

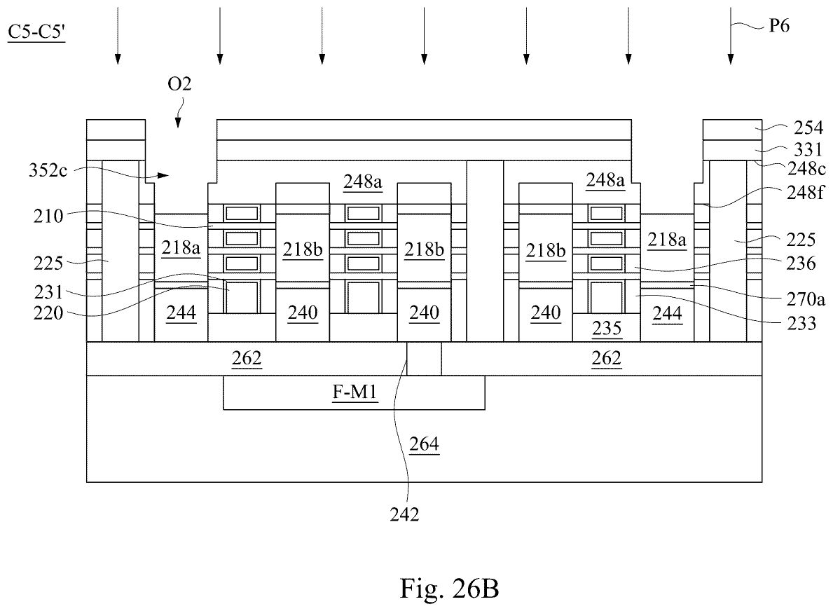

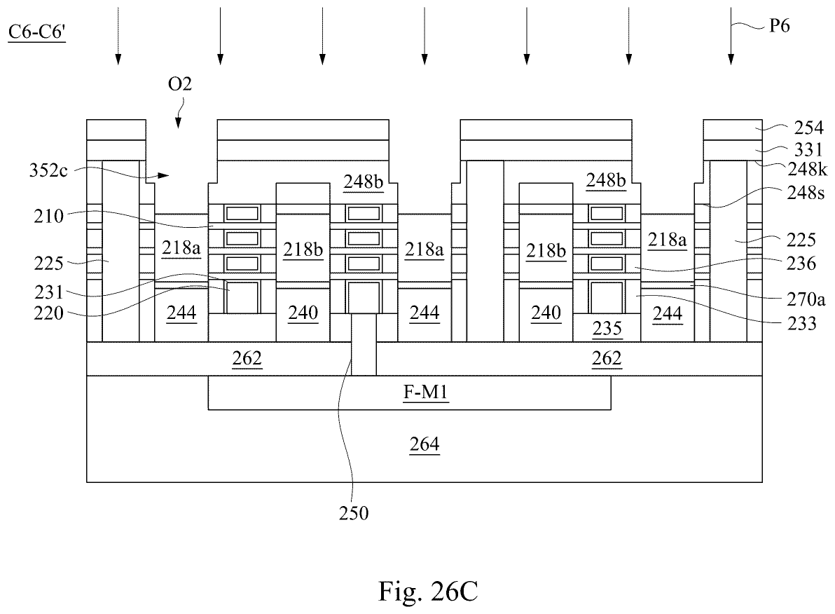

Subsequently, the semiconductive layer 259 and the dielectric layers 249 included in the Vdd node and the Vss node can be removed from the bask-side of the semiconductor structure to expose the source/drain regions 218a (see FIGS. 26A-26C). Specifically, firstly, a mask layer 254 (see FIGS. 24B-24D) may be formed over the back-side surface 331b of the back-side dielectric layer 331. The mask layer 254 can be patterned to have openings O2 (see FIGS. 24B-24D) overlapping the source/drain regions 218a. In some embodiments, the opening O2 (see FIG. 24A) on the mask layer 254 may have a dimension D5 (see FIG. 24A) in parallel with a lengthwise direction of the semiconductive sheet 210, and a dimension D6 (see FIG. 24A) in parallel with a lengthwise direction of the gate electrode 220 from the top view. As shown in FIGS. 24C and 24D, the dimension D5 of the opening O2 may be greater than a width of the source/drain regions 218a in the lengthwise direction of the semiconductive sheet 210, such that the opening O2 can overlap the gate spacer 233 and/or the gate electrode 220 from the top view. In some embodiments, as shown in FIG. 24B, the dimension D6 of the opening O2 may be the same as a width of the semiconductive sheet 210.

Subsequently, a first etching process P4 (see FIGS. 24B-24D) can be performed through the openings O2 to remove portions of the back-side dielectric layer 331 and the semiconductive layer 248a/248b, in which the semiconductive layer 259 can act as an etch stop layer. Subsequently, an etching process P5 (see FIGS. 25B-25D) can be performed through the openings O2 to remove the semiconductive layer 259, in which the dielectric layer 249 can act as an etch stop layer. Subsequently, a third etching process P6 (see FIGS. 26A-26C) can be performed through the openings O2 to remove the dielectric layer 249, in which the source/drain regions 218a can act as an etch stop layer, such that an back-side contact opening 252p can be formed to inherit the shape of the semiconductive layer 259 and the dielectric layer 249 and self-align with the source/drain region 218a.

In some embodiments, the semiconductive layer 259 may be made of a material that has a high etching selectivity relative to the dielectric layer 249 and the STI structure 251. For example, the etching selectivity, which is the ratio of the etching rate of the semiconductive layer 259 to the dielectric layer 249 and the STI structure 251, is greater than about 10 when the semiconductive layer 259 are etched. In some embodiments, the dielectric layer 249 may be made of a material that has a high etching selectivity relative to the source/drain regions 218a and the STI structure 251. For example, the etching selectivity, which is the ratio of the etching rate of the dielectric layer 249 to the source/drain region 218a and/or the STI structure 251, is greater than about 10 when the dielectric layers 249 are etched.

Subsequently, the back-side contact 252 (see FIGS. 3A, 3E and 3G) can be formed in the back-side contact opening 252p, and the source/drain region 218a can be electrically connected to the back-side metal line (e.g., power supply voltage lines B-M1-Vss, B-M1-Vdd) through the back-side contact 252 acting a power conductor path. Because the back-side contact opening 252p can be formed to inherit the shape of the semiconductive layer 259 and the dielectric layer 249 directly underlying the source/drain regions 218a, the contact 252 formed in the contact opening 252p can self-align with the source/drain regions 218a and on the back-side of the source/drain region 218a. Therefore, the back-side contact 252 can be interchangeably referred to as a self-aligned connection structure, and the intermediate stages in the formation of the semiconductor structure shown in FIGS. 12A-14C and 24A-27C can be referred to as a self-aligned contact process. As shown in FIGS. 3A, 3E, and 3H, the contact 252 can penetrate through the STI structure 251 and the back-side dielectric layer 331 when viewed in the cross section as shown in FIG. 3A and penetrate through the semiconductive layer 248a/248b when viewed in the cross section as shown in FIG. 3E or FIG. 3G.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. For example, in a cell routing of the IC structure, Vdd and Vss power routing may occupy too many routing resources and therefore impact the cell scaling as well as the performance of the IC structure (e.g., RC delay or IR drop). Hence, a part of power lines and power conductive contacts are moved to wafer back-side, so as to reduce the routing loading and improve the circuit density in a same chip area. Nevertheless, the power conductive contact on the wafer back-side may not be aligned with the source/drain region when forming thereof, which in turn non-overlaps with the source/drain region and/or overlaps with the gate, such that an unwanted connection may occur and therefore impacts the performance of IC structure. In some embodiments, the power conductive contact can be interchangeably referred to the back-side contact 252.

Therefore, the present disclosure in various embodiments provides a metal line routing method to improve the functional density and operation performance on the IC structure. Because the back-side contact 252 (i.e., power conductive contact) can be formed to inherit the location of the semiconductive layer 259 and the dielectric layer 249 directly underlying the source/drain region 218a, the back-side contact 252 can self-align with the source/drain region 218a to connect the source/drain region 218a to the back-side power metal layers (e.g., power supply voltage line Vdd/Vss). Hence, an isolation margin issue of the back-side contact 252 to gate electrode 220 can be solved, which in turn allows for scaling the contacted poly pitch (CPP).

In addition, because the back-side contact 252 can have a back-side portion having wider width than the front-side portion thereof to connect the back-side power metal layers, an improved contact resistance between the source/drain region 218a and the back-side power metal layers can be achieved. In some embodiments, the back-side portion of the back-side contact 252 can vertically overlap with the dielectric-base gate 225, the gate spacer 233, and/or the inner spacer 236. Furthermore, the power conductor path including the source/drain region 218a and the semiconductive layer 248a/248b doped with a same dopant as the source/drain region 218a can save an extra strap area (i.e., an area for connecting back-side metal to front-side metal) and hence additional connection process and cost, and thus a functional density of the IC structure can be improved. Moreover, the power mesh (e.g., power supply voltage line B-M1-Vdd/B-M1-Vss) in the wafer back-side can be located at a lower level metal layer (e.g., back-side M1 level), and thus the IC structure can have a more robustness power mesh in the cell region.

In some embodiments, a front-side silicide layer 270a can be formed between the source/drain contacts 240 and the source/drain regions 218b and/or between the power supply voltage contacts 244 and the source/drain regions 218a for Rc reduction. In some embodiments, a back-side silicide layer 270b can be formed between the back-side contact 252 and the source/drain regions 218a for Rc reduction. In some embodiments, the back-side silicide layer 270b can laterally surround the back-side contact 252 and interposes between the back-side contact 252 and the semiconductive layer 248a/248b.

Throughout the description, the notations of metal lines may be followed by the metal line levels they are in, wherein the respective metal line level is placed in parenthesis. As shown in FIG. 2B, metal lines disposed at the M1 level on the back-side of the semiconductor structure may include the power supply voltage lines B-M1-Vdd, and B-M1-Vss. The metal lines disposed at the M1 level on the back-side of the semiconductor structure may have lengthwise directions parallel to the X-direction (e.g., column direction) and perpendicular to a lengthwise direction of the gate electrode layer 220. In some embodiments, the power supply voltage line B-M1-Vss/B-M1-Vdd disposed at the M1 level on the back-side of the semiconductor structure can be interchangeably referred to a power supply voltage landing pad or a power supply voltage landing line. In some embodiments, the lines can be interchangeably referred to metal layers, conductive lines, conductive layers, or conductors.

The back-side power supply voltage line B-M1-Vdd/B-M1-Vss can be electrically connected to the front-side power supply voltage line F-M1-Vdd/F-M1-Vss through the back-side contact 252, the source/drain region 218a (see FIGS. 3A, 3E, and 3G), the front-side power supply voltage contact 244, and the front-side conductive via 246. In some embodiments, the back-side power supply voltage line B-M1-Vdd/B-M1-Vss and the back-side contact 252 can be either single damascene scheme or dual damascene scheme. In some embodiments, the back-side power supply voltage line B-M1-Vdd/B-M1-Vss may be made of a same material as the back-side contact 252. In some embodiments, the back-side power supply voltage line B-M1-Vdd/B-M1-Vss may be made of a different material than the back-side contact 252. In some embodiments, materials of the power supply voltage lines F-M1, F-M1-Vdd, F-M1-Vss, B-M1-Vdd, B-M1-Vss, the conductive vias 242, 246, and/or the contacts 240, 244 of the semiconductor structure may be made of Cu, Co, Ru, Pt, Al, W, Ti, TaN, TiN, Molybdenum (Mo), Ruthenium (Ru), Iridium (Ir), rhodium (Rh), or any combinations thereof. In some embodiments, the back-side power supply voltage line B-M1-Vdd/B-M1-Vss has a length in a range from about 200 nm to about 200 μm.

In some embodiments, the semiconductor structure can further includes conductive lines (e.g. power supply voltage line VDD/VSS) at the M2 level on the back-side of the semiconductor structure and extending along a direction perpendicular to the lengthwise direction of the back-side power supply voltage line B-M1-Vdd/B-M1-Vss. The power supply voltage line (e.g., Vdd) at the M2 level on the back-side of the semiconductor structure can be electrically connected to the back-side power supply voltage line B-M1-Vdd, and the power supply voltage line (e.g., Vss) at the M2 level on the back-side of the semiconductor structure can be electrically connected to the back-side power supply voltage line B-M1-Vss.

In some embodiments, NMOSFET including N+ doped (e.g., phosphorus) source/drain region 218a is upon an n-type semiconductive layer 248a, and PMOSFET including P+ doped (e.g., boron) source/drain region 218a is upon a p-type semiconductive layer 248b. This is described in greater detail with reference to FIG. 3E, the semiconductive layers 248a in the first conductivity type device region 10C have a same conductivity type as the source/drain regions 218a in the first conductivity type device region 10C. By way of example but not limiting the present disclosure, if the source/drain region 218a in the first conductivity type device region 10C is formed with an n-type dopant, the semiconductive layer 248a is dopant with the n-type dopant. In some embodiments, the semiconductive layer 248a in the first conductivity type device region 10C may include SiP, SiC, SiPC, SiAs, Si, or a combination thereof. In some embodiments, the semiconductive layer 248a in the first conductivity type device region 10C may have a phosphorus concentration within a range from about 5×10¹⁶ atoms/cm³ to about 1×10¹⁹ atoms/cm³.

With reference to FIG. 3G, the semiconductive layers 248b in the second conductivity type device region 10D have a same conductivity type as the source/drain regions 218a in the second conductivity type device region 10D. By way of example but not limiting the present disclosure, if the source/drain region 218a in the second conductivity type device region 10D is formed with a p-type dopant, the semiconductive layer 248b is dopant with the p-type dopant. In some embodiments, the semiconductive layer 248b in the second conductivity type device region 10D may include boron, BF₂, or a combination thereof. In some embodiments, the semiconductive layer 248b in the second conductivity type device region 10D may have a boron concentration within a range from about 5×10¹⁶ atoms/cm³ to about 1×10¹⁹ atoms/cm³.

In some embodiments, NMOSFET including N+ doped (e.g., phosphorus) source/drain region 218a is upon an p-type semiconductive layer 248a, and PMOSFET including P+ doped (e.g., boron) source/drain region 218a is upon a p-type semiconductive layer 248b. This is described in greater detail with reference to FIG. 3E, the semiconductive layers 248a in the first conductivity type device region 10C have a same conductivity type as the source/drain regions 218a in the first conductivity type device region 10C. By way of example but not limiting the present disclosure, if the source/drain region 218a in the first conductivity type device region 10C is formed with an n-type dopant, the semiconductive layer 248a is dopant with the n-type dopant. In some embodiments, the semiconductive layer 248a in the first conductivity type device region 10C may include SiP, SiC, SiPC, SiAs, Si, or a combination thereof. In some embodiments, the semiconductive layer 248a in the first conductivity type device region 10C may have a phosphorus concentration within a range from about 5×10¹⁶ atoms/cm³ to about 1×10¹⁹ atoms/cm³.

In some embodiments, NMOSFET including N+ doped (e.g., phosphorus) source/drain region 218a is upon an n-type semiconductive layer 248a, and NMOSFET including P+ doped (e.g., boron) source/drain region 218a is upon a p-type semiconductive layer 248b. This is described in greater detail with reference to FIG. 3E, the semiconductive layers 248a in the first conductivity type device region 10C have an opposite conductivity type to the source/drain regions 218a in the first conductivity type device region 10C. By way of example but not limiting the present disclosure, if the source/drain region 218a in the first conductivity type device region 10C is formed with an n-type dopant, the semiconductive layer 248a in the first conductivity type device region 10C is dopant with the p-type dopant. In some embodiments, the semiconductive layer 248a in the first conductivity type device region 10C may include boron, BF₂, or a combination thereof. In some embodiments, the semiconductive layer 248a in the first conductivity type device region 10C may have a boron concentration within a range from about 5×10¹⁶ atoms/cm³ to about 1×10¹⁹ atoms/cm³.

With reference to FIG. 3G, the semiconductive layers 248b in the second conductivity type device region 10D have an opposite conductivity type to the source/drain regions 218a in the second conductivity type device region 10D. By way of example but not limiting the present disclosure, if the source/drain region 218a in the second conductivity type device region 10D is formed with a p-type dopant, the semiconductive layer 248b is dopant with an n-type dopant. In some embodiments, the semiconductive layer 248b in the second conductivity type device region 10D may include SiP, SiC, SiPC, SiAs, Si, or a combination thereof. In some embodiments, the semiconductive layer 248b in the second conductivity type device region 10D may have a phosphorus concentration within a range from about 5×10¹⁶ atoms/cm³ to about 1×10¹⁹ atoms/cm³.

In FIGS. 2A, 2B, 3C, 3D, and 3J, dielectric regions 227 are formed on opposite ends of the gate electrode layers 220. In some embodiments, each dielectric region 227 is a gate-cut structure for the gate structure, and the gate-cut structure is formed by a cut metal gate (CMG) process. In some embodiments, the dielectric region 227 may be made of dielectric material, such as SiO₂, Si₃N₄, SiON, SiOC, SiOCN base dielectric material, or combinations thereof. In some embodiments, the dielectric region 227 may be made of an oxide, a nitride-based material, such as Si₃N₄, SiON, or a carbon-based material, such as SiC, SiOC, SiOCN, or combinations thereof. In some embodiments, the dielectric region 227 may be made of a material having a dielectric constant greater than about 9 (e.g., high dielectric constant (high-k) material). For example, the dielectric region 227 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

In FIGS. 2A, 2B, 3E, 3G, and 3I, gate spacers 233 are formed on the sidewalls of the gate electrode layers 220. In some embodiments, the gate spacer 233 may be made of silicon nitride or silicon oxynitride, although any suitable material, such as low-dielectric constant (low-k) materials having a k-value less than about 3.5, may be utilized. In FIGS. 3E and 3G, inner spacers 236 can act as isolation features and may be formed between the source/drain regions 218a and 218b and the gate electrode layers 220. In some embodiments, the inner spacer 236 may have a higher K (dielectric constant) value than the gate spacer 233. In FIGS. 3C, 3E, 3G, and 3I, hard mask layers 235 are formed over the gate electrode layers 220. In some embodiments, the hard mask layer 235 can be interchangeably referred to a gate top dielectric. In some embodiments, the hard mask layer 235 is made of a different material than the dielectric region 227 and/or the dielectric-base gate 225. In some embodiments, the hard mask layer 235 may be made of dielectric material, such as SiO₂, Si₃N₄, SiON, SiOC, SiOCN base dielectric material, or combinations thereof.

In FIGS. 3A, 3B, 3I, and 3J, an inter-layer dielectric (ILD) layer 260 can be formed between the gate electrode layers 220 and over the source/drain regions 218a and 218b. An ILD layer 262 can be formed over the hard mask layers 235 and the ILD layer 260 and laterally surrounds the gate vias 250 and the source/drain vias 242. An inter-metal dielectric (IMD) layer 264 can be formed over the ILD layer 262 and can provide electrical insulation as well as structural support for the various features therein, such as the metal line F-M1, the power supply voltage lines F-M1-Vdd, F-M1-Vss. In some embodiments, the ILD layer 260, the ILD layer 262, and/or the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In FIGS. 3A-3E, 3G, 3I, and 3J, an IMD layer 332 can be deposited over the NMOSFET and PMOSFET from the back-side of the semiconductor structure. The power supply voltage lines B-M1-Vdd, B-M1-Vss are formed in the IMD layer 332. The IMD layer 332 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, the like, or combinations thereof, which may be formed by a chemical vapor deposition (CVD) process, such as high density plasma CVD (HDP-CVD), flowable chemical vapor deposition (FCVD), the like, or a combination thereof.

Reference is made to FIGS. 3F and 3H. FIGS. 3F and 3H illustrate cross-sectional views of a semiconductor structure corresponding to FIGS. 3E and 3G, respectively, according to some embodiments of the present disclosure, in which a back-side contact 352 connecting to the source/drain regions 218a can be a stepped sidewall structure (or two stage-shaped profile structure). While FIGS. 3F and 3H show an embodiment of the semiconductor structure with a different back-side contact profile than the semiconductor structure in FIGS. 3A-3E, 3G, 3I, and 3J. The stepped sidewall structure of the back-side contact 352 can be due to the differences in etching selectivity among various materials used in the process. During the etching phase, where materials are removed to create an opening for the subsequent formation of the back-side contact 352, the large variance in how quickly these materials are etched results in the stepped sidewall structure. This etching behavior, differing from other parts of the process as illustrated in FIGS. 3A-3E, 3G, 3I, and 3J, can be in shaping the specific structural features of the back-side contact 352. In addition, the present disclosure may repeat reference numerals and/or letters in the various examples. This repetition is for the purpose of simplicity and clarity and does not in itself dictate a relationship between the various embodiments and/or configurations discussed.

Specifically, a first etching process P4 (see FIGS. 24B-24D) can be performed through the openings O2 to remove portions of the back-side dielectric layer 331 and the semiconductive layer 248a/248b to form a subsidiary contact opening 352a in the back-side dielectric layer 331 and the semiconductive layer 248a/248b, in which the semiconductive layer 259 can act as an etch stop layer. In some embodiments, the etching process P4 may be an anisotropic dry etch process, such as a dry etch process (e.g., RIE, a NBE, or the like). In some embodiments, the subsidiary contact opening 352a can have a top view profile inheriting the opening O2.

Subsequently, an etching process P5 (see FIGS. 25B-25D) can be performed through the openings O2 to remove the semiconductive layer 259, in which the dielectric layer 249 can act as an etch stop layer, such that a subsidiary contact opening 352b can be formed to inherit the shape of the semiconductive layer 259 and self-align with the source/drain regions 218a. In some embodiments, the subsidiary contact opening 352a and the subsidiary contact opening 352b can be collectively referred to as a back-side contact opening 352c. In some embodiments, the etching process P5 (see FIGS. 25B-25D) may be an anisotropic dry etch process, such as a dry etch process (e.g., RIE, a NBE, or the like) and may employ a different etchant than that used in the etching process P4 (see FIGS. 24B-24D). Subsequently, an etching process P6 (see FIGS. 26A-26C) can be performed through the openings O2 to remove the dielectric layer 249, in which the source/drain regions 218a can act as an etch stop layer.

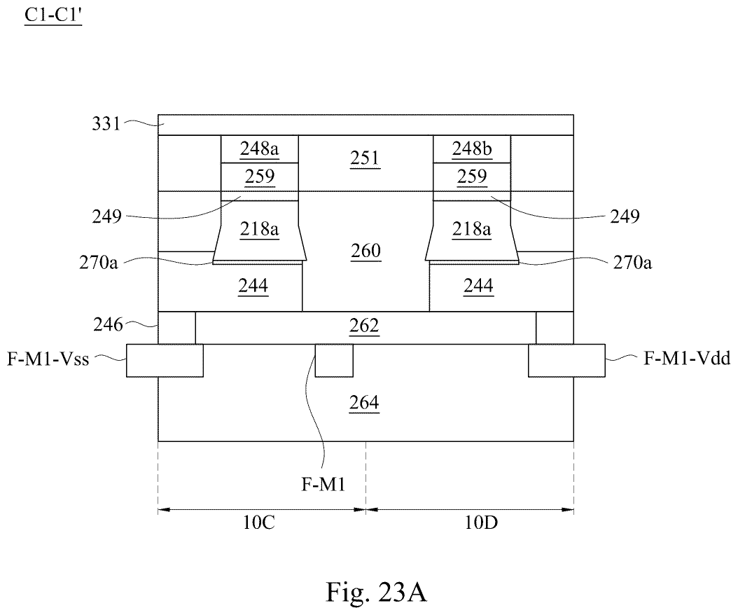

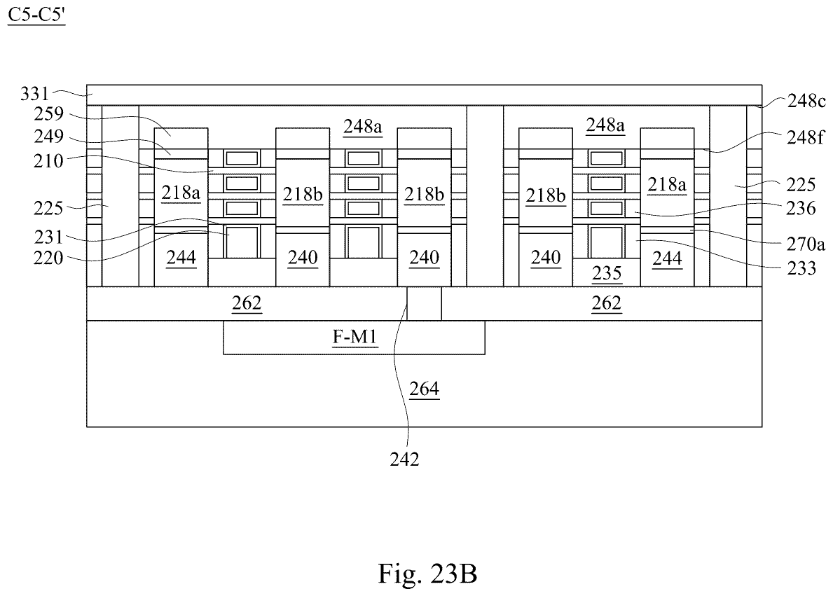

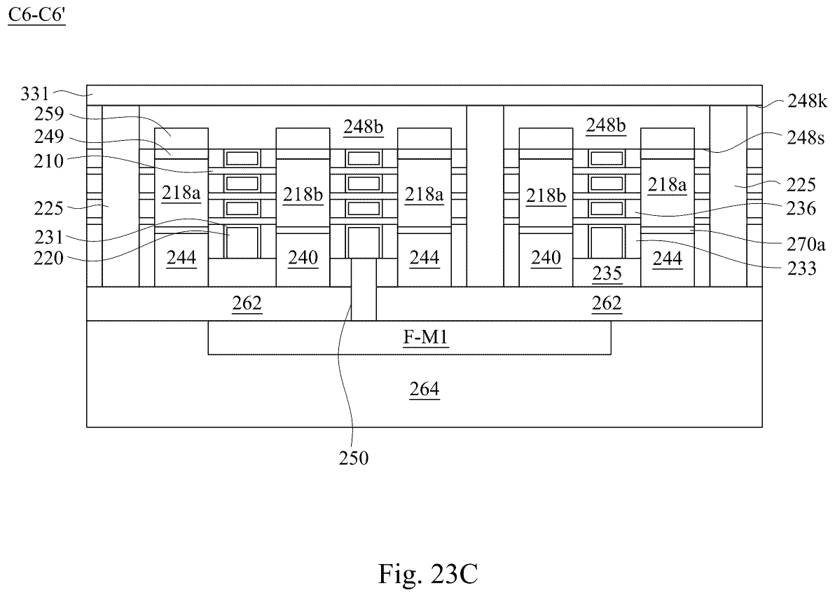

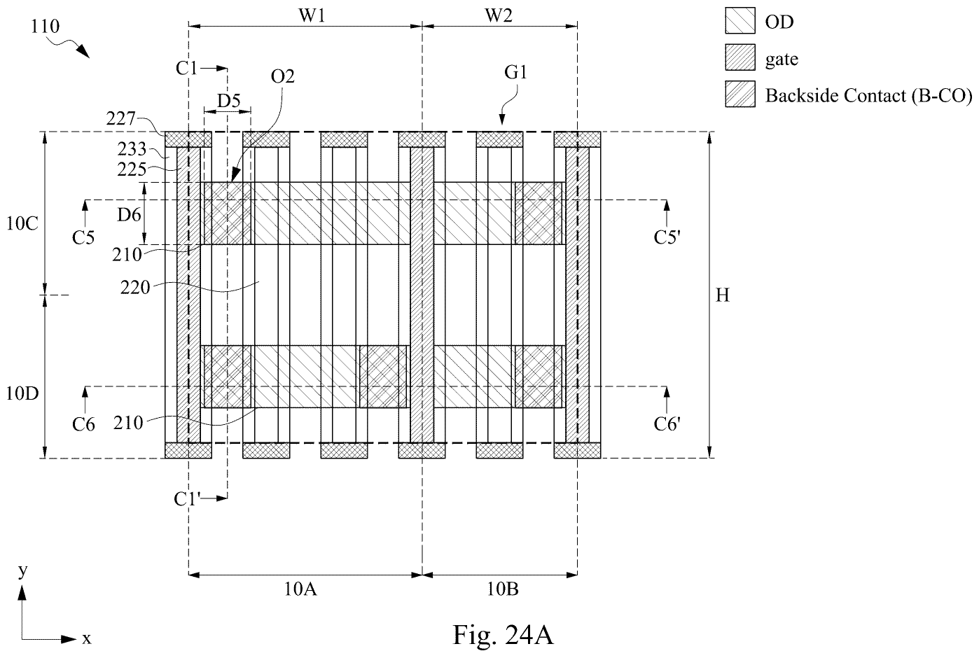

The subsidiary contact opening 352b (see FIG. 25A) may have a dimension D7 in parallel with the lengthwise direction of the semiconductive sheet 210, and a dimension D8 in parallel with the lengthwise direction of the gate electrode 220 from the top view. The dimension D7 of the subsidiary contact opening 352b may be the same as the width of the source/drain regions 218a in the lengthwise direction of the semiconductive sheet 210, such that the subsidiary contact opening 352b non-overlaps with the gate spacer 233 and/or the gate electrode 220 from the top view. The dimension D8 of the subsidiary contact opening 352b may be the same as a width of the semiconductive sheet 210. The dimension D5 (see FIG. 24A) of the subsidiary contact opening 352a is greater than the dimension D7 (see FIG. 25A) of the subsidiary contact opening 352b. By way of example and not limitation, a ratio of dimension D5 of the subsidiary contact opening 352a to the dimension D7 of the subsidiary contact opening 352b can be greater than about 1.3. In some embodiments, the ratio of dimension D5 of the subsidiary contact opening 352a to the dimension D7 of the subsidiary contact opening 352b can be in a range from about 1.3 to about 3, such as about 1.3, 1.4, 1.5, 1.6, 1.7, 1.8, 1.9, 2.0, 2.1, 2.2, 2.3, 2.4, 2.5, 2.6, 2.7, 2.8, 2.9 or 3. In some embodiments, the dimension D6 (see FIG. 22A) of the subsidiary contact opening 352a is substantially the same as the dimension D8 (see FIG. 23A) of the subsidiary contact opening 352b.

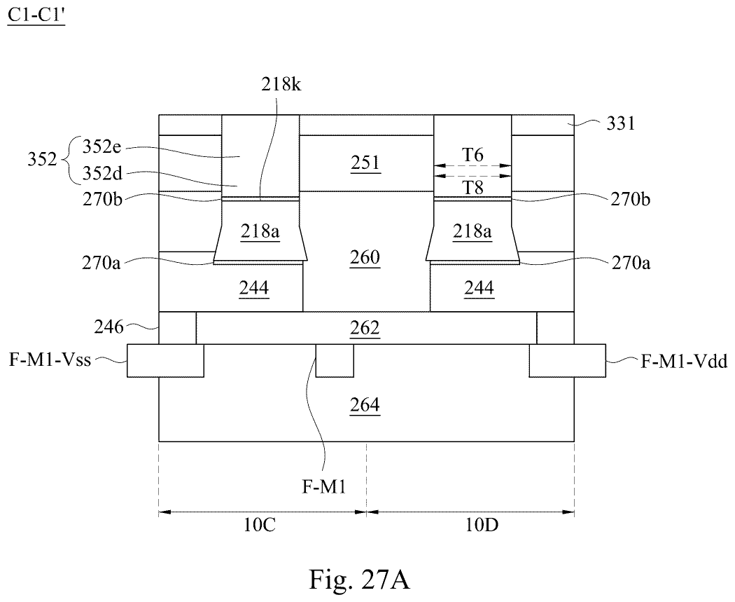

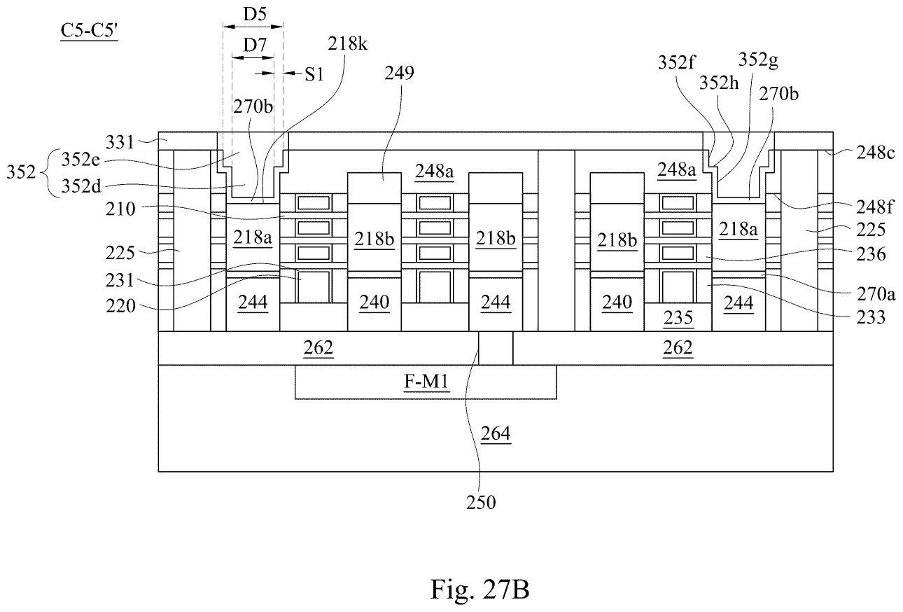

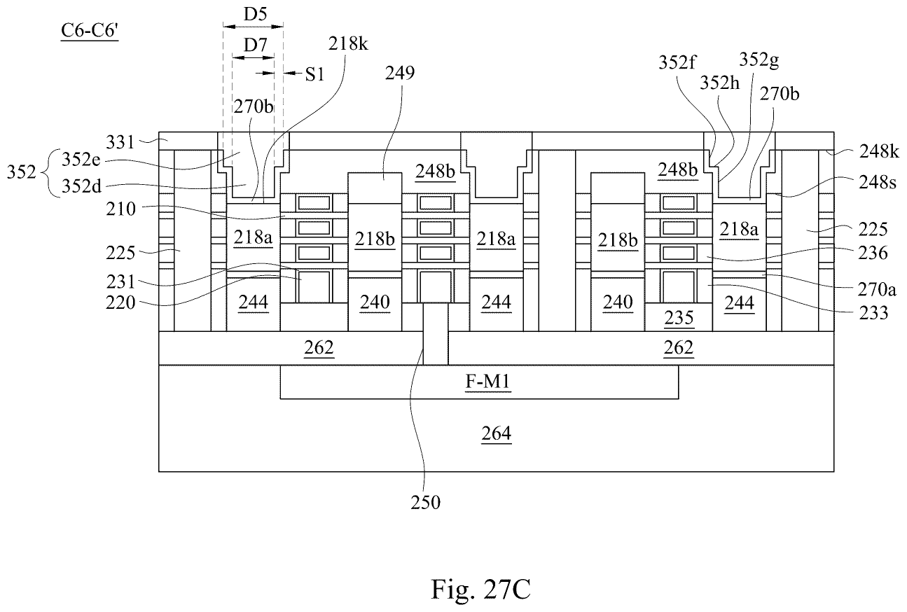

Subsequently, the contact 352 can formed in the contact opening 352c (see FIGS. 26A-26C), and the source/drain region 218a can be electrically connected to the back-side metal line (e.g., power supply voltage lines B-M1-Vss, B-M1-Vdd) through the contact 352 acting a power conductor path. Because the subsidiary contact opening 352b of the contact opening 352c (see FIGS. 26A-26C) can be formed to inherit the shape of the dielectric layer 249 and the semiconductive layer 259 (see FIGS. 24B-24D) directly underlying the source/drain regions 218a, the contact 352 (see FIGS. 27A-27C) formed in the contact opening 352c can self-align with the source/drain regions 218a and on the back-side 218k of the source/drain region 218a. Therefore, the contact 352 can be interchangeably referred to as a self-aligned connection structure. Specifically, the contact 352 has a front-side portion 352d formed in the subsidiary contact opening 352b and a back-side portion 352e formed in the subsidiary contact opening 352a.

The contact 352 can penetrate through the STI structure 251, the semiconductive layer 248a/248b, and the back-side dielectric layer 331. In addition, the contact 352 can be a stepped sidewall structure (e.g., two step shape) having a sidewall 352f, a sidewall 352g laterally set back from the sidewall 352f, and a horizontal surface 352h connecting the sidewall 352f to the sidewall 352g. The back-side portion 352e of the contact 352 may have a dimension T5 in parallel with a lengthwise direction of the semiconductive sheet 210, and a dimension T6 in parallel with a lengthwise direction of the gate electrode 220 from the top view. The dimension T5 of the back-side portion 352e of the contact 352 may be greater than a width of the source/drain regions 218a in the lengthwise direction of the semiconductive sheet 210, such that the back-side portion 352e of the contact 352 can overlap the gate spacer 233 and/or the gate electrode 220 from the top view. The dimension T6 of the back-side portion 352e of the contact 352 may be the same as a width of the semiconductive sheet 210 in the lengthwise direction of the gate electrode 220. The front-side portion 352d of the contact 352 may have a dimension T7 in parallel with the lengthwise direction of the semiconductive sheet 210, and a dimension T8 in parallel with the lengthwise direction of the gate electrode 220. The dimension T7 of the subsidiary contact opening 352b may be the same as the width of the source/drain regions 218a in the lengthwise direction of the semiconductive sheet 210, such that the front-side portion 352d of the contact 352 non-overlaps with the gate spacer 233 and/or the gate electrode 220. The dimension T8 of the subsidiary contact opening 352b may be the same as a width of the semiconductive sheet 210.

An interface between the back-side portion 352e and the front-side portion 352d of the contact 352 has an extension jog (e.g., horizontal surface 352h), such that the back-side portion 352e and the front-side portion 352d of the contact 352 have different lateral dimensions. In some embodiments, the back-side portion 352e of the contact 352 is wider than the front-side portion 352d of the contact 352 in the lengthwise direction of the semiconductive sheet 210. In other words, the front-side portion 352d of the contact 352 is narrower than the back-side portion 352e of the contact 352 in the lengthwise direction of the semiconductive sheet 210. Specifically, the dimension T5 of the back-side portion 352e of the contact 352 is greater than the dimension T7 of the front-side portion 352d of the contact 352, and greater than the dimension T11 of the semiconductive layer 259 (see FIG. 12B). In some embodiments, a ratio of dimension T5 of the back-side portion 352e of the contact 352 to the dimension T7 of the front-side portion 352d of the contact 352 can be greater than about 1.3. By way of example but not limiting the present disclosure, the ratio of dimension T5 of the back-side portion 352e of the contact 352 to the dimension T7 of the front-side portion 352d of the contact 352 can be in a range from about 1.3 to about 3, such as about 1.3, 1.4, 1.5, 1.6, 1.7, 1.8, 1.9, 2.0, 2.1, 2.2, 2.3, 2.4, 2.5, 2.6, 2.7, 2.8, 2.9 or 3. In some embodiments, the dimension T5 of the back-side portion 352e of the contact 352 may be in a range from about 13 nm to about 40 nm, such as about 13, 15, 20, 25, 30, 35, or 40 nm. The dimension T7 of the front-side portion 352d of the contact 352 may be in a range from about 9 nm to about 20 nm, such as about 6, 7, 8, 9, 10, 11, 12, 13, 14, 15, 16, 17, 18, 19, or 20 nm. In some embodiments, the dimension T6 of the back-side portion 352e of the contact 352 is substantially the same as the dimension T8 of the front-side portion 352d of the contact 352. In some embodiments, the front-side portion 352d of the contact 352 can have a front-side surface 352i in a position higher than the front-side surface 251f of the STI structure 251 (see FIG. 3A) and the front-side surface 248f/248s of the semiconductive layer 248a/248b. In some embodiments, the horizontal surface 352h of the contact 352 may have a length S1 (see FIGS. 23C and 23D) greater than about 2 nm. By way of example and not limitation, the length S1 (e.g., length) of the horizontal surface 352h of the contact 352 can be in a range from about 2 nm to about 10 nm, such as about 2, 3, 4, 5, 6, 7, 8, 9, or 10 nm.

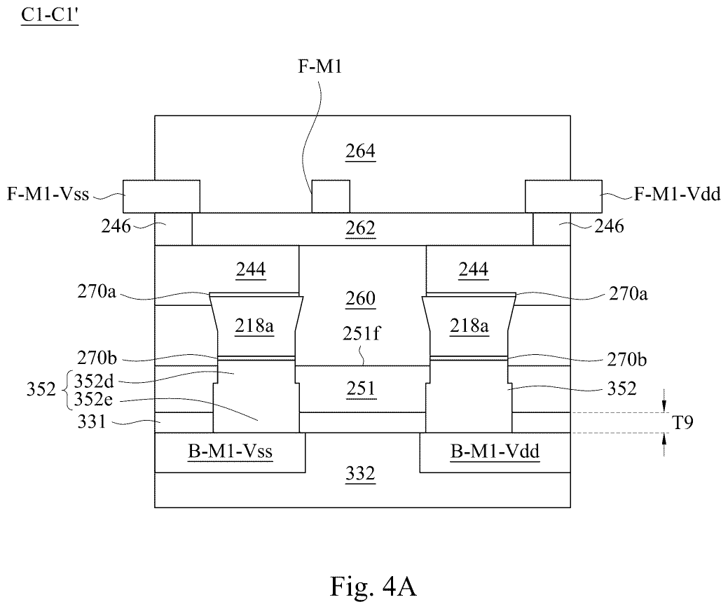

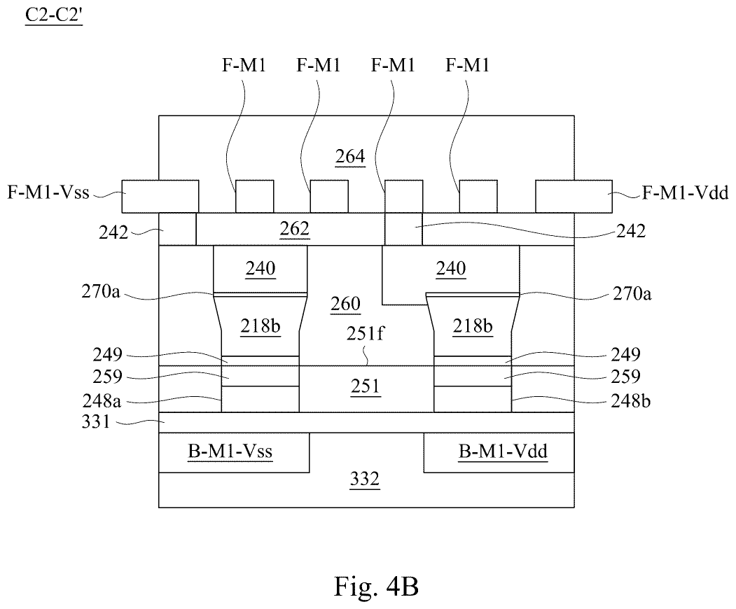

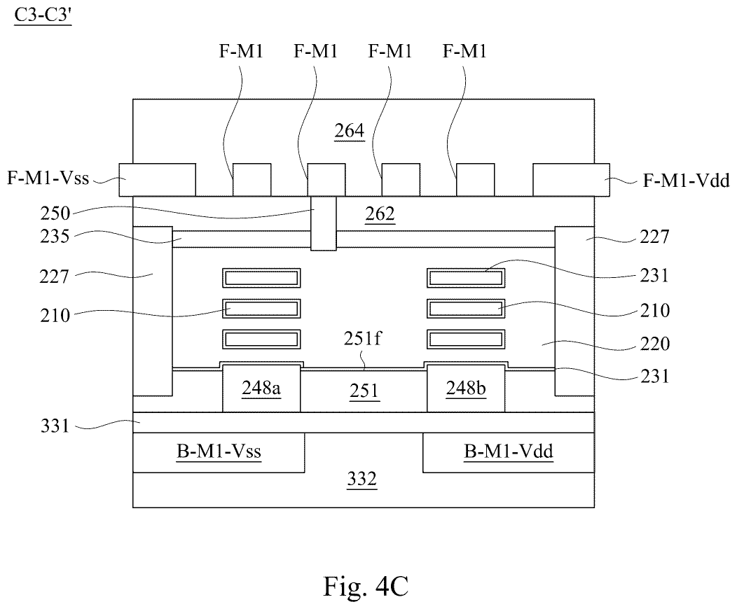

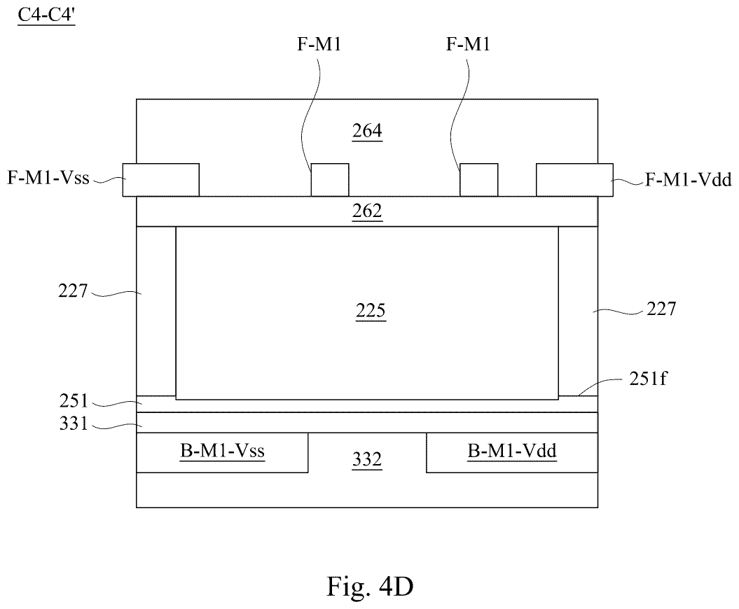

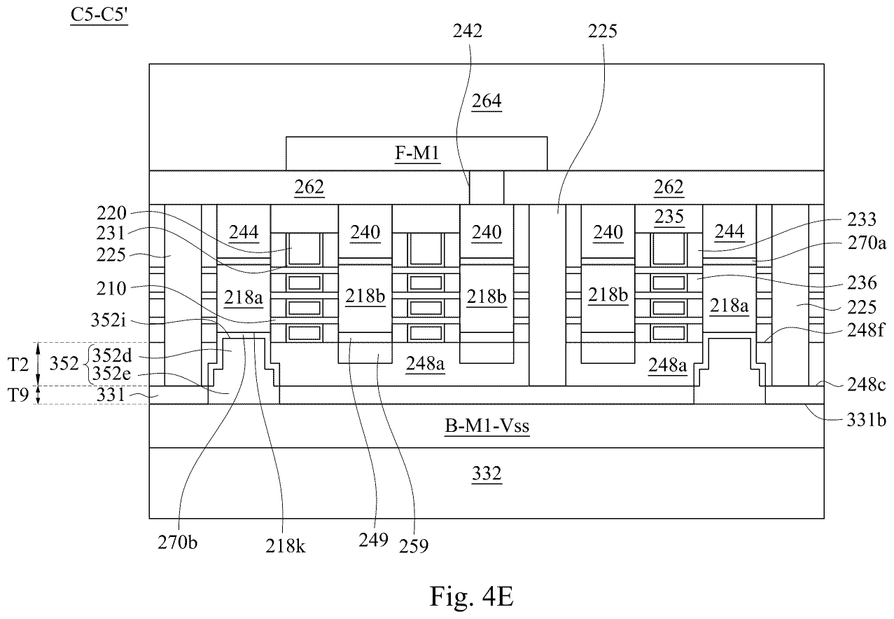

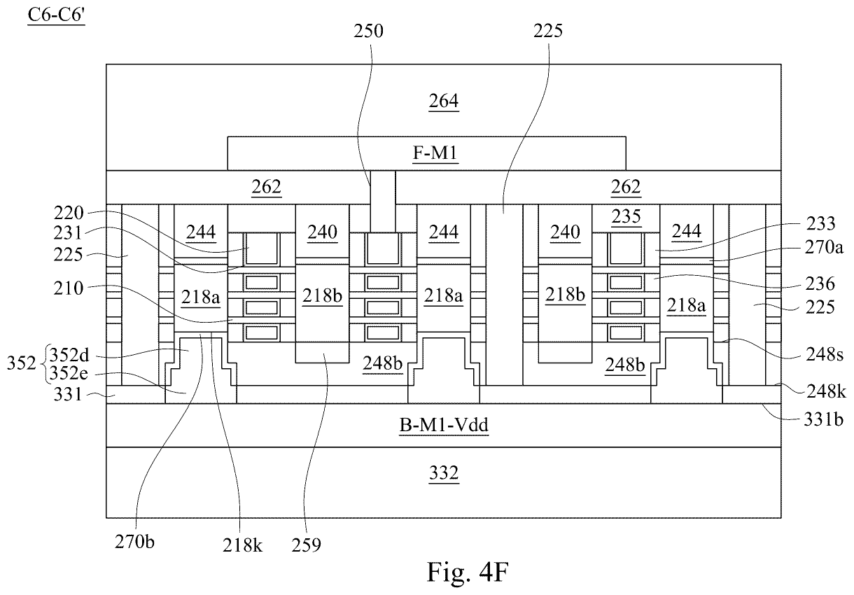

Reference is made to FIGS. 4A-4F. FIGS. 4A-4F illustrate cross-sectional views of a semiconductor structure corresponding to FIGS. 3A-3D, 3F, and 3H, respectively, according to some embodiments of the present disclosure, in which the dielectric layers 249 do not be formed within the second conductivity type device region 10D as shown in FIG. 4F. While FIG. 4F shows an embodiment of the semiconductor structure with a different profile than the semiconductor structure in FIG. 3H. In addition, the present disclosure may repeat reference numerals and/or letters in the various examples. This repetition is for the purpose of simplicity and clarity and does not in itself dictate a relationship between the various embodiments and/or configurations discussed.

The distinction in the semiconductor structure illustrated in FIGS. 4A-4F compared to that in FIGS. 3A-3D, 3F, and 3H may revolve around the second conductivity type device region 10D. Specifically, in FIGS. 4A-4F, the semiconductor structure can omit the dielectric layer 249 between the source/drain region 218b and the semiconductive layer 259, allowing for direct contact between the dielectric layer 249 between the source/drain region 218b, impacting the structural profile of the device. This direct interface is for forming a more improved structural profile, in the second conductivity type device region 10D, which may represent a PMOSFET transistor region. The semiconductive layer 259 can facilitate the epitaxial growth of the source/drain regions 218a and 218b. The semiconductive layer 259 is not for enhancing the electrical interface but to support the structural formation of the source/drain region 218b. By providing a template for epitaxial growth, the semiconductive layer 259 can help in achieving a more controlled and defined doping profile and structural integrity.

In some embodiments, the source/drain region 218b can include p-type dopants such as boron, BF₂, SiGe, or combinations thereof. The presence of these materials and their direct contact with the semiconductive layer 259 without an intervening dielectric layer can mean that the epitaxial layer can be more precisely formed, allowing for a structured extension of the doping profile directly from the semiconductive layer 259. Additionally, located beneath the semiconductive layer 259, the semiconductive layer 248b may be doped with an n-type dopant to provide a contrasting property relative to the p-type doped source/drain region 218b. This contrast is for creating effective p-n junctions, which can be fundamental in controlling the movement of carriers and thus reducing leakage currents and improving overall device performance.

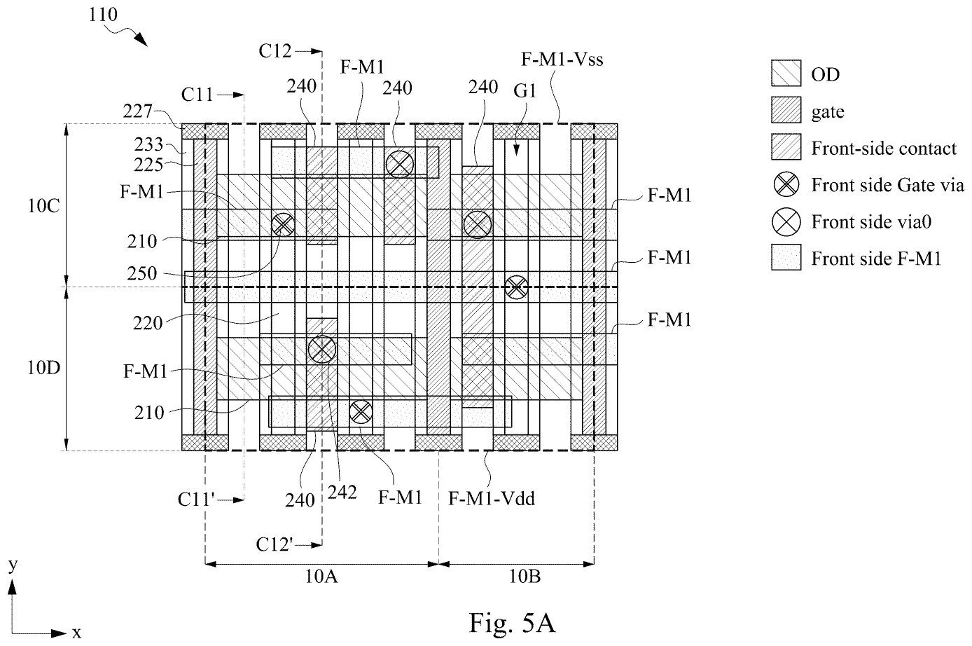

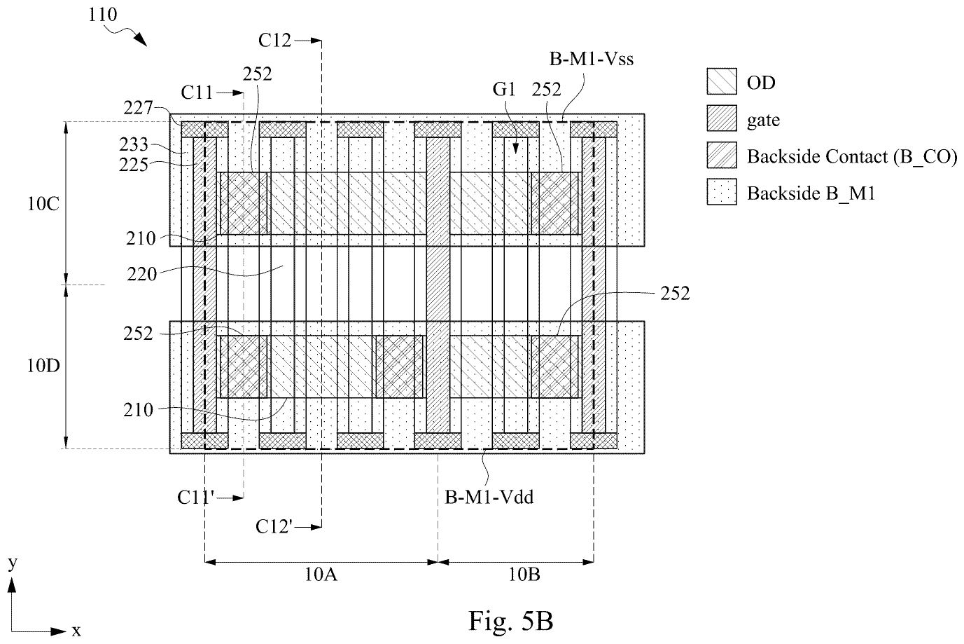

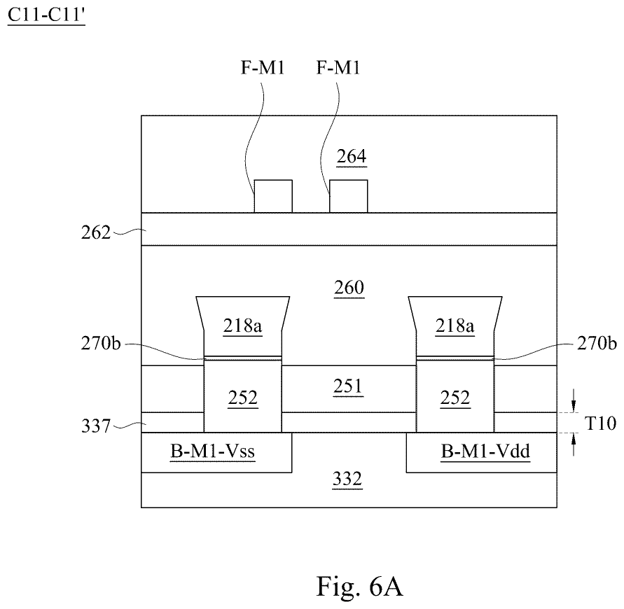

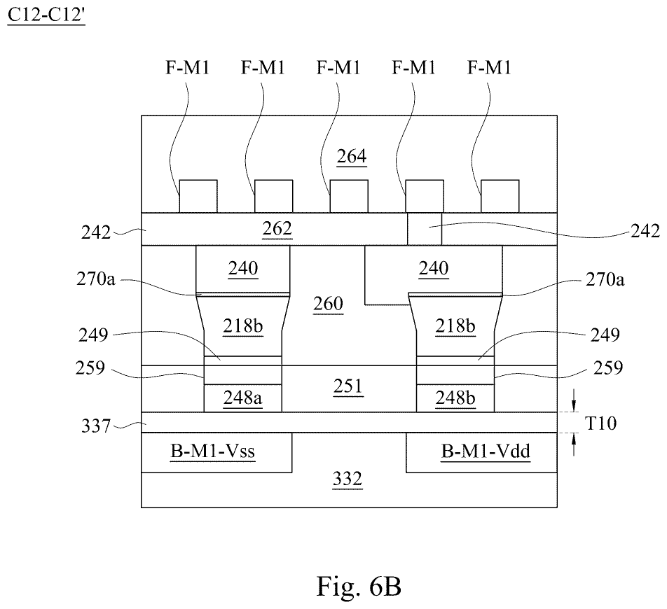

Reference is made to FIGS. 5A-6B. FIGS. 5A and 5B illustrate a layout diagram of a logic circuit on a front side and a back side of a semiconductor structure, respectively, according to some embodiments of the present disclosure. FIGS. 6A and 6B illustrate cross-sectional views obtained from reference cross-sections C11-C11′ and C12-C12′, in FIGS. 5A and 5B, and corresponding to FIGS. 3A and 3B, respectively. While FIGS. 5A-6B show an embodiment of the semiconductor structure with a different metal line routing method than the semiconductor structure in FIGS. 2A-4F. In addition, the present disclosure may repeat reference numerals and/or letters in the various examples. This repetition is for the purpose of simplicity and clarity and does not in itself dictate a relationship between the various embodiments and/or configurations discussed. It is noted that, the difference between the present embodiment and the embodiment in FIGS. 2A-4F is in that the wafer front-side is free of power supply voltage lines F-M1-Vdd, F-M1-Vss at the M1 level and the conductive via 246 and the source/drain contacts 240 associated with the power supply voltage lines F-M1-Vdd, F-M1-Vss and the conductive via 246 at the M1 level.

In some embodiments, the layouts as shown in FIGS. 2A, 2B, 5A, and 5B are represented by a plurality of masks generated by one or more processors and/or stored in one or more non-transitory computer-readable media. Other formats for representing the layout are within the scope of various embodiments. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

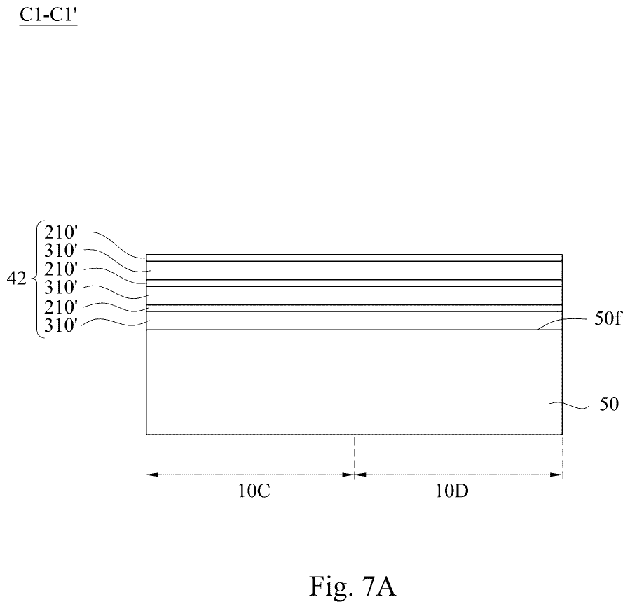

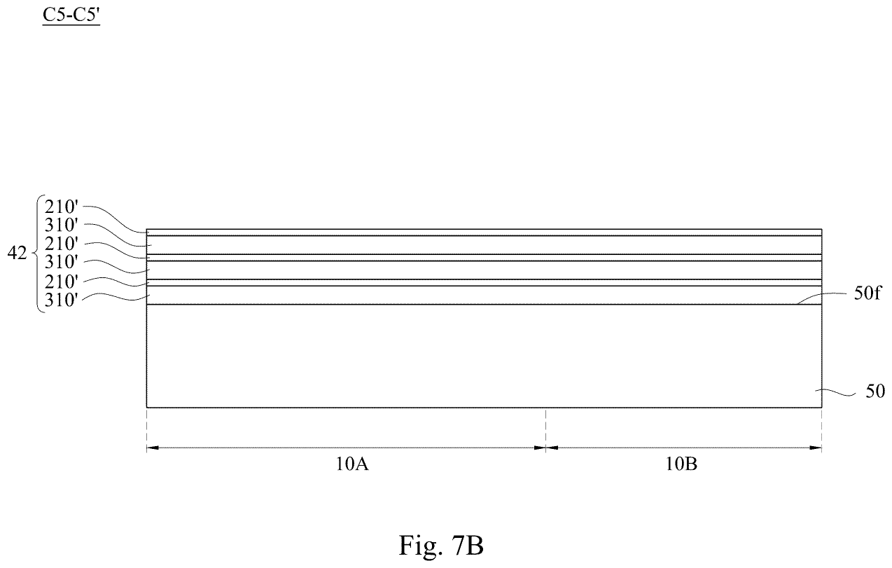

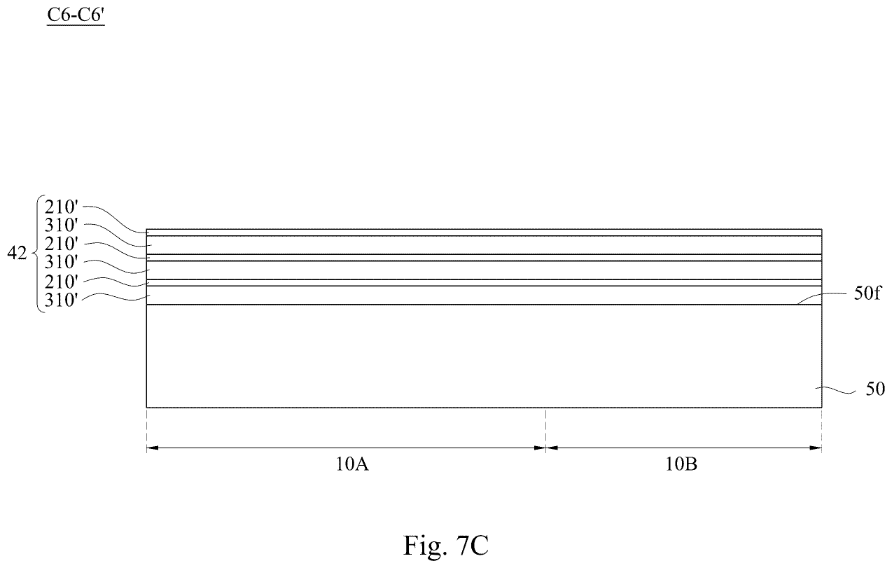

Reference is made to FIGS. 7A-25C. FIGS. 7A-28C illustrate cross-sectional views of intermediate stages in the formation of a semiconductor structure in accordance with some embodiments. Specifically, FIGS. 24A and 25A illustrate top views corresponding to FIG. 2B of intermediate stages in the formation of a semiconductor structure in accordance with some embodiments. FIGS. 7A, 8A, 9A, 10A, 11A, 12A, 13A, 14A, 15A, 16A, 17A, 18A, 19A, 20A, 21A, 22A, 23A, 24B, 25B, 26A, 27A, and 28A illustrate cross-sectional views obtained from the reference cross-section C1-C1′ in FIGS. 2A and 2B of intermediate stages in the formation of a semiconductor structure in accordance with some embodiments. FIGS. 7B, 8B, 9B, 10B, 11B, 12B, 13B, 14B, 15B, 16B, 17B, 18B, 19B, 20B, 21B, 22B, 23B, 24C, 25C, 26B, 27B, and 28B illustrate cross-sectional views obtained from the reference cross-section C5-C5′ in FIGS. 2A and 2B of intermediate stages in the formation of a semiconductor structure in accordance with some embodiments. FIGS. 7C, 8C, 9C, 10C, 11C, 12C, 13C, 14C, 15C, 16C, 17C, 18C, 19C, 20C, 21C, 22C, 23C, 24D, 25D, 26C, 27C, and 28C illustrate cross-sectional views obtained from the reference cross-section C6-C6′ in FIGS. 2A and 2B of intermediate stages in the formation of a semiconductor structure in accordance with some embodiments.

Reference is made to FIGS. 7A-7C. A substrate 50 is provided for forming nano-FETs. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

Specifically, the substrate 50 may have a first conductivity type device region 10C and a second conductivity type device region 10D. The first conductivity type device region 10C can be for forming n-type devices, such as NMOS transistors, e.g., n-type nano-FETs, and the second conductivity type device region 10D can be for forming p-type devices, such as PMOS transistors, e.g., p-type nano-FETs. The first conductivity type device region 10C may be physically separated from the second conductivity type device region 10D (not separately illustrated), and any number of device features (e.g., other active devices, doped regions, isolation structures, etc.) may be disposed between the first conductivity type device region 10C and the second conductivity type device region 10D. Although one first conductivity type device region 10C and one second conductivity type device region 10D are illustrated, any number of first and second conductivity type device regions 10C and 10D may be provided. In some embodiments, the first and second conductivity type device regions 10C and 10D of the substrate 50 may be a pure semiconductor layer without dopant. In some embodiments, the first conductivity type device region 10C and/or the second conductivity type device region 10D may be doped with a dopant having a same conductivity type as the source/drain region 218a/218b (see FIGS. 13A-13C) formed subsequently overlying thereof, and the dopant can be either n-type or p-type doping species. In some embodiments, the first conductivity type device region 10C and/or the second conductivity type device region 10D may be doped with a dopant having a different conductivity type than the source/drain region 218a/218b (see FIGS. 14A-14C) formed subsequently overlying thereof, and the dopant can be either n-type or p-type doping species.

Subsequently, a multi-layer stack 42 is formed on the front-side 50f of the substrate 50. The multi-layer stack 42 includes alternating first semiconductor layers 310′ and second semiconductor layers 210′. The first semiconductor layers 310′ formed of a first semiconductor material, and the second semiconductor layers 210′ are formed of a second semiconductor material. The semiconductor materials may each be selected from the candidate semiconductor materials of the substrate 50. In some embodiments, the multi-layer stack 42 includes three layers of each of the first semiconductor layers 310′ and the second semiconductor layers 210′. It should be appreciated that the multi-layer stack 42 may include any number (e.g. about 2 to 6) of the first semiconductor layers 310′ and the second semiconductor layers 210′. In some embodiments, and as will be subsequently described in greater detail, the first semiconductor layers 310′ will be removed and the second semiconductor layers 210′ will patterned to form channel regions for the nano-FETs. The first semiconductor layers 310′ are sacrificial layers (or dummy layers), which will be removed in subsequent processing to expose the top surfaces and the bottom surfaces of the second semiconductor layers 210′. The first semiconductor material of the first semiconductor layers 310′ is a material that has a high etching selectivity from the etching of the second semiconductor layers 210′, such as silicon germanium. The second semiconductor material of the second semiconductor layers 210′ is a material suitable for both n-type and p-type devices, such as silicon.

In some embodiments, the first semiconductor material of the first semiconductor layers 310′ may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 210′ may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers of the multi-layer stack 42 may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack 42 may have a thickness in a range from about 70 to 120 nm, such as about 70, 80, 90, 100, 110, or 120 nm. In some embodiments, each of the layers may have a small thickness, such as a thickness in a range of about 5 nm to about 40 nm. In some embodiments, some layers (e.g., the second semiconductor layers 210′) are formed to be thinner than other layers (e.g., the first semiconductor layers 310′). For example, in embodiments in which the first semiconductor layers 310′ are sacrificial layers (or dummy layers) and the second semiconductor layers 210′ are patterned to form channel regions for the nano-FETs.

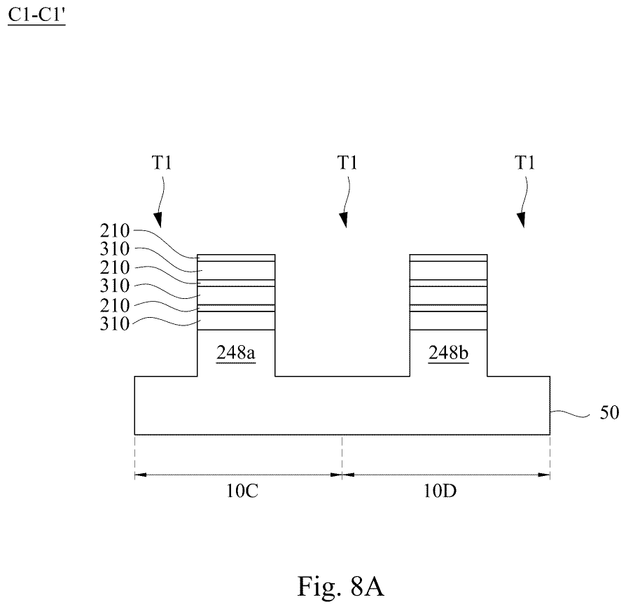

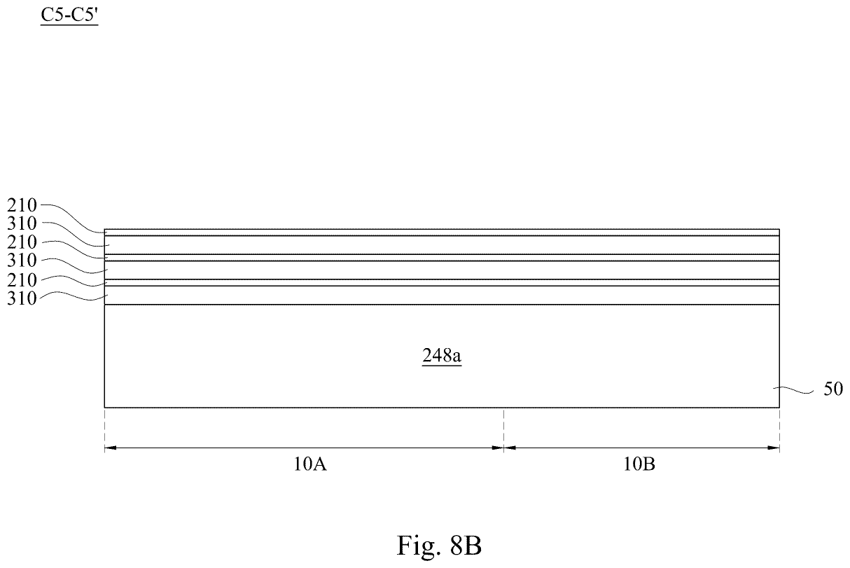

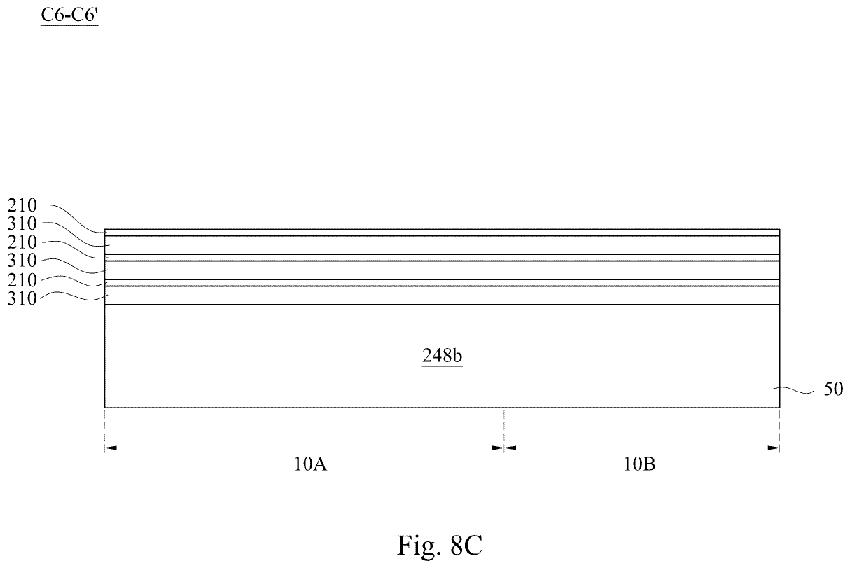

Reference is made to FIGS. 8A-8C. Trenches T1 can be patterned in the substrate 50 and the multi-layer stack 42 to form a semiconductive layer 248a in the first conductivity type device region 10C and a semiconductive layer 248b in the second conductivity type device region 10D, and first and second semiconductive sheets 210 and 310 over the semiconductive layers 248a and 248b. The semiconductive layers 248a and 248b can be semiconductor strips patterned in the substrate 50. In some embodiments, the semiconductive layer 248a/248b can be formed as a fin-like structure underlying the semiconductive sheets 210 and 310. The first semiconductive sheets 310 and the second semiconductive sheets 210 include the remaining portions of the first semiconductor layers 310′ and the second semiconductor layers 210′, respectively. The trenches T1 may be patterned by any acceptable etch process, such as a reactive ion etch (RIE), neutral beam etch (NBE), the like, or a combination thereof. The etching may be anisotropic. The semiconductive layers 248a and 248b and the first and second semiconductive sheets 310, 210 may be patterned by any suitable method. For example, the semiconductive layers 248a and 248b and the first and second semiconductive sheets 310, 210 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiments, a sacrificial layer is formed over a substrate and patterned using a photolithography process. Spacers are formed alongside the patterned sacrificial layer using a self-aligned process. The sacrificial layer is then removed, and the remaining spacers may then be used as masks to pattern the semiconductive layers 248a and 248b and the first and second semiconductive sheets 310, 210. In some embodiments, the mask (or other layer) may remain on the first and second semiconductive sheets 310, 210. The semiconductive layers 248a and 248b and the first and second semiconductive sheets 310, 210 may each have widths in a range of about 8 nm to about 40 nm. In some embodiments, the semiconductive layers 248a and 248b and the first and second semiconductive sheets 310, 210 have substantially equal widths.

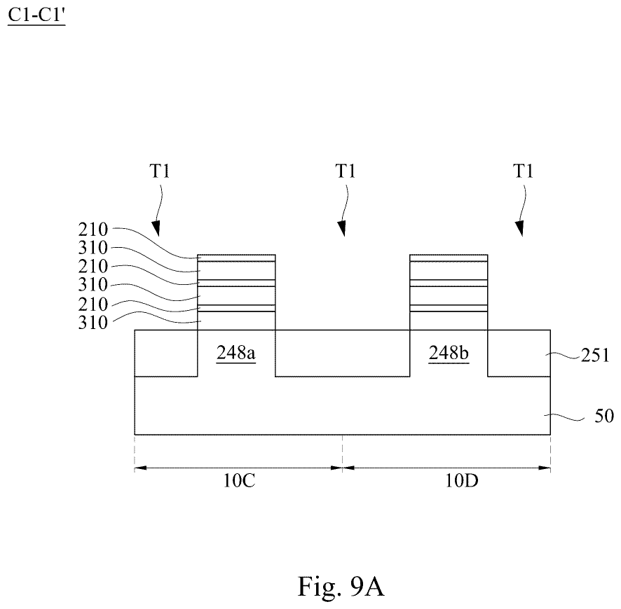

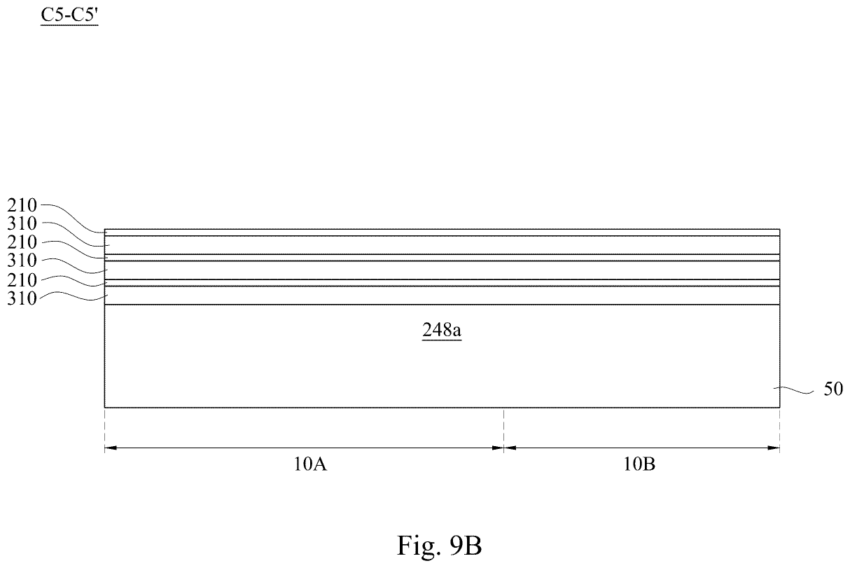

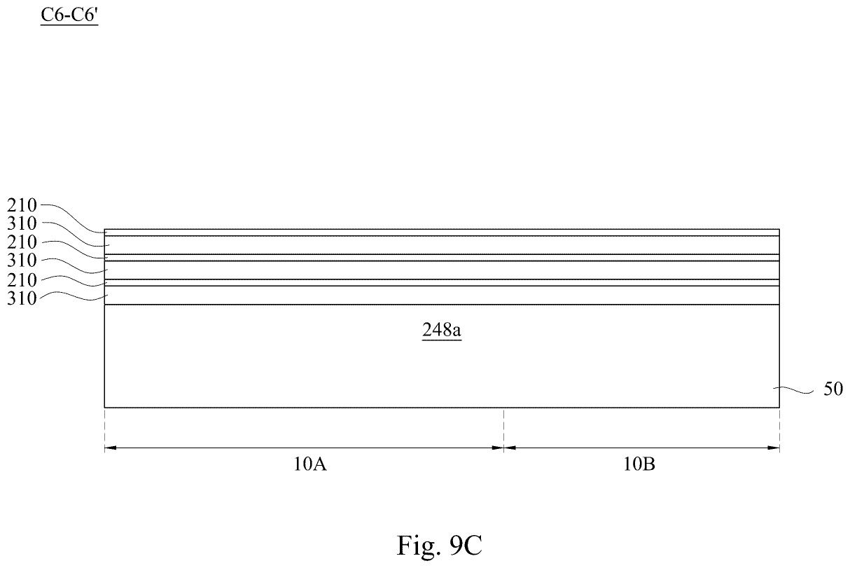

Reference is made to FIGS. 9A-9C. STI structures 251 are formed over the substrate 50 and between the semiconductive layers 248a and 248b. The STI structures 251 are disposed around at least a portion of the semiconductive layers 248a and 248b such that at least a portion of the first and second semiconductive sheets 310, 210 protrude from between adjacent STI structures 251. In some embodiments, the top surfaces of the STI structures 251 can be coplanar (within process variations) with the top surfaces of the semiconductive layers 248a and 248b. In some embodiments, the top surfaces of the STI structures 251 are above or below the top surfaces of the semiconductive layers 248a and 248b. The STI structures 251 can separate the features of adjacent devices.

The STI structures 251 may be formed by any suitable method. For example, an insulation material can be formed over the substrate 50 and the first and second semiconductive sheets 310, 210, and between adjacent semiconductive layers 248a and 248b. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In some embodiments, the insulation material is formed such that excess insulation material covers the first and second semiconductive sheets 310, 210. Although the STI structures 251 are each illustrated as a single layer, some embodiments may utilize multiple layers. For example, in some embodiments a liner (not separately illustrated) may first be formed along surfaces of the substrate 50, the semiconductive layers 248a and 248b, and the first and second semiconductive sheets 310, 210. Thereafter, a fill material, such as those previously described may be formed over the liner.

A removal process is then applied to the insulation material to remove excess insulation material over the first and second semiconductive sheets 310, 210. In some embodiments, a planarization process such as a chemical mechanical polish (CMP), an etch-back process, combinations thereof, or the like may be utilized. In embodiments in which a mask remains on the first and second semiconductive sheets 310, 210, the planarization process may expose the mask or remove the mask. After the planarization process, the top surfaces of the insulation material and the mask (if present) or the first and second semiconductive sheets 310, 210 are coplanar (within process variations). Accordingly, the top surfaces of the mask (if present) or the first and second semiconductive sheets 310, 210 are exposed through the insulation material. In some embodiments, no mask remains on the first and second semiconductive sheets 310, 210. The insulation material is then recessed to form the STI structures 251. The insulation material is recessed, such as in a range from about 30 nm to about 80 nm, such that at least a portion of the first and second semiconductive sheets 310, 210 protrude from between adjacent portions of the insulation material. Further, the top surfaces of the STI structures 251 may have a flat surface as illustrated, a convex surface, a concave surface (such as dishing), or a combination thereof. The top surfaces of the STI structures 251 may be formed flat, convex, and/or concave by an appropriate etch. The insulation material may be recessed using any acceptable etching process, such as one that is selective to the material of the insulation material (e.g., selectively etches the insulation material of the STI structures 251 at a faster rate than the materials of the semiconductive layers 248a and 248b and the first and second semiconductive sheets 310, 210). For example, an oxide removal may be performed using dilute hydrofluoric (dHF) acid.

The process previously described is just one example of how the semiconductive layers 248a and 248b and the first and second semiconductive sheets 310, 210 may be formed. In some embodiments, the semiconductive layers 248a and 248b and/or the first and second semiconductive sheets 310, 210 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the semiconductive layers 248a and 248b and/or the first and second semiconductive sheets 310, 210. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

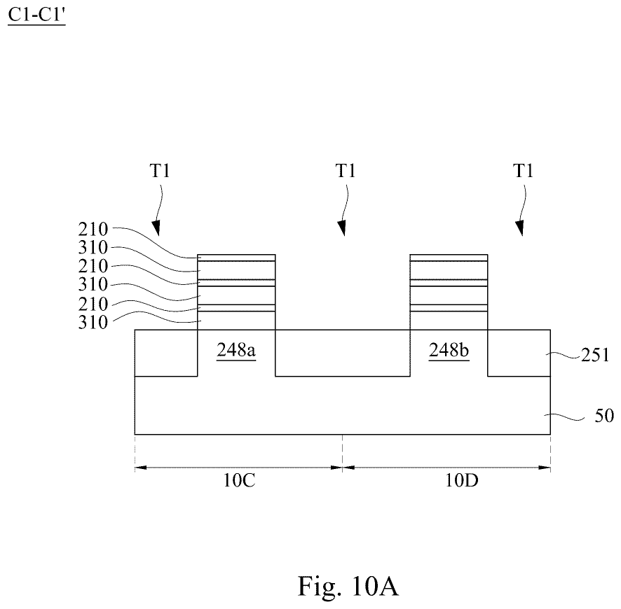

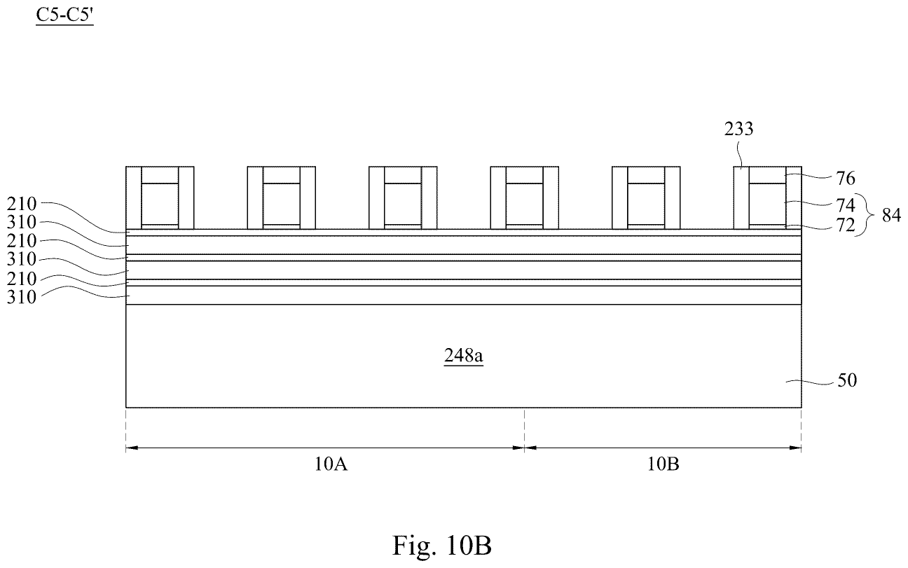

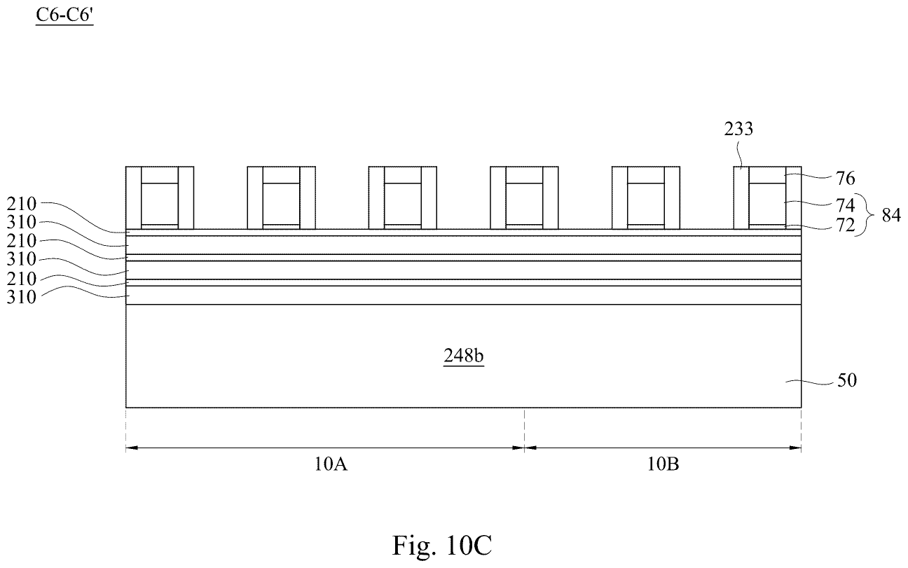

Reference is made to FIGS. 10A-10C. A dummy dielectric layer, a dummy gate layer, and a mask layer are sequentially formed on the semiconductive layers 248a and 248b and the first and second semiconductive sheets 310, 210. Specifically, firstly, the dummy dielectric layer can be formed on the semiconductive layers 248a and 248b and the first and second semiconductive sheets 310, 210. The dummy dielectric layer may be formed of a dielectric material such as silicon oxide, silicon nitride, a combination thereof, or the like, which may be deposited or thermally grown according to acceptable techniques. Subsequently, a dummy gate layer can be formed over the dummy dielectric layer. The dummy gate layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer may be formed of material(s) that have a high etching selectivity from the etching of insulation materials, e.g., the STI structures 251 and/or the dummy dielectric layer. Subsequently, a mask layer can be formed over the dummy gate layer. The mask layer may be formed of a dielectric material such as silicon nitride, silicon oxynitride, or the like.

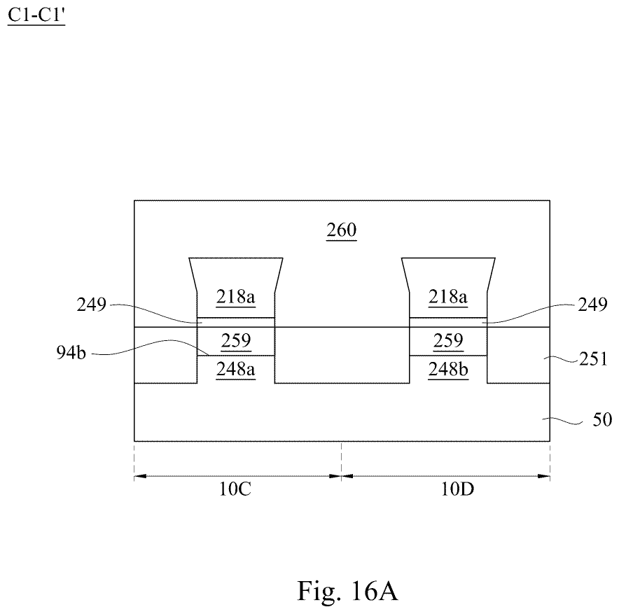

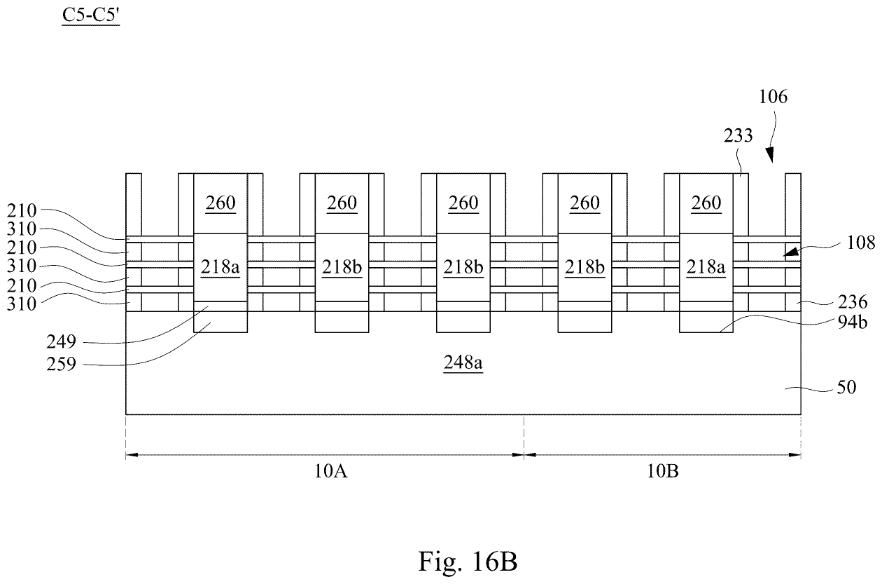

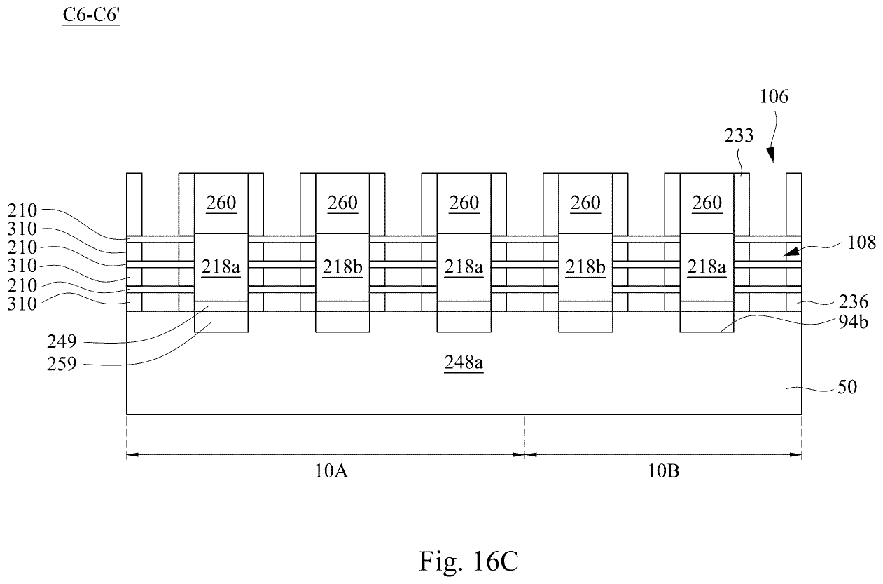

The mask layer is patterned using acceptable photolithography and etching techniques to form masks 76. The pattern of the masks 76 is then transferred to the dummy gate layer by any acceptable etching technique to form dummy gates 74. The pattern of the masks 76 may optionally be further transferred to the dummy dielectric layer by any acceptable etching technique to form dummy dielectrics 72. The dummy gate 74 and the dummy dielectric 72 may be collectively referred to as a dummy gate structure 84. The dummy gate structures 84 cover portions of the first and second semiconductive sheets 310, 210 that will be exposed in subsequent processing to form channel regions (see FIGS. 16B and 16C). Specifically, the dummy gate structures 84 extend across the portions of the second semiconductive sheets 210 that will be patterned to form channel regions, in lengthwise directions substantially perpendicular (within process variations) to the lengthwise directions of the semiconductive layers 248a and 248b. In some embodiments, the masks 76 can optionally be removed after patterning, such as by any acceptable etching technique.

Gate spacers 233 can be formed over the first and second semiconductive sheets 310, 210, on exposed sidewalls of the masks 76, the dummy gates 74, and the dummy dielectrics 72. In some embodiments, the gate spacers 233 can be interchangeably referred to top/upper spacers. In some embodiments, the gate spacers 233 may have a lateral dimension in a range from about 4 nm to about 12 nm. The gate spacers 233 may be formed by conformally depositing one or more dielectric material(s) and subsequently etching the dielectric material(s). In some embodiments, the gate spacer 233 may include multiple dielectric material and selected from a group consist of silicon oxide, silicon nitride, silicon oxynitride, silicon oxycarbonitride, carbon doped oxide, nitrogen doped oxide, porous oxide, air gap, or combinations thereof, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gate structures 84 (thus forming the gate spacers 233).

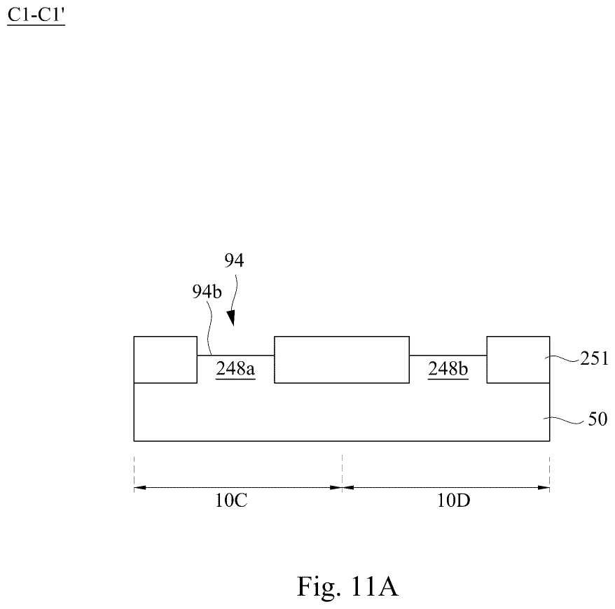

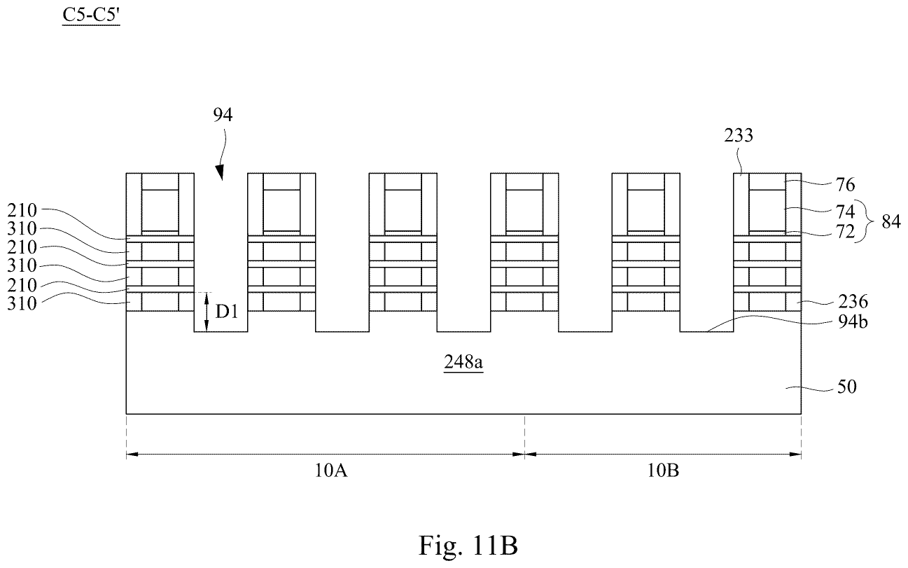

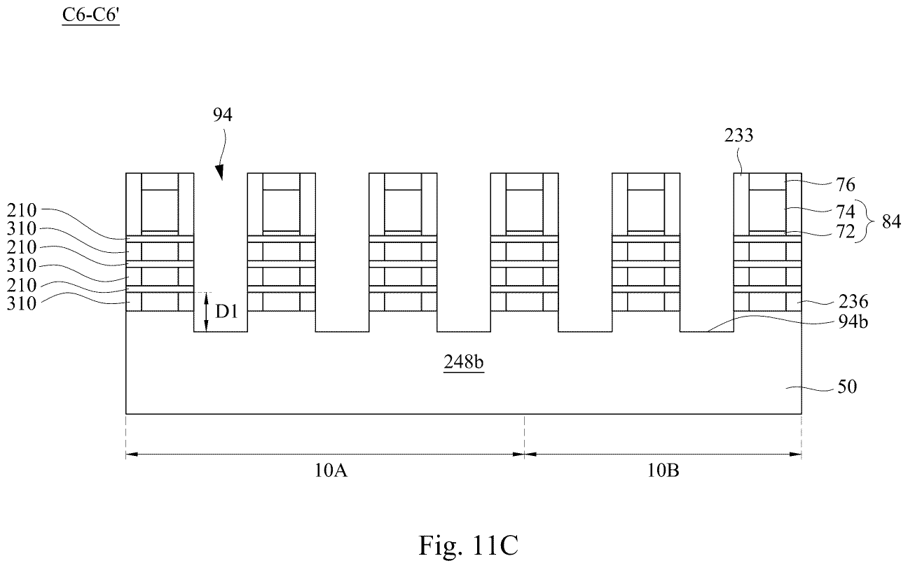

Reference is made to FIGS. 11A-11C. Source/drain recesses 94 can be formed in the first and second semiconductive sheets 310, 210. In some embodiments, the source/drain recesses 94 extend through the first and second semiconductive sheets 310, 210 and into the semiconductive layers 248a and 248b. In some embodiments, the semiconductive layers 248a and 248b may be etched such that bottom surfaces of the source/drain recesses 94 are disposed below the top surfaces of the STI structures 251. The source/drain recesses 94 may be formed by etching the first and second semiconductive sheets 310, 210 using an anisotropic etching process, such as a RIE, a NBE, or the like. The gate spacers 233 and the dummy gate structures 84 collectively mask portions of the semiconductive layers 248a and 248b and/or the first and second semiconductive sheets 310, 210 during the etching processes used to form the source/drain recesses 94. A single etch process may be used to etch each of the first and second semiconductive sheets 310, 210, or multiple etch processes may be used to etch the first and second semiconductive sheets 310, 210. Timed etch processes may be used to stop the etching of the source/drain recesses 94 after the source/drain recesses 94 reach a desired depth. In some embodiments, the source/drain recess 94 has a bottom 94b that is in a position lower than a bottommost one of the second semiconductive sheets 210 about a vertical dimension D1. By way of example but not limitation, the vertical dimension D1 can be in a range from about 5 nm to about 60 nm, such as about 5, 10, 15, 20, 25, 30, 35, 40, 45, 50, 55, or 60 nm.

Subsequently, inner spacers 236 are formed on sidewalls of the remaining portions of the first semiconductive sheets 310, e.g., those sidewalls exposed by the source/drain recesses 94. As will be subsequently described in greater detail, source/drain regions will be subsequently formed in the source/drain recesses 94, and the first semiconductive sheets 310 will be subsequently replaced with corresponding gate structures. The inner spacers 236 act as isolation features between the subsequently formed source/drain regions and the subsequently formed gate structures. Further, the inner spacers 236 may be used to substantially prevent damage to the subsequently formed source/drain regions by subsequent etching processes, such as etching processes used to subsequently remove the first semiconductive sheets 310. In some embodiments, the inner spacers 236 can be interchangeably referred to lower gate spacers. In some embodiments, the inner spacers 236 may have a lateral dimension in a range from about 4 nm to about 12 nm.

As an example to form the inner spacers 236, the source/drain recesses 94 can be laterally expanded. Specifically, portions of the sidewalls of the first semiconductive sheets 310 exposed by the source/drain recesses 94 may be recessed. Although sidewalls of the first semiconductive sheets 310 are illustrated as being straight, the sidewalls may be concave or convex. The sidewalls may be recessed by any acceptable etching process, such as one that is selective to the material of the first semiconductive sheets 310 (e.g., selectively etches the material of the first semiconductive sheets 310 at a faster rate than the material of the second semiconductive sheets 210). The etching may be isotropic. For example, when the second semiconductive sheets 210 are formed of silicon and the first semiconductive sheets 310 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94 and recess the sidewalls of the first semiconductive sheets 310. The inner spacers 236 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236 may have a higher K (dielectric constant) value than the gate spacer 233. In some embodiments, the material of inner spacer is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 236 are illustrated as being flush with respect to the sidewalls of the gate spacers 233, the outer sidewalls of the inner spacers 236 may extend beyond or be recessed from the sidewalls of the gate spacers 233. In other words, the inner spacers 236 may partially fill, completely fill, or overfill the sidewall recesses. Moreover, although the sidewalls of the inner spacers 236 are illustrated as being straight, the sidewalls of the inner spacers 236 may be concave or convex.

Reference is made to FIGS. 12A-12C. A semiconductive layer 259 can be selective formed on the semiconductive layer 248a/248b exposed from the source/drain recess 94. A selective deposition process P2, including a deposition process and a removing process, can be performed to form the semiconductive layer 259. For example, the deposition process (e.g., epitaxial growth process) may be performed to deposit a semiconductive material over the semiconductive sheets 210 and the =semiconductive layer 248a/248b. Subsequently, the removing process (e.g., sputter process) can be performed to remove the semiconductive material deposited on sidewalls of the source/drain recesses 94 and an upper surface above the semiconductive sheets 210, so as to leave the deposited semiconductive material on the semiconductive layer 248a/248b to form the semiconductive layer 259. In some embodiments, sputter etching caused by plasmas in the selective deposition process P2 may provide a higher sputter etch rate at the semiconductive material on the sidewalls of the recesses 94 and the upper surface above the substrate 50 than on the lower surface above the substrate 50, such that the net effect of the deposition and sputter etching in the selective deposition process P2 leads to the semiconductive material remaining on the bottom 94b of the recess 94 and absent on the sidewalls of the recesses 94 and the upper surface above the substrate 50. In some embodiments, the deposition and sputter etching in the selective deposition process P2 may be performed in-situ or ex-situ.

In some embodiments, the semiconductive layer 259 may have a lateral dimension T11 (see FIGS. 12B and 12C) in parallel with the lengthwise direction of the semiconductive sheet 210, and a lateral dimension T12 (see FIG. 12A) in parallel with the lengthwise direction of the gate electrode 220, and a vertical dimension T13 (see FIGS. 12A-12C) perpendicular to the lateral dimensions T11 and T12. By way of example and not limitation, the lateral dimension T11 of the semiconductive layer 259 may be in a range from about 13 to about 40 nm, such as about 13, 15, 20, 25, 30, 35, or 40 nm, the vertical dimension T13 of the semiconductive layer 259 may be in a range from about 10 to about 50 nm, such as about 10, 15, 20, 25, 30, 35, 40, 45, or 50 nm. In some embodiments, the vertical dimension of the semiconductive layer 259 in the first logic circuit region 10A can be less than, greater than, or substantially the same as the vertical dimension of the semiconductive layer 259 in the second logic circuit region 10B.

In some embodiments, the semiconductive layer 259 can be made of a different material than the semiconductive layer 248a/248b. In some embodiments, the semiconductive layer 259 can be made of a material different than or the same as the source/drain region 218a/218b (see FIGS. 14A-14C). In some embodiments, the semiconductive layer 259 is free of dopant. By way of example but not limiting the present disclosure, the semiconductive layer 259 can include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

Reference is made to FIGS. 13A-13C. A dielectric layer 249 can be formed over the semiconductive layer 259. A selective deposition process P3, including a deposition process and a removing process, can be performed to form the dielectric layer 249. For example, the deposition process may be performed to deposit a dielectric material over the substrate 50. Subsequently, the removing process (e.g., sputter process) can be performed to remove the dielectric material deposited on sidewalls of the source/drain recesses 94 and an upper surface above the substrate 50, so as to leave the deposited dielectric material on the semiconductive layer 259 to form the dielectric layer 249.

By way of example but not limiting the present disclosure, the selective deposition process P3 may be performed by an inductively coupled plasma (ICP) tool or a capactitively coupled plasma (CCP) tool. In some embodiments, the deposition gas used in the selective deposition process P3 may include, for example, a silicon source gas, such as silicon tetrachloride gas, SiCl₄, and an oxygen source gas, such as molecular oxygen gas, O₂, in plasma state to form a silicon oxide layer over the substrate 50. In some embodiments, the deposition gas used in the selective deposition process P3 may include, for example, a fluorocarbon (CₓF_{y}) source gas, such as C₄F₆ and/or C₄F₈, and an oxygen source gas, such as molecular oxygen gas, O₂, in plasma state to form a CₓF_{y} layer over the substrate 50. In some embodiments, the deposition gas used in the selective deposition process P3 may include a mixture of BCl₃ and N₂ to deposit boron or boron nitride; a mixture of BCl₃, CH₄ and H₂ to deposit boron carbide. In some embodiments, sputter etching caused by plasmas in the selective deposition process P3 may provide a higher sputter etch rate at the dielectric material on the sidewalls of the recesses 94 and the upper surface above the substrate 50 than on the lower surface above the substrate 50, such that the net effect of the deposition and sputter etching in the selective deposition process P3 leads to the dielectric material remaining on the semiconductive layer 259 and absent on the sidewalls of the recesses 94 and the upper surface above the substrate 50. In some embodiments, the deposition and sputter etching in the selective deposition process P3 may be performed in-situ or ex-situ.

In some embodiments, the dielectric layer 249 can be made of a different material than the inner spacer 236. In some embodiments, the dielectric layer 249 can be made of a same material as the inner spacer 236. In some embodiments, the dielectric layer 249 is made of an oxide-containing material (e.g., SiO₂), a nitrogen-containing material (e.g., SiON, SiN, Si₃N₄), a carbon-containing material (e.g., SiOC, SIOCN), the like, or combinations thereof. In some embodiments, the dielectric layer 249 may be made of a material having a dielectric constant greater than about 7.9 (e.g., high dielectric constant (high-k) material). For example, the dielectric layer 249 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

Reference is made to FIGS. 14A-14C. Epitaxial source/drain regions 218a and 218b are formed in the source/drain recesses 94, such that each dummy gate 84 (and corresponding channel regions) is disposed between respective adjacent pairs of the epitaxial source/drain regions 218a and 218b. In some embodiments, the gate spacers 233 and the inner spacers 236 are used to separate the epitaxial source/drain regions 218a and 218b from, respectively, the dummy gate structures 84 and the first semiconductive sheets 310 by an appropriate lateral distance so that the epitaxial source/drain regions 218a and 218b do not short out with subsequently formed gates of the resulting nano-FETs. A material of the epitaxial source/drain regions 218a and 218b may be selected to exert stress in the respective channel regions, thereby improving performance of the semiconductor structure.

The epitaxial source/drain regions 218a and 218b in the first conductivity type device region 10C may be formed by masking the second conductivity type device region 10D. Then, the epitaxial source/drain regions 218a and 218b in the first conductivity type device region 10C can be epitaxially grown in the source/drain recesses 94 in the first conductivity type device regions 10C. The epitaxial source/drain regions 218a and 218b in the first conductivity type device region 10C may include any acceptable material appropriate for n-type devices. For example, the epitaxial source/drain regions 218a and 218b in the first conductivity type device region 10C may include materials exerting a tensile strain on the channel regions, such as silicon, silicon carbide, phosphorous doped silicon carbide, silicon phosphide, or the like. The epitaxial source/drain regions 218a and 218b in the first conductivity type device region 10C may be referred to as “n-type source/drain region.” The epitaxial source/drain regions 218a and 218b in the first conductivity type device region 10C may have surfaces raised from respective surfaces of the semiconductive layers 248a and 248b and the first and second semiconductive sheets 310, 210, and may have facets. In some embodiments, the source/drain regions 218a and 218b of the first conductivity type device region 10C may have a phosphorus concentration within a range from about 2E19/cm³ to about 3E21/cm³.

The epitaxial source/drain regions 218a and 218b in the second conductivity type device region 10D may be formed by masking the first conductivity type device region 10C. Then, the epitaxial source/drain regions 218a and 218b in the second conductivity type device region 10D can be epitaxially grown in the source/drain recesses 94 in the second conductivity type device region 10D. The epitaxial source/drain regions 218a and 218b in the second conductivity type device region 10D may include any acceptable material appropriate for p-type devices. For example, the epitaxial source/drain regions 218a and 218b in the second conductivity type device region 10D may include materials exerting a compressive strain on the channel regions, such as silicon germanium, boron doped silicon germanium, germanium, germanium tin, or the like. The epitaxial source/drain regions 218a and 218b in the second conductivity type device region 10D may be referred to as “p-type source/drain region.” The epitaxial source/drain regions 218a and 218b in the second conductivity type device region 10D may have surfaces raised from respective surfaces of the semiconductive layers 248a and 248b and the first and second semiconductive sheets 310, 210, and may have facets. In some embodiments, the source/drain regions 218a and 218b of the second conductivity type device region 10D may have a boron concentration within a range from about 1E19/cm³ to about 6E20/cm³. In some embodiments, the source/drain regions 218a and 218b of the second conductivity type device region 10D may have a Ge atomic percentage within a range of about 36% to about 85%.

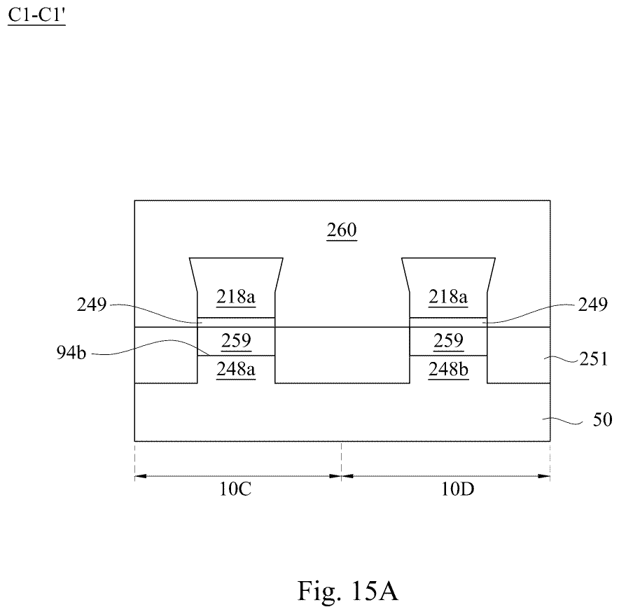

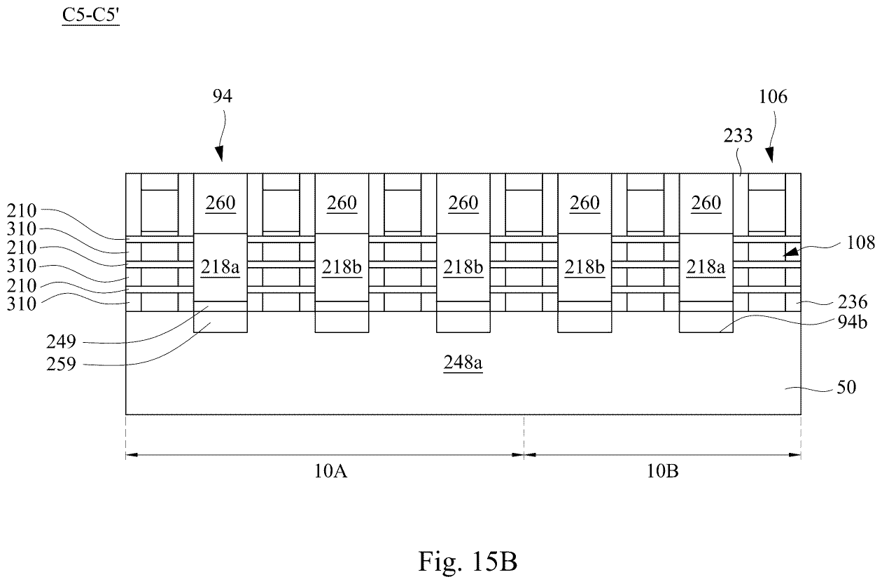

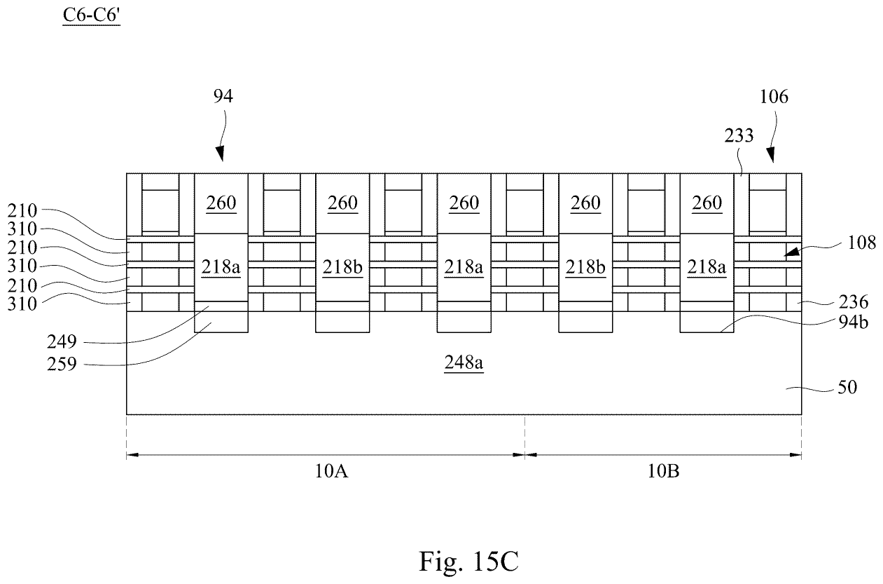

Reference is made to FIGS. 15A-15C. An inter-layer dielectric (ILD) layer 260 can be deposited over the epitaxial source/drain regions 218a and 218b, the gate spacers 233, the dummy gate structures 84. The ILD layer 260 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) is formed between the ILD layer 260 and the epitaxial source/drain regions 218a and 218b, the gate spacers 233, and the dummy gate structures 844. The CESL may be formed of a dielectric material, such as silicon nitride, silicon oxide, silicon oxynitride, or the like, having a high etching selectivity from the etching of the ILD 260. The CESL may be formed by an any suitable method, such as CVD, ALD, or the like.

Subsequently, a removal process is performed to level the top surfaces of the ILD layer 260 with the top surfaces of the dummy gate structures 84. In some embodiments, a planarization process such as a chemical mechanical polish (CMP), an etch-back process, combinations thereof, or the like may be utilized. The planarization process may also remove the masks 76 on the dummy gate structures 84, and portions of the gate spacers 233 along sidewalls of the masks 76. After the planarization process, the top surfaces of the gate spacers 233, the ILD layer 260, the CESL, and the dummy gate structures 84 can be coplanar (within process variations). Accordingly, the top surfaces of the dummy gate structures 84 can be exposed through the ILD layer 260. In some embodiments, the masks 76 remain, and the planarization process levels the top surfaces of the ILD layer 260 with the top surfaces of the masks 76.

Reference is made to FIGS. 16A-16C. The dummy gate structures 84 can be removed in an etching process, so that recesses 106 can be formed. In some embodiments, the dummy gate structures 84 can be removed by an anisotropic dry etch process. For example, the etching process may include a dry etch process using reaction gas(es) that selectively etch the dummy gate structures 84 at a faster rate than the ILD layer 260 or the gate spacers 233. During the removal, the dummy dielectrics 72 may be used as etch stop layers when the dummy gate structures 84 are etched. The dummy dielectrics 72 are then removed. Each recess 106 exposes and/or overlies portions of the channel regions. Portions of the second semiconductive sheets 210 which act as the channel regions are disposed between adjacent pairs of the epitaxial source/drain regions 218a and 218b.

The remaining portions of the first semiconductive sheets 310 can be then removed to expand the recesses 106, such that openings 108 can be formed in regions between the second semiconductive sheets 210. The remaining portions of the first semiconductive sheets 310 can be removed by any acceptable etching process that selectively etches the material of the first semiconductive sheets 310 at a faster rate than the material of the second semiconductive sheets 210. The etching may be isotropic. For example, when the first semiconductive sheets 310 can be formed of silicon germanium and the second semiconductive sheets 210 can be formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second semiconductive sheets 210. In some embodiments, the removing of the remaining portions of the first semiconductive sheets 310 can be interchangeably referred to as a channel releasing process. The second semiconductive sheets 210 can be interchangeably referred to as a vertically stacked multiple channels (sheets) and may have a vertically sheet pitch within a range of from about 10 nm to about 23 nm, such as about 10, 11, 12, 13, 14, 15, 16, 17, 18, 19, 20, 21, 22, or 23 nm. In some embodiments, the second semiconductive sheets 210 may have a thickness within a range from about 4 to about 8 nm, such as about 4, 5, 6, 7, 8 nm. In some embodiments, the vertically sheet pitch of the between adjacent two of the second semiconductive sheets 210 may be within a range from about 6 to 15 nm, such as about 6, 7, 8, 9, 10, 11, 12, 13, 14, or 15 nm.

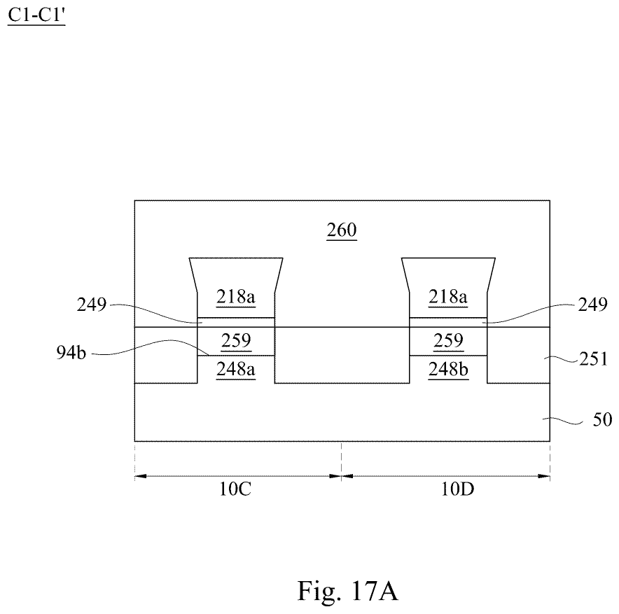

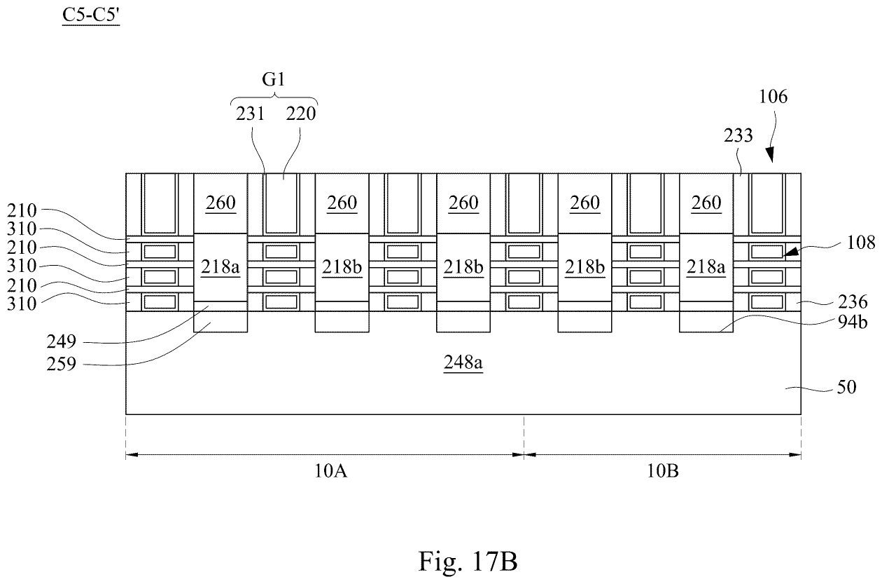

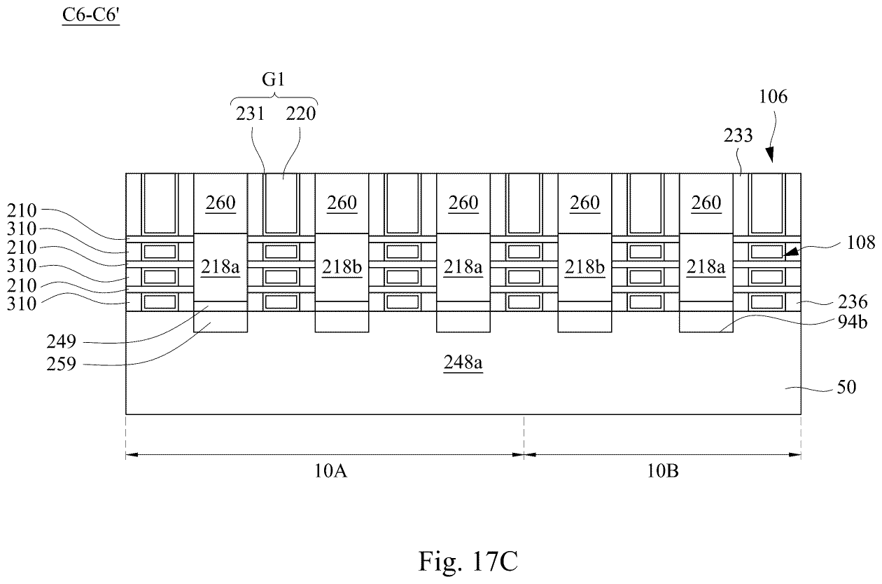

Reference is made to FIGS. 17A-17C. Gate structures G1 can be formed to wrap around the second semiconductive sheets 210. Specifically, a gate dielectric layer 231 can be formed in the recesses 106 and the openings 108. Gate electrode layers 220 are formed over the gate dielectric layer 231. The gate dielectric layer 231 and the gate electrode layers 220 are layers for replacement gates, and each wrap around all (e.g., four) sides of the second semiconductive sheet 210. In some embodiments, the gate structure G1 can be interchangeably referred to as a metal gate, a functional gate, a gate strip, a gate pattern, or a gate line.

The gate dielectric layer 231 is disposed on the sidewalls and/or the top surfaces of the semiconductive layers 248a and 248b; on the top surfaces, the sidewalls, and the bottom surfaces of the second semiconductive sheets 210; and on the inner sidewalls of the gate spacers 233. The gate dielectric layer 231 may include an oxide such as silicon oxide or a metal oxide, a silicate such as a metal silicate, combinations thereof, multi-layers thereof, or the like. The gate dielectric layer 231 may include a dielectric material having a k-value greater than about 7.0, such as a metal oxide or a silicate of hafnium, aluminum, zirconium, lanthanum, manganese, barium, titanium, lead, and combinations thereof. Although a single-layered gate dielectric layer 231 is illustrated in FIGS. 17B and 17C, as will be subsequently described in greater detail, the gate dielectric layer 231 may include any number of interfacial layers and any number of main layers.

The gate electrode layers 220 may include a metal-containing material such as titanium nitride, titanium oxide, tungsten, cobalt, ruthenium, aluminum, combinations thereof, multi-layers thereof, or the like. Although a single-layered gate electrode layers 220 is illustrated in FIGS. 17B and 17C, as will be subsequently described in greater detail, the gate electrode layer 220 may include any number of work function tuning layers, any number of barrier layers, any number of glue layers, and a fill material. In some embodiments, the gate electrode layers 220 may be made of a material selected from a group including TIN, TaN, TiAl, TiAlN, TaAl, TaAlN, TaAlC, TaCN, WNC, Co, Ni, Pt, W, or combinations thereof.

The formation of the gate dielectric layers 231 in the first conductivity type device region 10C and the second conductivity type device region 10D may form simultaneously such that the gate dielectric layers 231 in each region are formed of the same materials, and the formation of the gate electrode layers 220 may form simultaneously such that the gate electrode layers 220 in each region are formed of the same materials. In some embodiments, the gate dielectric layers 231 in each region may be formed by distinct processes, such that the gate dielectric layers 231 may be different materials and/or have a different number of layers, and/or the gate electrode layers 220 in each region may be formed by distinct processes, such that the gate electrode layers 220 may be different materials and/or have a different number of layers. Various masking steps may be used to mask and expose appropriate regions when using distinct processes. In the following description, at least portions of the gate electrode layers 220 in the first conductivity type device region 10C and the gate electrode layers 220 in the second conductivity type device region 10D are formed separately.

Subsequently, a removal process is performed to remove the excess portions of the materials of the gate dielectric layer 231 and the gate electrode layers 220, which excess portions are over the top surfaces of the ILD layer 260 and the gate spacers 233, thereby forming gate dielectric layer 231 and gate electrode layers 220. In some embodiments, a planarization process such as a chemical mechanical polish (CMP), an etch-back process, combinations thereof, or the like may be utilized. The gate dielectric layer 231, when planarized, has portions left in the recesses 106 (thus forming the gate dielectric layer 231). The gate electrode layers 220, when planarized, have portions left in the recesses 106 (thus forming the gate electrode layers 220). The top surfaces of the gate spacers 233; the CESL (not shown); the ILD layer 260; the gate dielectric layer 231, and the gate electrodes can be coplanar (within process variations). The gate dielectric layer 231 and the gate electrode layers 220 can form replacement gates of the resulting nano-FETs. In some embodiments, the gate electrode layers 220 each have a gate length in a range from about 6 to about 20 nm, such as about 6, 7, 8, 9, 10, 11, 12, 13, 14, 15, 16, 17, 18, 19, or 20 nm.

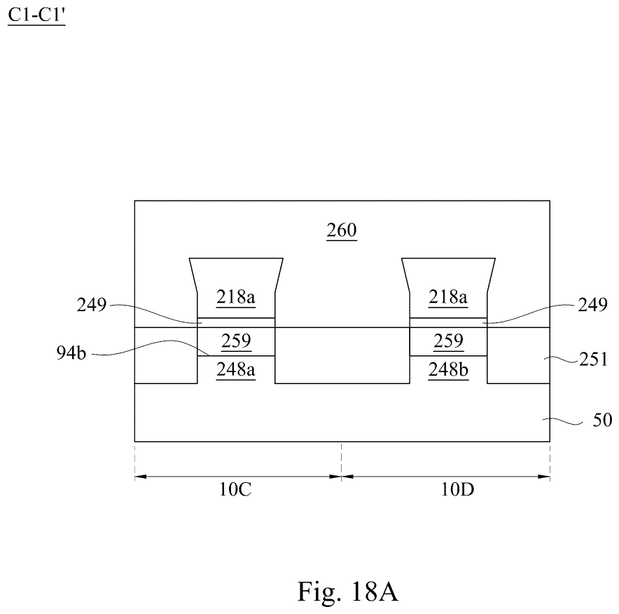

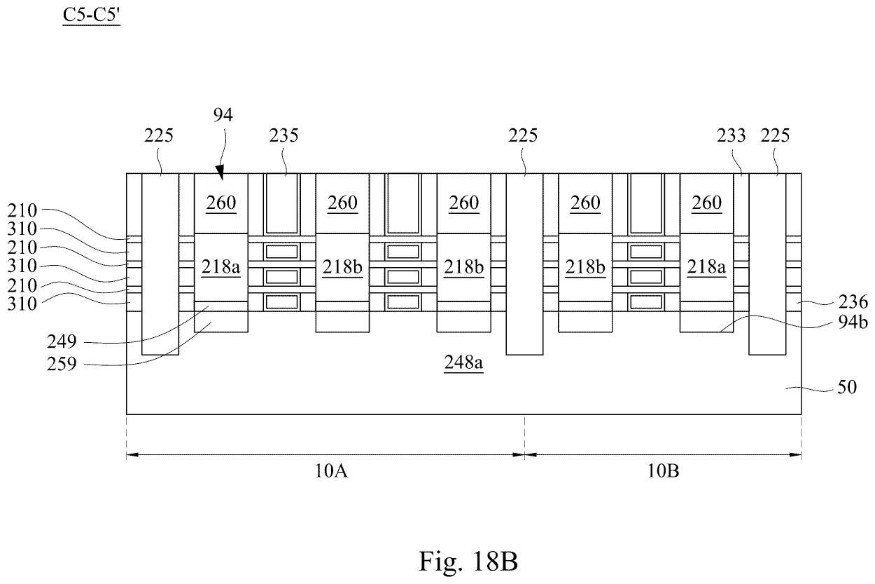

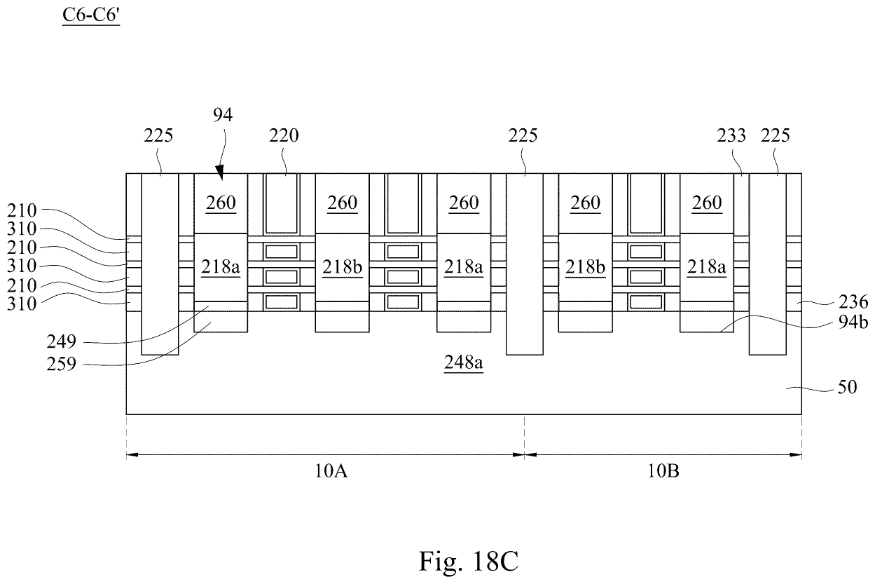

Reference is made to FIGS. 18A-18C. The gate electrode layers 220 and the gate dielectric layer 231 on the boundary of the first and second logic circuit regions 10A and 10B are removed to form isolation regions separating the source/drain regions of neighboring semiconductor devices from each other and separate different semiconductor devices. The isolation region may be formed by using an etching process. In the etching process, the gate electrode layers 220 and the gate dielectric layer 231 on the boundary of the first and second logic circuit regions 10A and 10B are etched anisotropically, until the underlying semiconductive layers 248a and 248b are exposed. The semiconductive layers 248a and 248b are then etched, and the etching continues down into the underlying semiconductive layer 248a/248b and deeper than the recess 94. In some embodiments, the etching may be stopped on the STI structures 251. Subsequently, a dielectric material is filled in the isolation region (i.e., spaces originally occupied by the gate electrode layers 220 and the gate dielectric layer 231 warping the gate electrode layers 220) to form dielectric-base gates 225. As shown in FIGS. 2A and 2B, the dielectric-base gates 225 extend in the Y-direction and being dummy gates. The gate electrodes 220 are arranged between the dielectric-base gates 225. The material of the dielectric-base gates 225 can be different from that of the gate electrodes 220. In some embodiments, the dielectric-base gates 225 can be made of silicon oxide (SiOₓ), silicon nitride (SiₓN_{y}), silicon oxynitride (SiON), dielectric material(s), other suitable material, or a combination thereof. In some embodiments, the dielectric-base gates 225 can be formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

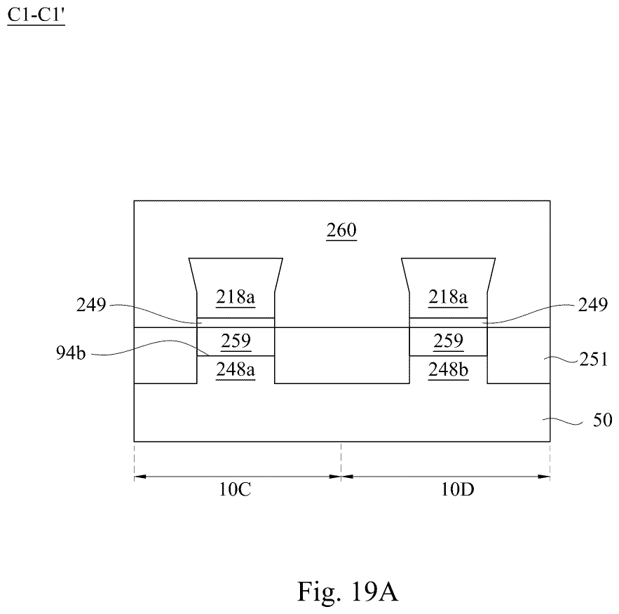

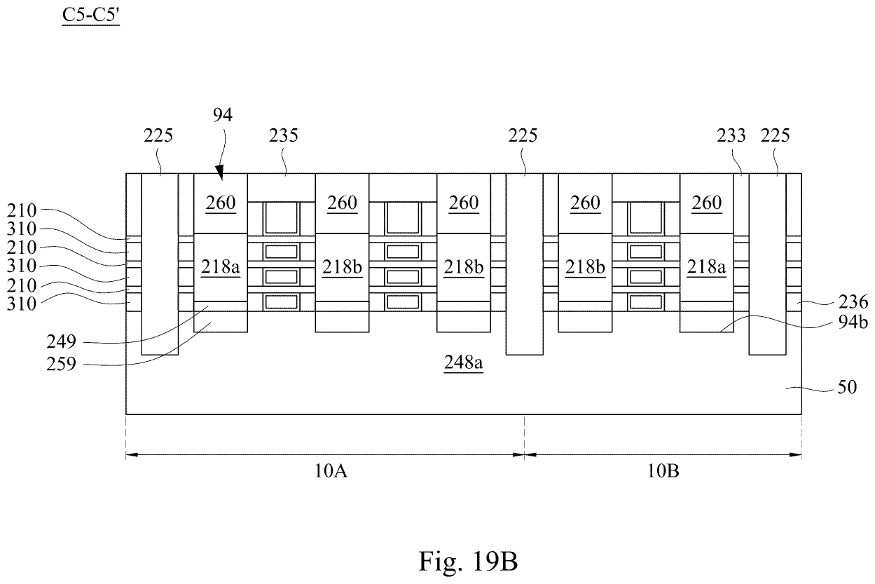

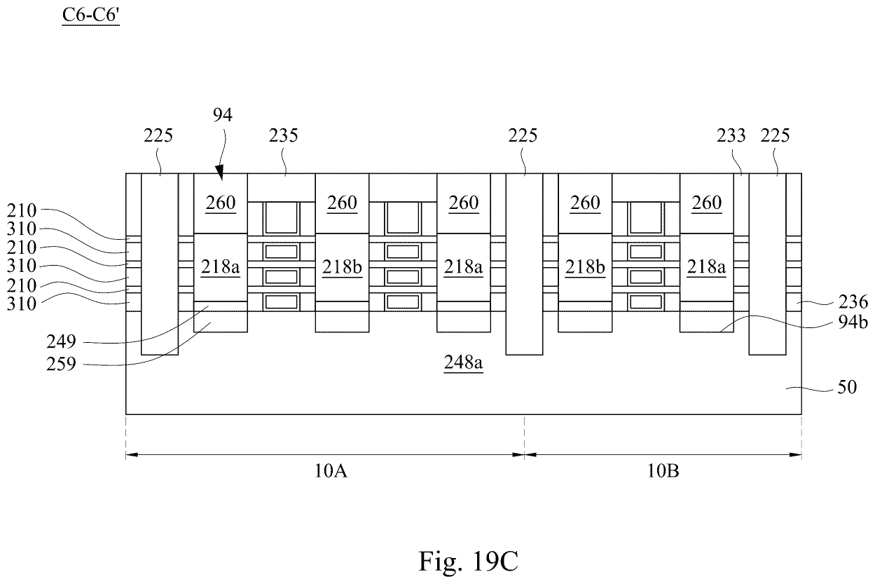

Reference is made to FIGS. 19A-19C. An etch back process is performed on the gate electrode layers 220 and the gate dielectric layer 231 to scale down the gate structure G1. The etch back process may include a bias plasma etching step. The bias plasma etching step may be performed to remove portions of the gate electrode layers 220 and the gate dielectric layer 231. Portions of the gate trenches (e.g., recesses 106) may reappear with shallower depth. Top surfaces of the gate electrode layers 220 and the gate dielectric layer 231 may be no longer level with the ILD layer 260. Inner sidewalls of the gate spacers 233 are then exposed from the gate electrode layers 220 and the gate dielectric layer 231. In some embodiments, the bias plasma etching step may use a gas mixture of Cl₂, O₂, BCl₃, and Ar with a bias in a range from about 25V to about 1200V.

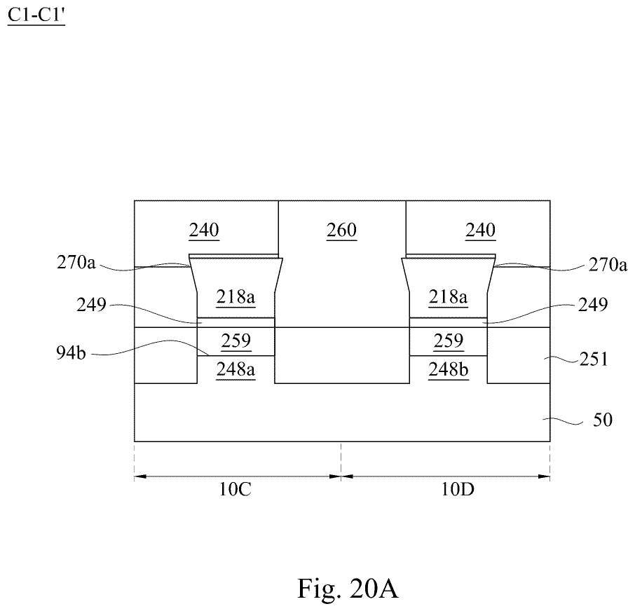

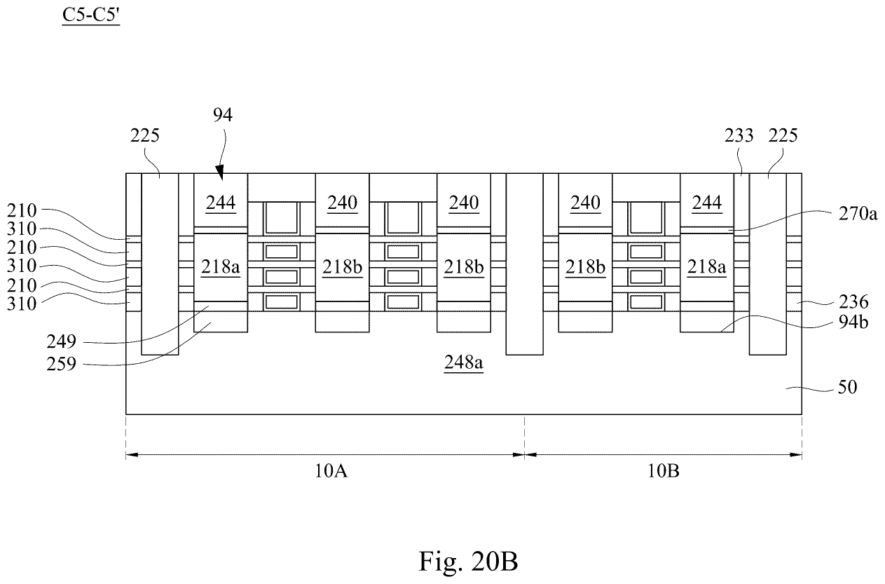

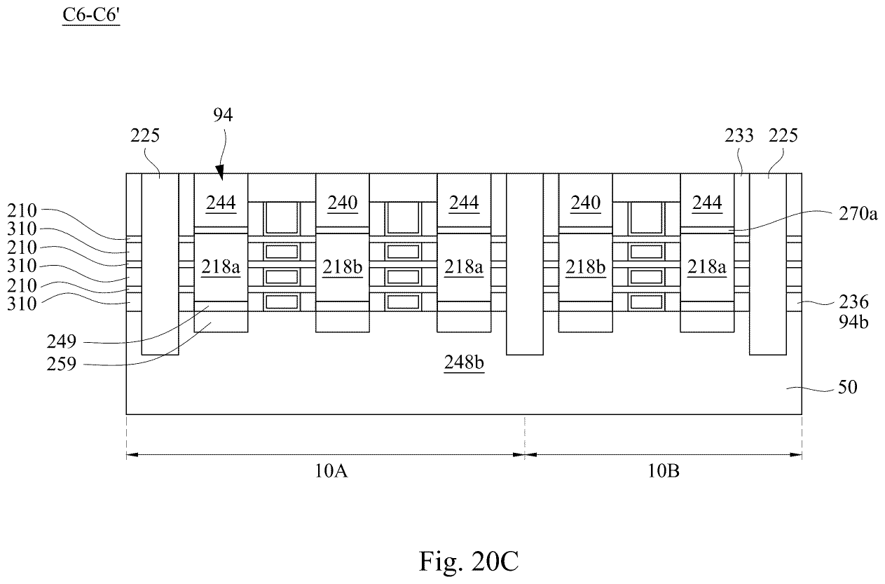

Subsequently, a hard mask layer 235 can be formed over the gate electrode layers 220 and the gate dielectric layer 231 using, for example, a deposition process to deposit a dielectric material over the substrate 50, followed by a CMP process to remove excess dielectric material above the spacers 233 and the ILD layer 260. In some embodiments, source/drain contacts 240 and power supply voltage contacts 244 (see FIGS. 20B and 20C) formed subsequently are formed by a self-aligned contact process using the hard mask layer 235 as a contact etch protection layer. In some embodiments, the hard mask layer 235 may have a thickness in a range from about 2 nm to about 60 nm. In some embodiments, the hard mask layer 235 may be made of a nitride-based material, such as Si₃N₄, SiON, or a carbon-based material, such as SiC. SiOC, SiOCN, or combinations thereof. In some embodiments, the hard mask layer 235 may include SiOₓ, SiBN, SiCBN, other suitable dielectric materials, or combinations thereof. In some embodiments, the hard mask layer 235 may include a metal oxide, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The hard mask layer 235 has different etch selectivity than the spacers 233 and/or the ILD layer 260, so as to selective etch back the hard mask layer 235. By way of example, if the hard mask layer 235 is made of silicon nitride, the spacers 233 and/or the ILD layer 260 may be made of a dielectric material different from silicon nitride. If the hard mask layer 235 is made of silicon carbide (SiC), the spacers 233 and/or the ILD layer 260 may be made of a dielectric material different from silicon carbide. Therefore, the hard mask layer 235 can be used to define self-aligned gate contact region and thus referred to as a self-aligned contact (SAC) structure or a SAC layer. In some embodiments, the hard mask layer 235 may have a thickness in a range from about 2 nm to about 60 nm, such as about 2, 5, 10, 15, 20, 25, 30, 35, 40, 45, 50, 55, or 60 nm. In some embodiments, the hard mask layer 235 can be interchangeably referred to a gate-top dielectric layer.

In some embodiments, the dielectric regions 227 (see FIGS. 3C, 3D, and 3J) can be formed on opposite ends of the gate electrode layers 220 after the forming of the hard mask layer 235. In some embodiments, each dielectric region 227 is a gate-cut structure for the gate structure, and the gate-cut structure is formed by a cut metal gate (CMG) process. In some embodiments, the dielectric region 227 can be interchangeably referred to a gate end dielectric. Specifically, the opposite ends the gate electrode layers 220 can be removed to form gate trenches. The ends of the gate electrode layers 220 may be removed by dry etching, wet etching, or a combination of dry and wet etching. Subsequently, a dielectric material is deposited into the gate trenches, followed by a planarization process to remove excess portions of the dielectric material. The remaining dielectric material forms the dielectric regions 227. By way of example but not limiting the present disclosure, the dielectric region 227 can have a vertical dimension D4 (see FIG. 3C) in the STI structure 251 about 5 nm to about 60 nm, such as about 5, 6, 10, 15, 20, 25, 30, 35, 40, 45, 50, 55, or 60 nm.

In some embodiments, the deposition of the dielectric material of the dielectric regions 227 can be performed using a conformal deposition process such as ALD, which may be PEALD, thermal ALD, or the like. The dielectric material may be formed of or comprise SiO₂, SiOC, SiOCN, or the like, or combinations thereof. In some embodiments, the dielectric region 227 may be made of a nitride-based material, such as Si₃N₄, or a carbon-based material, such as SiOCN, or combinations thereof. In some embodiments, the dielectric region 227 may be made of a material having a dielectric constant greater than about 9 (e.g., high dielectric constant (high-k) material). For example, the dielectric region 227 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric regions 227 may be formed of a homogenous material, or may have a composite structure including more than one layer. The dielectric regions 227 may include dielectric liners, which may be formed of, for example, silicon oxide. In some embodiments, the dielectric material of the dielectric regions 227 comprises SiN, and the deposition is performed using process gases including dichlorosilane and ammonia. Hydrogen (H₂) may or may not be added.

Reference is made to FIGS. 20A-20C. Source/drain contacts 240 and power supply voltage contacts 244 can be formed in the ILD layer 260 and over the source/drain regions 218a and 218b. In some embodiments, the power supply voltage contacts 244 can be interchangeably referred to source/drain contacts. In some embodiments, materials of the source/drain contacts 240 and the power supply voltage contacts 244 may include Cu, Co, Ru, Pt, Al, W, Ti, TaN, TiN, Molybdenum (Mo), Ruthenium (Ru), Iridium (Ir), rhodium (Rh), or any combinations thereof.

In some embodiments, front-side silicide layers 270a can be formed between the source/drain contacts 240 and the source/drain regions 218b and between the power supply voltage contacts 244 and the source/drain regions 218a. In some embodiments, a metal silicidation process can be performed on the source/drain region 218a/218b to form the front-side silicide layer 270a. The metal silicidation process is to make a reaction between metal and silicon (or polycrystalline silicon). In some embodiments, a metal layer is formed on the source/drain region 218a/218b. Subsequently, regarding the metal silicidation process, a first rapid thermal annealing (RTA) process may be performed in, for example, Ar, He, N₂ or other inert atmosphere at a first temperature, such as lower than 200˜300° C., to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400˜500° C., thereby forming the front-side silicide layer 270a with low resistance. In some embodiments, the front-side silicide layer 270a may include titanium silicide (TiSi), nickel silicide (NiSi), cobalt silicide (CoSi), Ni—Pt, or combinations thereof.

Reference is made to FIGS. 21A-21C. An ILD layer 262 is deposited over the ILD layer 260. Subsequently, source/drain vias 242 are formed in the ILD layer 262 and land on the source/drain contacts 240, and the conductive vias 246 are formed in the ILD layer 262 and land on the power supply voltage contact 244. In some embodiments, the conductive vias 246 can be interchangeably referred to source/drain vias. Gate vias 250 are formed to pass through the ILD layer 262 and the hard mask layer 235 and land on the gate electrode layers 220. The source/drain vias 242, conductive vias 246, and/or the gate vias 250 may include a metal-containing material such as titanium nitride, titanium oxide, tungsten, cobalt, ruthenium, aluminum, copper, combinations thereof, multi-layers thereof, or the like. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, a front-side interconnect structure can be formed over the front-side gate vias 250, the front-side source/drain vias 242, and the front-side conductive vias 246. The interconnect structure includes a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure may include metal lines F-M1 and power supply voltage lines F-M1-Vdd, F-M1-Vss formed in a first front-side metallization layer. The metal lines F-M1 and the power supply voltage lines F-M1-Vdd, F-M1-Vss are in an IMD (inter-metal dielectric) layer 264. The front-side metal layers F-M1 are electrically connected to the gate electrode layers 220 through the gate vias 250 and electrically connected to the source/drain regions 218a and 218b through the source/drain vias 242 and the source/drain contacts 240. The power supply voltage lines F-M1-Vdd, F-M1-Vss are electrically connected to the source/drain regions 218a and 218b through the conductive vias 246 and the power supply voltage contact 244. In some embodiments, materials of the metal lines F-M1, and/or the power supply voltage lines F-M1-Vdd, F-M1-Vss, may include Cu, Co, Ru, Pt, Al, W, Ti, TaN, TiN, Molybdenum (Mo), Ruthenium (Ru), Iridium (Ir), rhodium (Rh), or any combinations thereof. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. Subsequently, a protection layer (not shown) can be formed over the front-side interconnect structure. The protection layer can be a single layer, some embodiments may utilize multiple dielectric layers. In some embodiments, the protection layer can be a poly layer, or a silicon substrate.

Reference is made to FIGS. 22A-22C. The structures of FIGS. 21A-21C can be “flipped” upside down, and the substrate 50 is removed. The substrate 50 may be removed in a plurality of process operations, for example, CMP, HNA, and/or TMAH etching from the back-side 50k (see FIGS. 21A-21C) of the substrate 50, which stops at the STI structure 251 or the semiconductive layer 248a/248b. After the removal process, the STI structure 251 and the semiconductive layers 248a and 248b can be exposed as shown in FIGS. 22A-22C.

Reference is made to FIGS. 23A-23C. A back-side dielectric layer 331 is formed over a back-side surface of the STI structure 251 and back-side surfaces 248c and 248k of the semiconductive layers 248a and 248b. In some embodiments, the back-side dielectric layer 331 may be made of dielectric material, such as SiO₂, Si₃N₄, SiON, SiOC, SiOCN base dielectric material, or combinations thereof. In some embodiments, the back-side dielectric layer 331 may be made of an oxide, a nitride-based material, such as Si₃N₄, SiON, or a carbon-based material, such as SIC, SiOC, SiOCN, or combinations thereof. In some embodiments, the back-side dielectric layer 331 may be made of a material having a dielectric constant greater than about 9 (e.g., high dielectric constant (high-k) material). For example, the back-side dielectric layer 331 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. In some embodiments, the semiconductive layer 248a/248b can be partially broken by the dielectric-base gates 225, not fully broken by the dielectric-base gates 225.

Reference is made to FIGS. 24A-24D. A mask layer 254 (see FIGS. 24B-24D) may be formed over the back-side of the dielectric layer 331. The mask layer 254 is patterned to have openings O2 (see FIGS. 24B-24D) overlapping the source/drain regions 218a. In some embodiments, the opening O2 (see FIG. 24A) on the mask layer 254 may have a dimension D5 in parallel with a lengthwise direction of the semiconductive sheet 210, and a dimension D6 in parallel with a lengthwise direction of the gate electrode 220 from the top view. The dimension D5 of the opening O2 may be greater than a width of the source/drain regions 218a in the lengthwise direction of the semiconductive sheet 210, such that the opening O2 can overlap the gate spacer 233 and/or the gate electrode 220 from the top view. The dimension D6 of the opening O2 may be the same as a width of the semiconductive sheet 210. Subsequently, an etching process P4 (see FIGS. 24B-24D) can be performed through the openings O2 to remove portions of the semiconductive layer 248a/248b and the dielectric layer 331 to form a subsidiary contact opening 352a in the semiconductive layer 248a/248b and the dielectric layer 331, in which the semiconductive layer 259 can act as an etch stop layer. In some embodiments, the etching process P4 may be an anisotropic dry etch process, such as a dry etch process (e.g., RIE, a NBE, or the like). In some embodiments, the subsidiary contact opening 352a can have a top view profile inheriting the opening O2.

Reference is made to FIGS. 25A-25D. The semiconductive layers 259 included in Vdd node and Vss nodes can be removed from the bask-side of the semiconductor structure to expose the dielectric layers 249. An etching process P5 (see FIGS. 25B-25D) can be performed through the openings O2 to remove the semiconductive layer 259 over the source/drain region 218a that is of Vdd node or Vss node, in which the dielectric layers 249 can act as an etch stop layer, such that a subsidiary contact opening 352b can be formed to inherit the shape of the semiconductive layer 259 and self-align with the source/drain regions 218a. After the removing of the semiconductive layer 259 underlying the source/drain regions 218a. On the other hand, the semiconductive layer 259 over the source/drain region 218b can be remained. Therefore, the source/drain regions 218b which are not of Vdd node and Vss node can be isolated from the semiconductive layers 248a and 248b by the remained semiconductive layers 259 and the dielectric layers 249. In some embodiments, the etching process P5 may be an anisotropic dry etch process, such as a dry etch process (e.g., RIE, a NBE, or the like) and may employ a different etchant than that used in the etching process P4.

In some embodiments, the subsidiary contact opening 352b (see FIG. 23A) may have a dimension D7 in parallel with the lengthwise direction of the semiconductive sheet 210, and a dimension D8 in parallel with the lengthwise direction of the gate electrode 220 from the top view. The dimension D7 of the subsidiary contact opening 352b may be the same as the width of the source/drain regions 218a in the lengthwise direction of the semiconductive sheet 210, such that the subsidiary contact opening 352b non-overlaps with the gate spacer 233 and/or the gate electrode 220 from the top view. The dimension D8 of the subsidiary contact opening 352b may be the same as a width of the semiconductive sheet 210. The dimension D5 of the subsidiary contact opening 352a is greater than the dimension D7 of the subsidiary contact opening 352b. By way of example and not limitation, a ratio of dimension D5 of the subsidiary contact opening 352a to the dimension D7 of the subsidiary contact opening 352b can be greater than about 1.3. In some embodiments, the dimension D6 of the subsidiary contact opening 352a is substantially the same as the dimension D8 of the subsidiary contact opening 352b.

Reference is made to FIGS. 26A-26C. The dielectric layers 249 included in Vdd node and Vss nodes can be removed from the bask-side of the semiconductor structure to expose the source/drain regions 218a. An etching process P6 (see FIGS. 26A-26C) can be performed through the openings O2 to remove the dielectric layers 249 on the source/drain region 218a that is of Vdd node or Vss node, in which the source/drain regions 218a can act as an etch stop layer. After the removing of the dielectric layers 249 underlying the source/drain regions 218a, the patterned mask layer 254 can be removed with a wet clean process, an ashing process, or the like. On the other hand, the dielectric layers 249 on the source/drain region 218b are remained. In some embodiments, the etching process P6 may be an anisotropic dry etch process, such as a dry etch process (e.g., RIE, a NBE, or the like) and may employ a different etchant than that used in the etching process P5.

Reference is made to FIGS. 27A-27C. A conductive material is deposited over the back-side of the semiconductor structure and in the back-side contact opening 352c. Subsequently, a removal process is performed to level the back-side surface of the conductive material with the back-side of the dielectric layer 331 to form contacts 352 in the back-side contact opening 352c. In some embodiments, a planarization process such as a chemical mechanical polish (CMP), an etch-back process, combinations thereof, or the like may be utilized. Therefore, the source/drain region 218a can be electrically connected to the back-side metal line (e.g., power supply voltage lines B-M1-Vss, B-M1-Vdd) through the contact 352 acting a power conductor path. Because the subsidiary contact opening 352b of the contact opening 352c can be formed to inherit the shape of the dielectric layer 249 directly underlying the source/drain regions 218a, the contact 352 formed in the contact opening 352c can self-align with the source/drain regions 218a and on the back-side 218k of the source/drain region 218a. Therefore, the contact 352 can be interchangeably referred to as a self-aligned connection structure, and the intermediate stages in the formation of the semiconductor structure shown in FIGS. 12A-13C and 22A-24C can be referred to as a self-aligned contact process. Specifically, the contact 352 has a front-side portion 352d formed in the subsidiary contact opening 352b and a back-side portion 352e formed in the back-side contact opening 352a.

As shown in FIGS. 27A-27C, the contact 352 can penetrate through the back-side dielectric layer 331 and the STI structure 251 when viewed in the cross section as shown in FIG. 27A and penetrate through the back-side dielectric layer 331 and the semiconductive layer 248a/248b when viewed in the cross section as shown in FIG. 27B or FIG. 27C. In addition, the contact 352 can be a stepped sidewall structure having a sidewall 352f, a sidewall 352g laterally set back from the sidewall 352f, and an horizontal surface 352h connecting the sidewall 352f to the sidewall 352g. The back-side portion 352e of the contact 352 may have a dimension T5 (see FIGS. 27B and 27C) in parallel with a lengthwise direction of the semiconductive sheet 210, and a dimension T6 (see FIG. 27A) in parallel with a lengthwise direction of the gate electrode 220 from the top view.

The front-side portion 352d of the contact 352 (see FIGS. 27B and 27C) may have a dimension T7 in parallel with the lengthwise direction of the semiconductive sheet 210, and a dimension T8 in parallel with the lengthwise direction of the gate electrode 220. The dimension T7 of the subsidiary contact opening 352b may be the same as the width of the source/drain regions 218a in the lengthwise direction of the semiconductive sheet 210, such that the front-side portion 352d of the contact 352 non-overlaps with the gate spacer 233 and/or the gate electrode 220. The dimension T8 of the subsidiary contact opening 352b may be the same as a width of the semiconductive sheet 210 in the lengthwise direction of the gate electrode 220. In some embodiments, the lateral dimension T11 (see FIGS. 12B and 12C) of the dielectric layer 249 may be the same as the dimension T7 of the subsidiary contact opening 352b. In some embodiments, the lateral dimension T12 (see FIG. 12A) of the dielectric layer 249 may be the same as the dimension T8 of the subsidiary contact opening 352b. In some embodiments, the dimension T5 of the back-side portion 352e of the contact 352 is greater than the dimension T11 of the dielectric layer 249.

In some embodiments, a back-side silicide layer 270b can be formed between the back-side contact 352 and the source/drain regions 218a, and between the back-side contact 352 and the semiconductive layer 248a/248b. On the other hand, the back-side silicide layer 270b can be free from coverage of the back-side dielectric layer 331. In some embodiments, a metal silicidation process can be performed on the source/drain region 218a to form the back-side silicide layer 270b. The metal silicidation process is to make a reaction between metal and silicon (or polycrystalline silicon). In some embodiments, a metal layer is formed on the source/drain region 218a. Subsequently, regarding the metal silicidation process, a first rapid thermal annealing (RTA) process may be performed in, for example, Ar, He, N₂ or other inert atmosphere at a first temperature, such as lower than 200˜300° C., to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400˜500° C., thereby forming the back-side silicide layer 270b with low resistance. In some embodiments, the back-side silicide layer 270b may include titanium silicide (TiSi), nickel silicide (NiSi), cobalt silicide (CoSi), Ni—Pt, or combinations thereof.

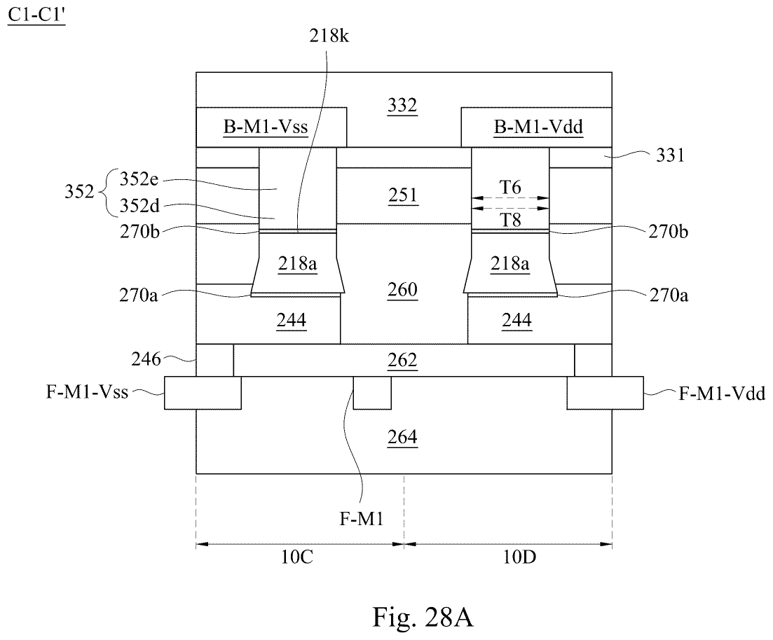

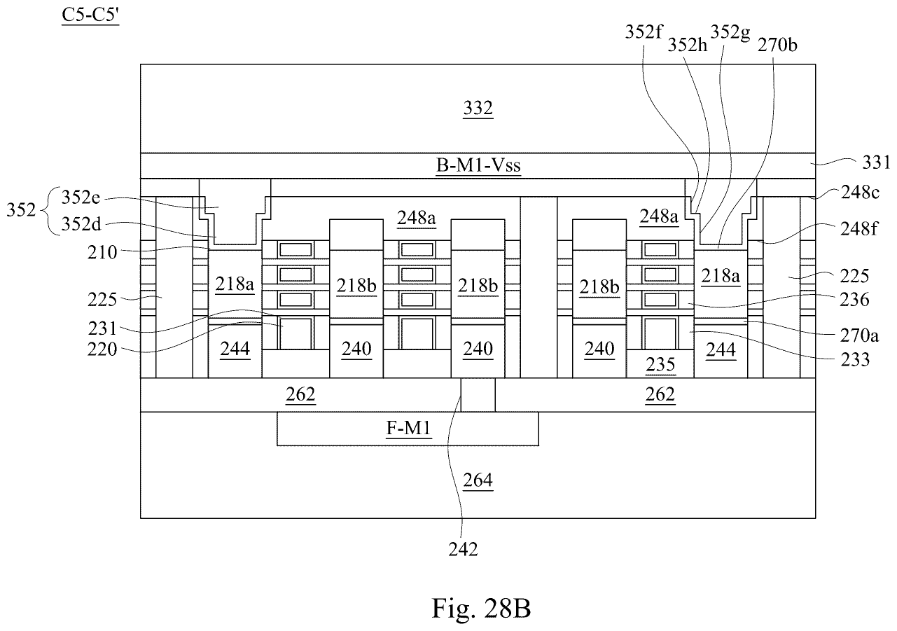

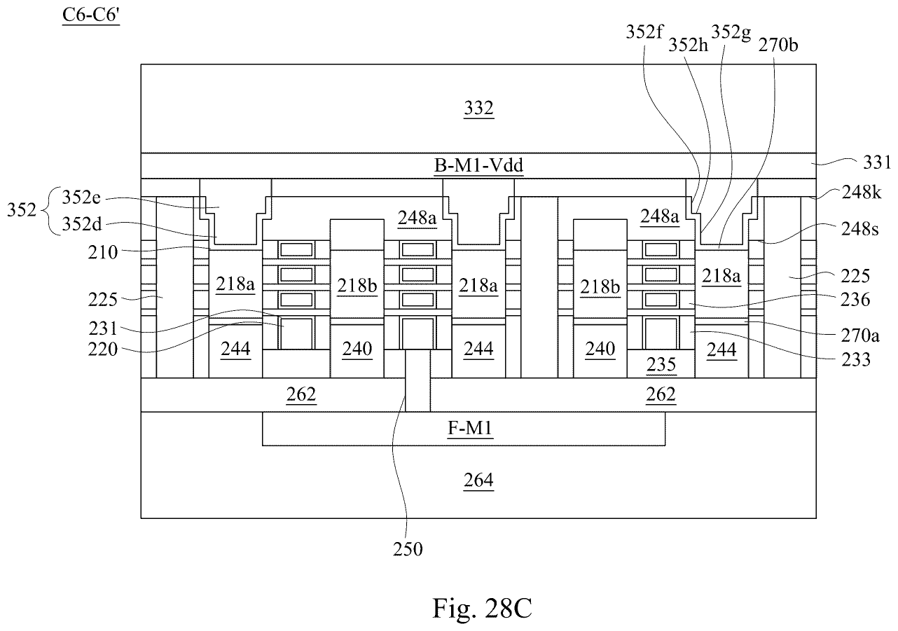

Reference is made to FIGS. 28A-28C. A back-side interconnect structure is formed over the back-side contact 352. The back-side interconnect structure includes a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The back-side interconnect structure may include the power supply voltage lines B-M1-Vss, B-M1-Vdd in a first back-side metallization layer formed in an IMD layer 332. The power supply voltage lines B-M1-Vss, B-M1-Vdd are electrically connected to the source/drain regions 218a and 218b through the back-side contact 352. In some embodiments, materials of the power supply voltage lines B-M1-Vss, B-M2-Vdd may include Cu, Co, Ru, Pt, Al, W, Ti, TaN, TIN, Molybdenum (Mo), Ruthenium (Ru), Iridium (Ir), rhodium (Rh), or any combinations thereof. In some embodiments, the IMD layer 332 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, after the forming of the back-side interconnect structure, a backside to front side connection module formation (not shown) can be formed on the IC structure, such as a tap structure formation. Subsequently, backside bump pads formation (not shown) and passivation layer formation (not shown) can be formed on the back-side interconnect structure.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a metal line routing method to improve the functional density and operation performance on the IC structure. Because the power conductive contact can be formed to inherit the location of the dielectric layer and/or semiconductive layer (e.g., sacrificial layer) directly underlying the source/drain region, the back-side contact can self-align with the source/drain region to connect the source/drain region to the back-side power metal layers. Therefore, an isolation margin issue of the back-side power conductive contact to gate electrode can be solved, which in turn allows for scaling the contacted poly pitch (CPP). In addition, because the back-side power conductive contact can have a back-side portion having wider width than the front-side portion thereof (e.g., stepped sidewall structure) to connect the back-side power metal layers, an improved contact resistance between the source/drain region and the back-side power metal layers can be achieved.

In some embodiments, a method includes forming a semiconductive sheet over a front-side of a semiconductive region that is on a front-side of a substrate; forming a plurality of semiconductive layers on the front-side of the semiconductive region and at either side of the semiconductive sheet; forming a plurality of source/drain structures over the semiconductive layers and on the either side of the semiconductive sheet; forming a gate structure wrapping around the semiconductive sheet; performing a planarization process on a back-side of the substrate to expose the semiconductive region; etching the semiconductive region from a back-side of the semiconductive region to form a first opening exposing a first one of the semiconductive layers, while remains covering a second one of the semiconductive layers; selectively removing the first one of the semiconductive layers through the first opening to form a second opening; forming a contact having a first portion in the first opening and a second portion in the second opening; forming a power supply voltage line on a back-side of the contact. In some embodiments, the semiconductive layers comprise silicon germanium. In some embodiments, when viewed in a cross section taken along a lengthwise direction of the semiconductive sheet, a lateral dimension of the first portion of the contact is greater than a lateral dimension of the second portion of the contact. In some embodiments, when viewed in a cross section taken along a lengthwise direction of the semiconductive sheet, a lateral dimension of the first portion of the contact is greater than a lateral dimension of the remained second one of the semiconductive layers. In some embodiments, when viewed in a cross section taken along a lengthwise direction of the semiconductive sheet, the contact is a stepped sidewall structure having a first sidewall in the first opening, a second sidewall in the second opening and laterally set back from the first sidewall, and a horizontal surface connecting the first sidewall to the second sidewall. In some embodiments, when viewed in a cross section taken along a direction in parallel with a lengthwise direction the gate structure, a lateral dimension of the first portion of the contact is substantially the same as a lateral dimension of the second portion of the contact. In some embodiments, the method further includes before forming the source/drain structures, forming a plurality of dielectric layers over the semiconductive layers and on the either side of the semiconductive sheet; after selectively removing the first one of the semiconductive layers, selectively removing one of the dielectric layers through the first and second openings. In some embodiments, the method further includes before forming the contact, forming a silicide layer on a back-side of one of the source/drain structures through the first and second openings. In some embodiments, the silicide layer is further conformally formed on sidewalls of the first and second openings. In some embodiments, the method further includes forming a back-side dielectric layer over the back-side of the semiconductive region, wherein the contact penetrates through the back-side dielectric layer.

In some embodiments, a method includes forming a plurality of nanostructures arranged in a vertical direction on a semiconductor strip upwardly extending from a front-side of a substrate; forming a plurality of epitaxial layers on the semiconductor strip; growing a plurality of epitaxial patterns on opposite sides of the nanostructures and on the epitaxial layers; forming a gate pattern across the nanostructures and between the epitaxial patterns; performing a planarization process on a back-side of the substrate to expose the semiconductor strip; etching the semiconductor strip to expose one of the epitaxial layers; performing an etch process on the one of the epitaxial layers to expose one of the epitaxial patterns; after removing the one of the epitaxial layers, forming a power conductive contact extending through the semiconductor strip and on the one of the epitaxial patterns, wherein from a cross-sectional view, the power conductive contact is a stepped sidewall structure, and a lateral dimension of a back-side of the power conductive contact is greater than a lateral dimension of a front-side of the power conductive contact; forming a power supply voltage line on the back-side of the power conductive contact. In some embodiments, during the etch process, an etching rate of the one of the epitaxial layers is greater than an etching rate of the semiconductor strip. In some embodiments, the method further includes forming a spacer on a sidewall of the gate pattern, wherein the power conductive contact overlaps the spacer from a top view. In some embodiments, from the cross-sectional view, the back-side of the power conductive contact has opposite two sidewalls, the sidewalls has a distance therebetween in a range from about 13 to about 40 nm. In some embodiments, from the cross-sectional view, the front-side of the power conductive contact has opposite two sidewalls, the sidewalls having a distance therebetween in a range from about 6 to about 20 nm. In some embodiments, one of the epitaxial patterns has a first dopant being of a first conductivity type, and the semiconductor strip has a second dopant being of a second conductivity type opposite to the first conductivity type.

In some embodiments, the semiconductor structure includes a silicon layer, a transistor, a contact, a front-side power supply voltage line, a back-side power supply voltage line, and a silicon germanium layer. The transistor is on a front side of a silicon layer. The transistor includes a channel region, a gate structure surrounding the channel region, and a plurality of source/drain regions on opposite sides of the gate structure. The contact extends through the silicon layer and over a back-side of a first one of the source/drain regions. The front-side power supply voltage line is electrically connected to a front-side of the first one of the source/drain regions. The back-side power supply voltage line is electrically connected to a back-side of the contact. The silicon germanium layer is between the silicon layer and a second one of the source/drain regions. In some embodiments, the silicon germanium layer is in contact with the second one of the source/drain regions. In some embodiments, the semiconductor structure further includes a dielectric layer over a back-side of a second one of the source/drain regions, wherein the silicon germanium layer is sandwiched between the dielectric layer and the silicon layer. In some embodiments, the contact has a first sidewall, a second sidewall laterally set back from the first sidewall, and a horizontal surface connecting the first sidewall to the second sidewall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductive sheet over a front-side of a semiconductive region that is on a front-side of a substrate;
forming a plurality of semiconductive layers on the front-side of the semiconductive region and at either side of the semiconductive sheet;
forming a plurality of source/drain structures over the semiconductive layers and on the either side of the semiconductive sheet;
forming a gate structure wrapping around the semiconductive sheet;
performing a planarization process on a back-side of the substrate to expose the semiconductive region;
etching the semiconductive region from a back-side of the semiconductive region to form a first opening exposing a first one of the semiconductive layers, while remains covering a second one of the semiconductive layers;
selectively removing the first one of the semiconductive layers through the first opening to form a second opening;
forming a contact having a first portion in the first opening and a second portion in the second opening; and
forming a power supply voltage line on a back-side of the contact.

2. The method of claim 1, wherein the semiconductive layers comprise silicon germanium.

3. The method of claim 1, wherein when viewed in a cross section taken along a lengthwise direction of the semiconductive sheet, a lateral dimension of the first portion of the contact is greater than a lateral dimension of the second portion of the contact.

4. The method of claim 1, wherein when viewed in a cross section taken along a lengthwise direction of the semiconductive sheet, a lateral dimension of the first portion of the contact is greater than a lateral dimension of the remained second one of the semiconductive layers.

5. The method of claim 1, wherein when viewed in a cross section taken along a lengthwise direction of the semiconductive sheet, the contact is a stepped sidewall structure having a first sidewall in the first opening, a second sidewall in the second opening and laterally set back from the first sidewall, and a horizontal surface connecting the first sidewall to the second sidewall.

6. The method of claim 1, wherein when viewed in a cross section taken along a direction in parallel with a lengthwise direction the gate structure, a lateral dimension of the first portion of the contact is substantially the same as a lateral dimension of the second portion of the contact.

7. The method of claim 1, further comprising:
before forming the source/drain structures, forming a plurality of dielectric layers over the semiconductive layers and on the either side of the semiconductive sheet; and
after selectively removing the first one of the semiconductive layers, selectively removing one of the dielectric layers through the first and second openings.

8. The method of claim 1, further comprising:
before forming the contact, forming a silicide layer on a back-side of one of the source/drain structures through the first and second openings.

9. The method of claim 8, wherein the silicide layer is further conformally formed on sidewalls of the first and second openings.

10. The method of claim 1, further comprising:
forming a back-side dielectric layer over the back-side of the semiconductive region, wherein the contact penetrates through the back-side dielectric layer.

11. A method, comprising:
forming a plurality of nanostructures arranged in a vertical direction on a semiconductor strip upwardly extending from a front-side of a substrate;
forming a plurality of epitaxial layers on the semiconductor strip;
growing a plurality of epitaxial patterns on opposite sides of the nanostructures and on the epitaxial layers;
forming a gate pattern across the nanostructures and between the epitaxial patterns;
performing a planarization process on a back-side of the substrate to expose the semiconductor strip;
etching the semiconductor strip to expose one of the epitaxial layers;
performing an etch process on the one of the epitaxial layers to expose one of the epitaxial patterns;
after removing the one of the epitaxial layers, forming a power conductive contact extending through the semiconductor strip and on the one of the epitaxial patterns, wherein from a cross-sectional view, the power conductive contact is a stepped sidewall structure, and a lateral dimension of a back-side of the power conductive contact is greater than a lateral dimension of a front-side of the power conductive contact; and
forming a power supply voltage line on the back-side of the power conductive contact.

12. The method of claim 11, wherein during the etch process, an etching rate of the one of the epitaxial layers is greater than an etching rate of the semiconductor strip.

13. The method of claim 11, further comprising:
forming a spacer on a sidewall of the gate pattern, wherein the power conductive contact overlaps the spacer from a top view.

14. The method of claim 11, wherein from the cross-sectional view, the back-side of the power conductive contact has opposite two sidewalls, the sidewalls has a distance therebetween in a range from about 13 to about 40 nm.

15. The method of claim 11, wherein from the cross-sectional view, the front-side of the power conductive contact has opposite two sidewalls, the sidewalls having a distance therebetween in a range from about 6 to about 20 nm.

16. The method of claim 11, wherein one of the epitaxial patterns has a first dopant being of a first conductivity type, and the semiconductor strip has a second dopant being of a second conductivity type opposite to the first conductivity type.

17. A semiconductor structure, comprising:
a transistor on a front side of a silicon layer, the transistor comprising a channel region, a gate structure surrounding the channel region, and a plurality of source/drain regions on opposite sides of the gate structure;
a contact extending through the silicon layer and over a back-side of a first one of the source/drain regions;
a front-side power supply voltage line electrically connected to a front-side of the first one of the source/drain regions;
a back-side power supply voltage line electrically connected to a back-side of the contact; and
a silicon germanium layer between the silicon layer and a second one of the source/drain regions.

18. The semiconductor structure of claim 17, wherein the silicon germanium layer is in contact with the second one of the source/drain regions.

19. The semiconductor structure of claim 17, further comprising:
a dielectric layer over a back-side of a second one of the source/drain regions, wherein the silicon germanium layer is sandwiched between the dielectric layer and the silicon layer.

20. The semiconductor structure of claim 17, wherein the contact has a first sidewall, a second sidewall laterally set back from the first sidewall, and a horizontal surface connecting the first sidewall to the second sidewall.
